(19) United States
(12) Patent Application Publication
(10) Pub. No.: US 2002/0042007 A1
(43) Pub. Date: Apr. 11, 2002

(54) Fabrication method of semiconductor integrated circuit device

(76) Inventors: Ko Miyazaki, Kokubunji (JP); Kazutaka Mori, Kokubunji (JP); Norio Hasegawa, Hinode (JP); Tsuneo Terasawa, Ome (JP); Toshihiko Tanaka, Tokyo (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/964,490

(22) Filed: Sep. 28, 2001

(30) Foreign Application Priority Data
Oct. 6, 2000 (JP) 2000-308320

(51) Int. Cl. G03F 9/00; G06F 17/50

(52) U.S. Cl. 430/5; 716/19

(57) ABSTRACT

Provided is a fabrication method of a semiconductor integrated circuit device, which comprises properly using a photomask having light blocking patterns made of a metal and another photomask having light blocking patterns made of a resist film upon exposure treatment, depending on the fabrication step of the semiconductor integrated circuit device.

According to the present invention, the productivity of the semiconductor integrated circuit device can be improved.

### BACKGROUND OF THE INVENTION

The present invention relates to a fabrication technique of a semiconductor integrated circuit device, particularly to a technique effective when applied to photolithography (hereinafter be called “lithography” simply) for transferring predetermined patterns onto a semiconductor wafer (hereinafter be called “wafer” simply) with a photomask (hereinafter be called “mask” simply) in a fabrication step of the semiconductor integrated circuit device.

In the fabrication of a semiconductor integrated circuit device (LSI: Large Scale Integrated Circuit), lithography is employed as a method for forming minute patterns on a wafer. As this photolithography, a so-called optical projection exposure method in which patterns formed on a mask are transferred in repetition onto a wafer through a stepper optical system is most popular. The basic constitution of the stepper is described, for example, in Japanese Patent Application Laid-Open No. 2000-91192.

In this projection exposure method, the resolution R on a wafer is usually expressed by R=k×λ/NA wherein k stands for a constant depending on a resist material or process, λ means the wavelength of an illumination light and NA represents the numerical aperture of a projection exposure lens. As is apparent from this relational equation, with a tendency to miniaturize patterns, a projection exposure technique using a light source of a shorter wavelength becomes necessary. Fabrication of LSI is now conducted through a projection exposure system using, as an illumination light source, i line (λ=365 nm) of a mercury lamp or KrF excimer laser (λ=248 nm). Adoption of an ArF excimer laser (λ=193 nm) or F₂ excimer laser (λ=157 nm) is under investigation, because a light source of a shorter wavelength is required for realization of further miniaturization.

The mask used in the projection exposure method has, on a quartz glass substrate transparent to an exposure light, light blocking patterns made of a light blocking film of chromium. Such a mask is manufactured, for example, by forming a chromium film, which is to be a light blocking film, on a quartz glass substrate, applying thereto a resist film photosensitive to electron beams, exposing the resist film to electron beams based on predetermined pattern data, developing to form resist patterns, etching the thin chromium film with the resist patterns as an etching mask, thereby forming light blocking patterns, and then removing the remaining electron-beam sensitive resist film.

### SUMMARY OF THE INVENTION

The present inventor has however found that the below-described problem exists in the exposure technique using a mask having light blocking patterns made of a metal film such as chromium.

Described specifically, a mask having light blocking patterns made of a metal film is suited for mass production because it is rich in durability, has high reliability and can therefore be utilized for a great deal of exposure treatment. In a development period or pre-production stage of a semiconductor integrated circuit device, or in large item small scale production of a semiconductor integrated circuit device, mask patterns tend to be changed or corrected and a sharing frequency of a mask is low. In such a case, it takes time and cost for manufacturing masks, inhibiting productivity improvement or cost reduction of a semiconductor integrated circuit device. This is the problem found by the present inventor.

An object of the present invention is therefore to provide a technique capable of improving the productivity of a semiconductor integrated circuit device.

Another object of the present invention is to provide a technique capable of shortening the fabrication time of a semiconductor integrated circuit device.

A further object of the present invention is to provide a technique capable of reducing the cost of a semiconductor integrated circuit device.

The above-described and the other objects and novel features of the present invention will be apparent from the description herein and accompanying drawings.

Among the inventions disclosed by the present application, typical ones will next be described briefly.

In one aspect of the present invention, there is thus provided a fabrication method of a semiconductor integrated circuit device, which comprises properly using, upon exposure treatment, a first photomask which has an organic photosensitive resin as a blocker against an exposure light, and a second photomask which has a metal film as a blocker against an exposure light, depending on the production amount of the semiconductor integrated circuit device.

In another aspect of the present invention, there is also provided a fabrication method of a semiconductor integrated circuit device, which comprises judging whether the production amount of the semiconductor integration circuit device exceeds a predetermined threshold production amount or not; and using a photomask which has, as a blocker against an exposure light, an organic material containing an organic photosensitive resin film upon exposure treatment when the production amount of the semiconductor integrated circuit device does not exceed the threshold value.

In a further aspect of the present invention, there is also provided a fabrication method of a semiconductor integrated circuit device, which comprises judging whether the production amount of the semiconductor integration circuit device exceeds a predetermined threshold production amount or not; judging whether the function of the semiconductor integrated circuit device has been determined or not when the production amount of the semiconductor integrated circuit device exceeds the threshold value; and using a photomask which has, as a blocker against an exposure light, an organic material containing an organic photosensitive resin film upon exposure treatment when the function has not yet been determined,.

In a still further aspect of the present invention, there is also provided a fabrication method of a semiconductor integrated circuit device, which comprises using a photomask having, as a blocker against an exposure light, an organic material containing an organic photosensitive resin upon exposure treatment prior to a mass production step.

In a still further aspect of the present invention, there is also provided a fabrication method of a semiconductor integrated circuit device, which comprises using a first photomask which has, as a blocker against an exposure light, an organic material containing an organic photosensitive resin upon exposure treatment prior to a mass production step, and upon the mass production step, using a second photomask which has a metal film as a blocker against an exposure light.

In a still further aspect of the present invention, there is also provided a fabrication method of a semiconductor integrated circuit device, which comprises using a first photomask which has, as a blocker against an exposure light, an organic material containing an organic photosensitive resin upon exposure treatment in a step of forming patterns relating to the constitution of a logic circuit, while using a second photomask which has a metal film as a blocker against an exposure light upon exposure treatment in a step of forming patterns relating to a unit cell.

In a still further aspect of the present invention, there is also provided a fabrication method of a semiconductor integrated circuit device having an ROM, which comprises using a first photomask having, as a blocker against an exposure light, an organic material containing an organic photosensitive resin upon exposure treatment for forming patterns relating to data writing of the ROM; and using a second photomask having a metal as a blocker against an exposure light upon exposure treatment for forming patterns other than those relating to data writing.

In a still further aspect of the present invention, there is also provided a fabrication method of a semiconductor integrated circuit device, which comprises properly using, upon forming patterns of the semiconductor integrated circuit device, exposure treatment using a first photomask having, as a blocker against an exposure light, an organic material containing an organic photosensitive resin; exposure treatment using a second photomask having a metal film as a blocker against an exposure light; and direct writing treatment using an energy beam.

In a still further aspect of the present invention, there is also provided a fabrication method of a semiconductor integrated circuit device, which comprises forming a first photomask having, as a blocker against an exposure light, an organic material containing an organic photosensitive resin on a semiconductor-integrated-circuit-device evaluator's side; transferring predetermined patterns onto a semiconductor wafer by exposure treatment with the first photomask on a semiconductor-integrated-circuit-device maker's side; and evaluating the semiconductor wafer to which the predetermined patterns have been transferred on the semiconductor-integrated-circuit-device evaluator's side.

In a still further aspect of the present invention, there is also provided a fabrication method of a semiconductor integrated circuit device, which comprises using a photomask having a metal film as a blocker against an exposure light upon exposure treatment in a mass production step of the semiconductor integrated circuit device; discarding the photomask having a metal film as a blocker against an exposure light after completion of the mass production step of the semiconductor integrated circuit device; and when the semiconductor integrated circuit device is fabricated again after discarding the photomask, using another photomask having, as a blocker against an exposure light, an organic material containing an organic photosensitive resin upon exposure treatment.

In a still further aspect of the present invention, there is also provided a fabrication method of a semiconductor integrated circuit device, which comprises: using a first photomask having, as a blocker against an exposure light, an organic material containing an organic photosensitive resin upon exposure treatment prior to a mass production step of the semiconductor integrated circuit device; and using a second photomask having a metal film as a blocker against an exposure light upon exposure treatment in the mass production step of the semiconductor integrated circuit device, wherein said first photomask has, disposed thereon, a plurality of semiconductor chip transfer regions, and patterns having data of the same semiconductor integrated circuit device which are different each other are disposed in the transfer regions, respectively.

### DETAILED DESCRIPTION OF THE DRAWINGS

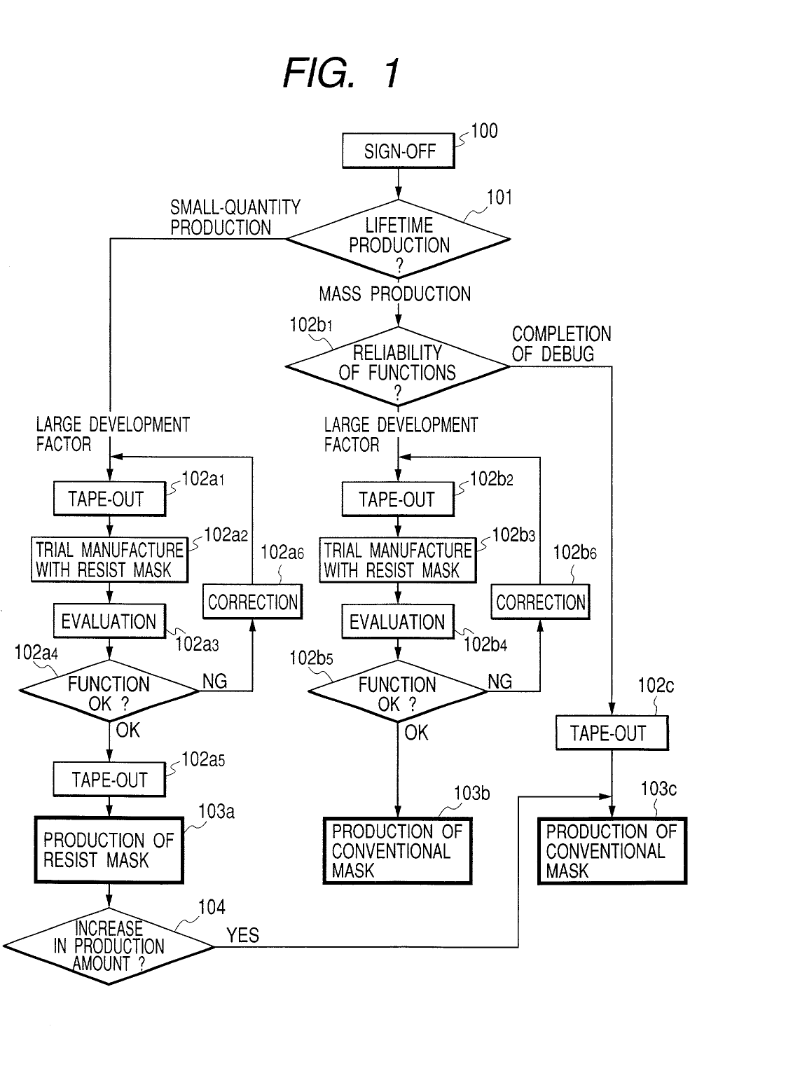

FIG. 1 is a production flow chart of a mask to be used in the fabrication step of the semiconductor integrated circuit device according to one embodiment of the present invention;

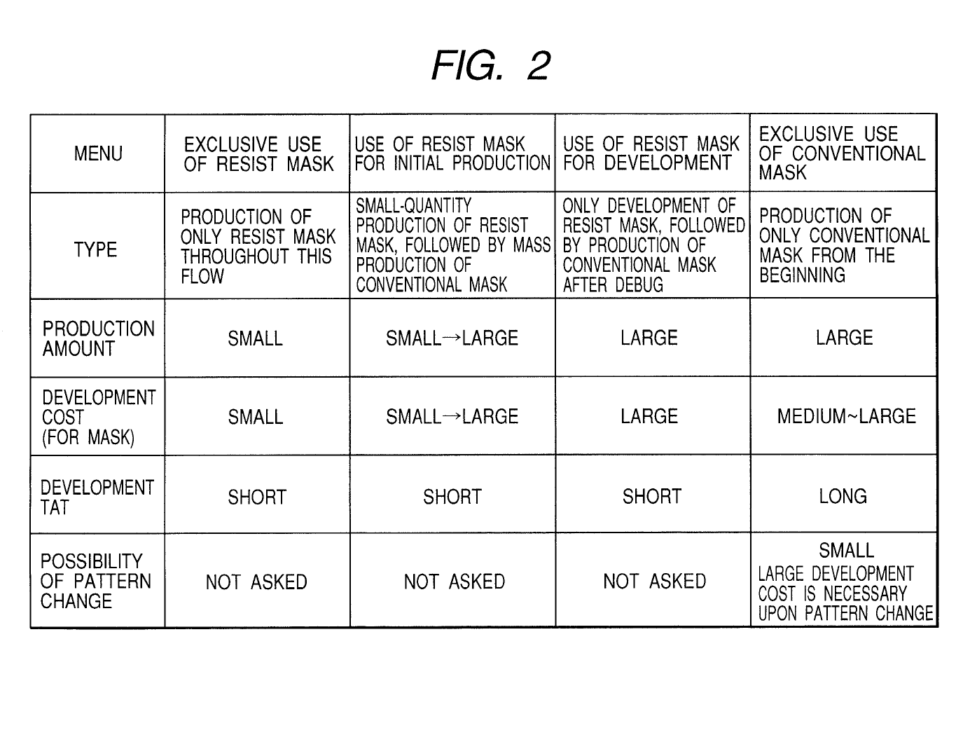

FIG. 2 illustrates on example of a production type menu in mask production of FIG. 1;

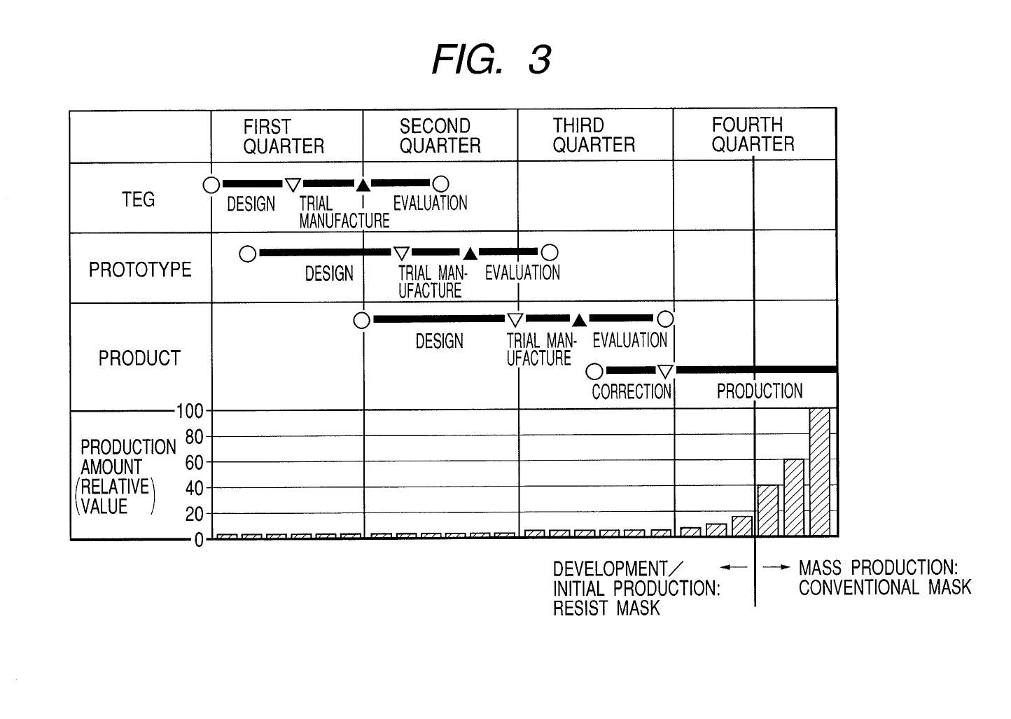

FIG. 3 illustrates one specific production example in the mask production of FIG. 1;

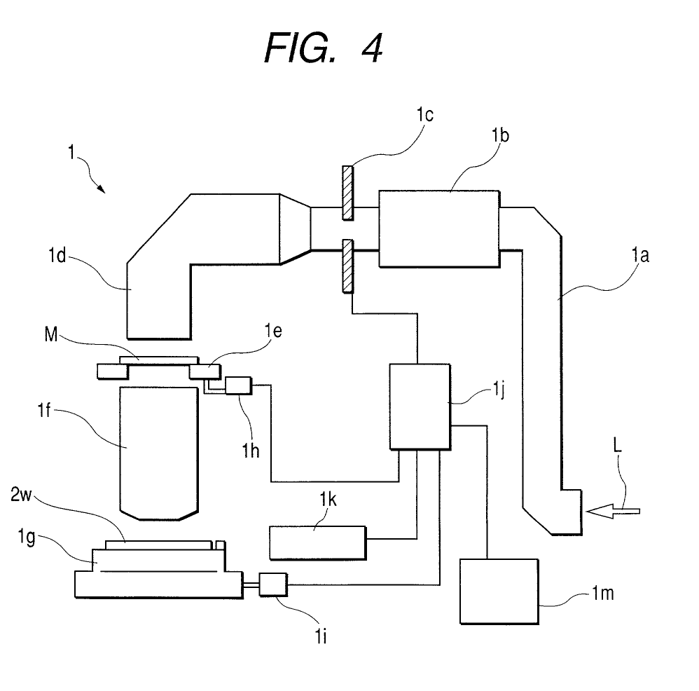

FIG. 4 illustrates one example of an exposure apparatus used in the fabrication step of the semiconductor integrated circuit device according to one embodiment of the present invention;

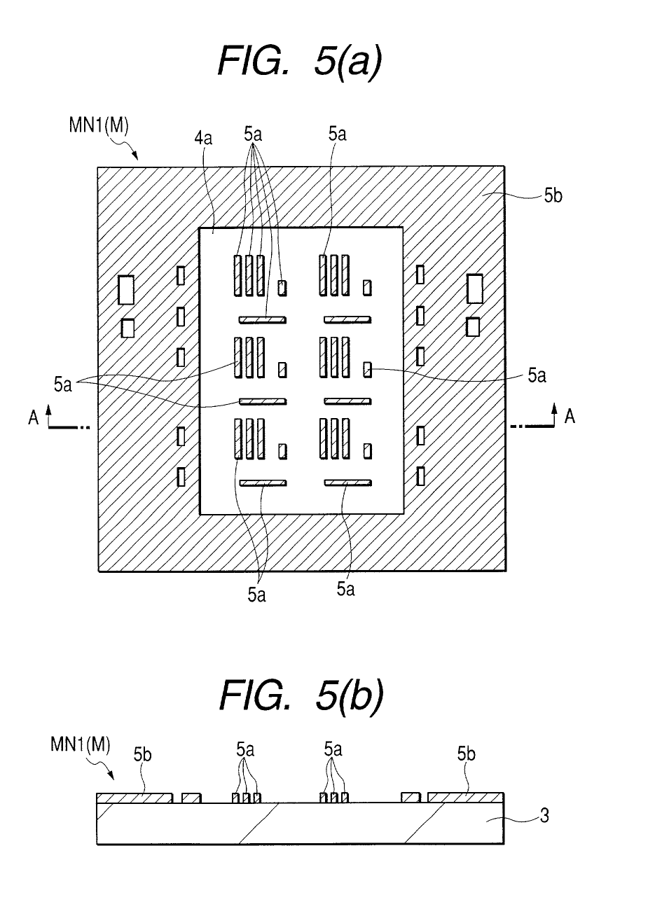

FIG. 5(a) is a plan view illustrating one example of a photomask used in the fabrication step of a semiconductor integrated circuit device; and FIG. 5(b) is a cross-sectional view taken along a line A-A of FIG. 5(a);

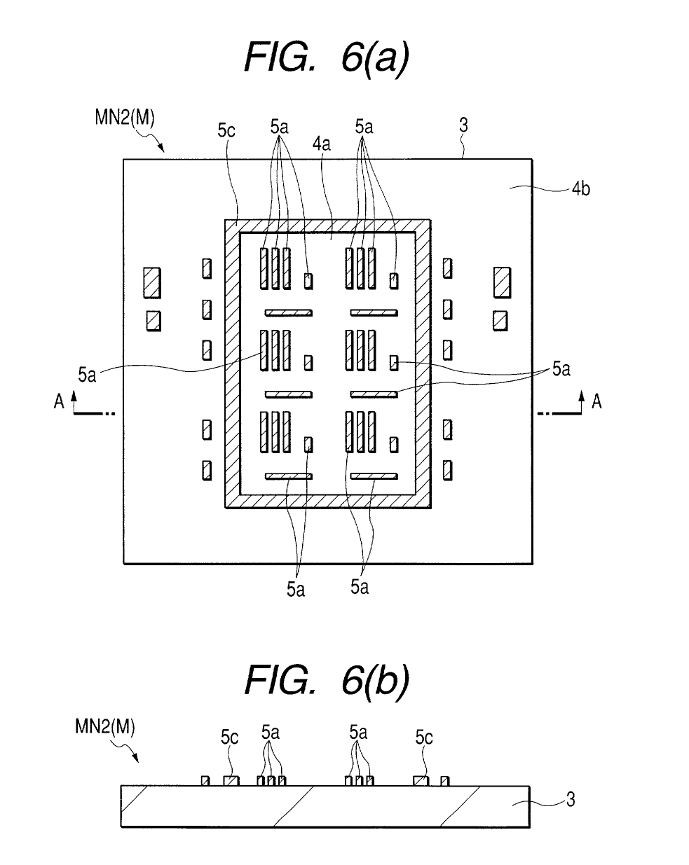

FIG. 6(a) is a plan view illustrating one example of a photomask used in the fabrication step of a semiconductor integrated circuit device; and FIG. 6(b) is a cross-sectional view taken along a line A-A of FIG. 6(a);

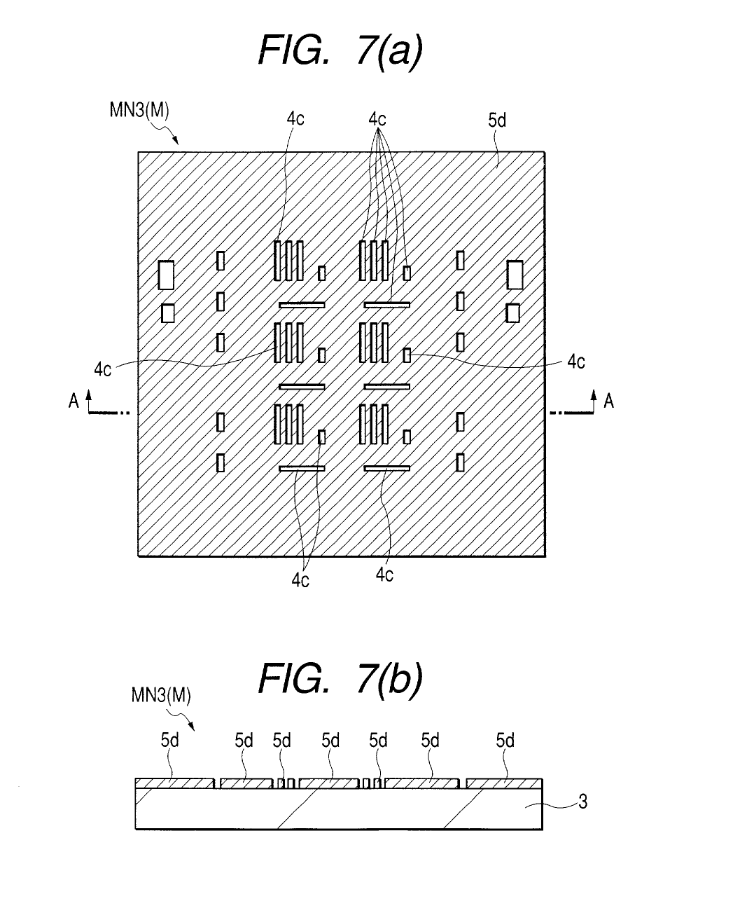

FIG. 7(a) is a plan view illustrating one example of a photomask used in the fabrication step of a semiconductor integrated circuit device; and FIG. 7(b) is a cross-sectional view taken along a line A-A of FIG. 7(a);

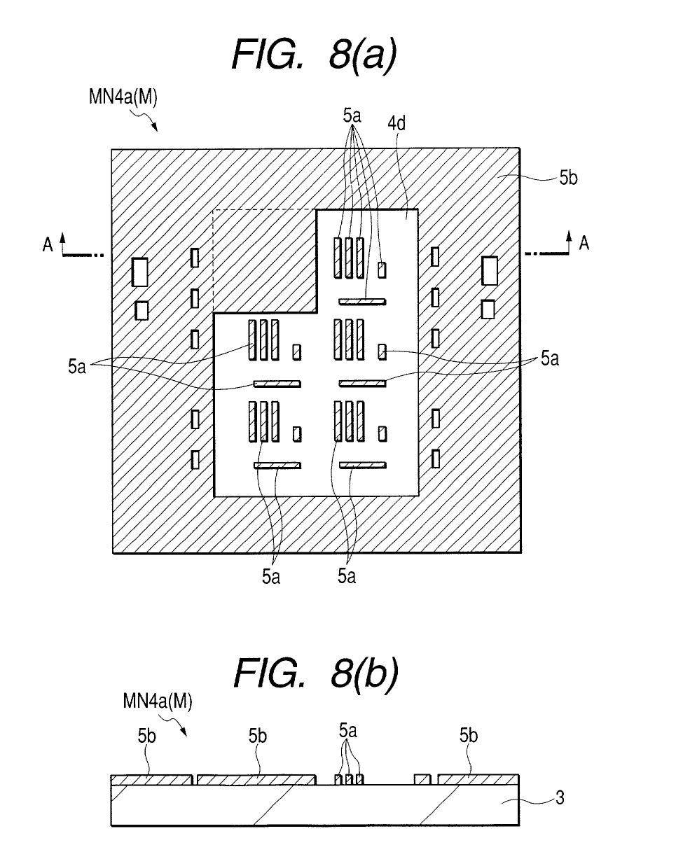

FIG. 8(a) is a plan view illustrating one example of a photomask used in the fabrication step of a semiconductor integrated circuit device; and FIG. 8(b) is a cross-sectional view taken along a line A-A of FIG. 8(a);

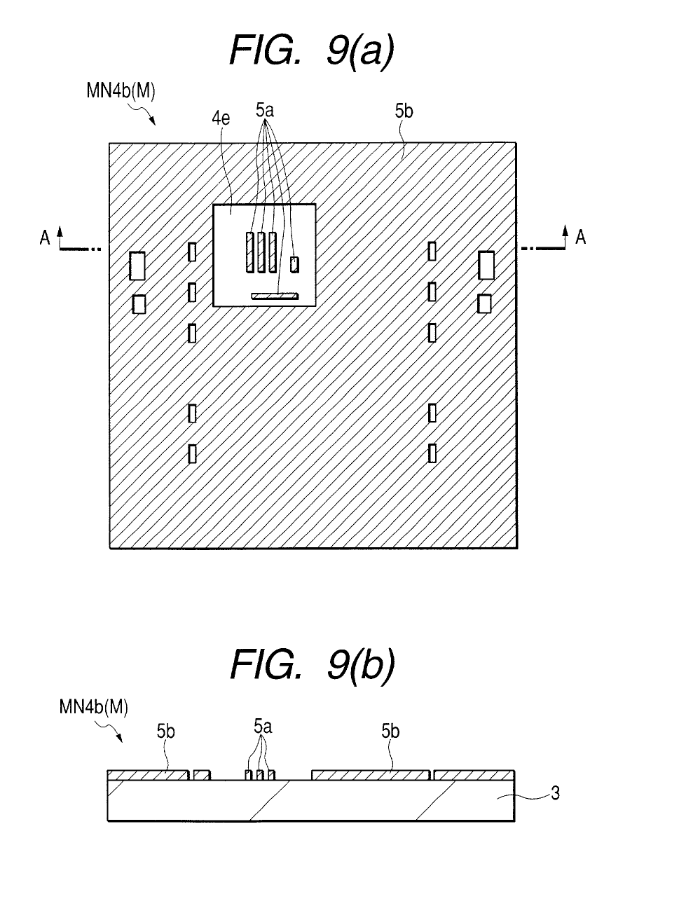

FIG. 9(a) is a plan view illustrating one example of a photomask used in the fabrication step of a semiconductor integrated circuit device; and FIG. 9(b) is a cross-sectional view taken along a line A-A of FIG. 9(a);

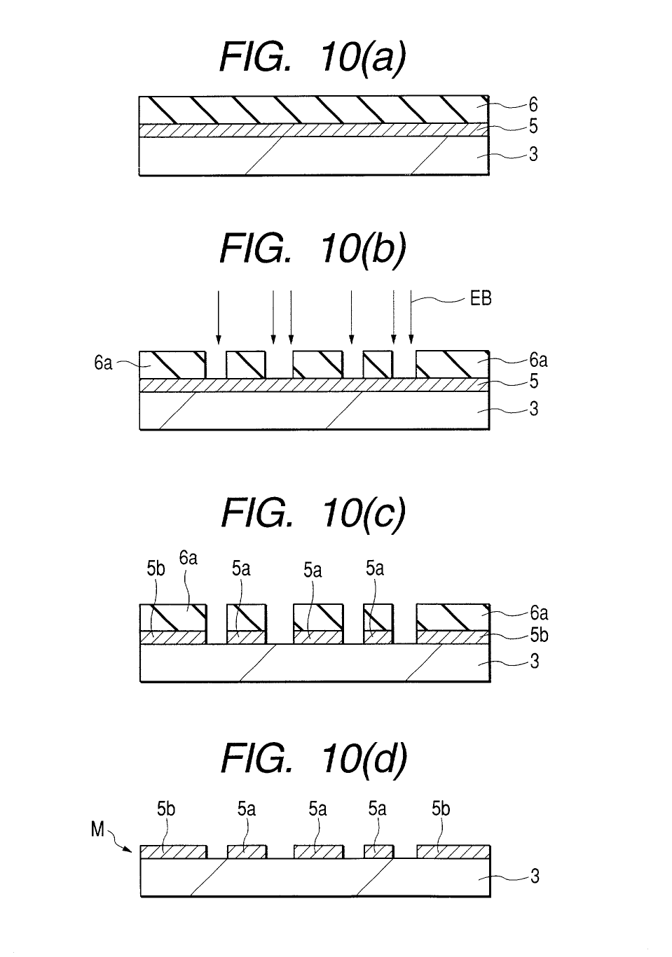

FIGS. 10 (a) to 10(d) are each a cross-sectional view illustrating a conventional photomask during its manufacturing step;

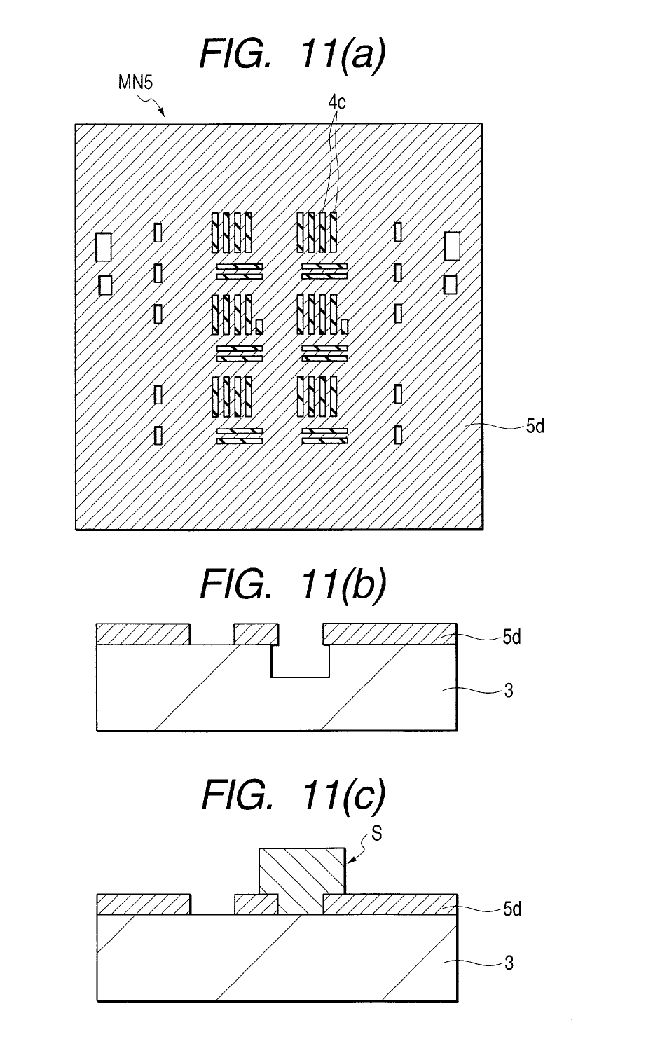

FIG. 11(a) is a plan view illustrating one example of a photomask used in the fabrication step of a semiconductor integrated circuit device; FIG. 11(b) is a fragmentary cross-sectional view of FIG. 11(a); and FIG. 11(c) is a modification example of FIG. 11(b) and at the same time, a fragmentary cross-sectional view of FIG. 11(a);

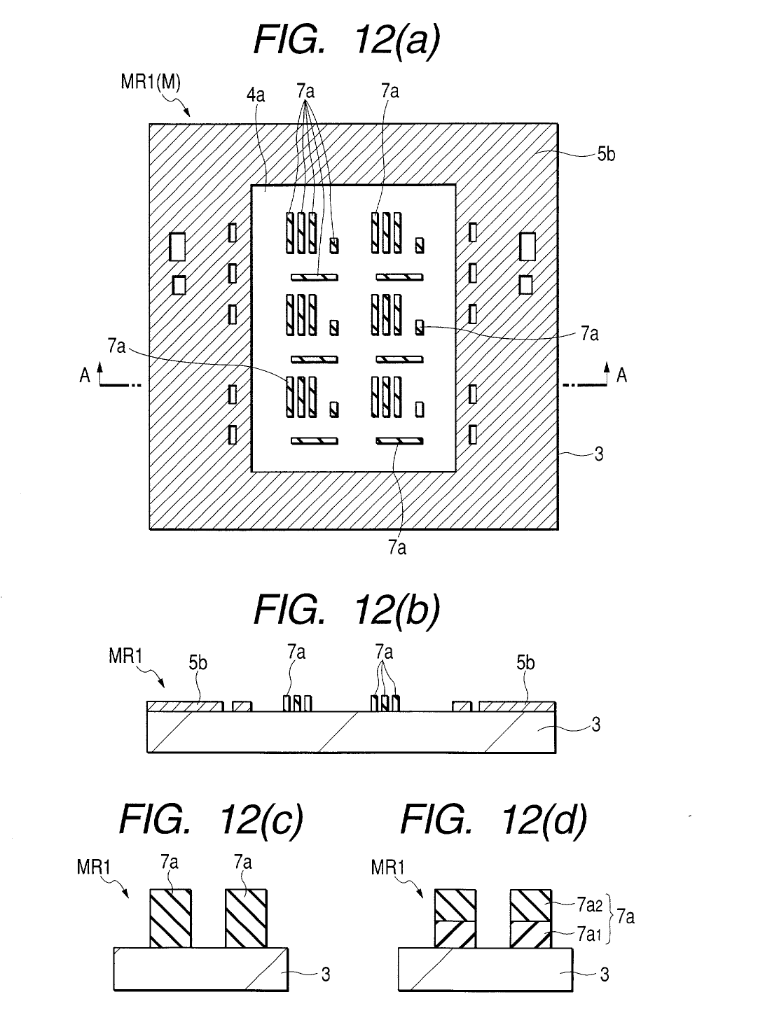

FIG. 12(a) is a plan view illustrating one example of a photomask used in the fabrication step of a semiconductor integrated circuit device, FIG. 11(b) is a cross-sectional view taken along a line A-A of FIG. 12(a), FIG. 11(c) is a fragmentary enlarged cross-sectional view of FIG. 12(b); and FIG. 11(d) is a modification example of a light blocker and at the same time, a fragmentary enlarged cross-sectional view of FIG. 12(b);

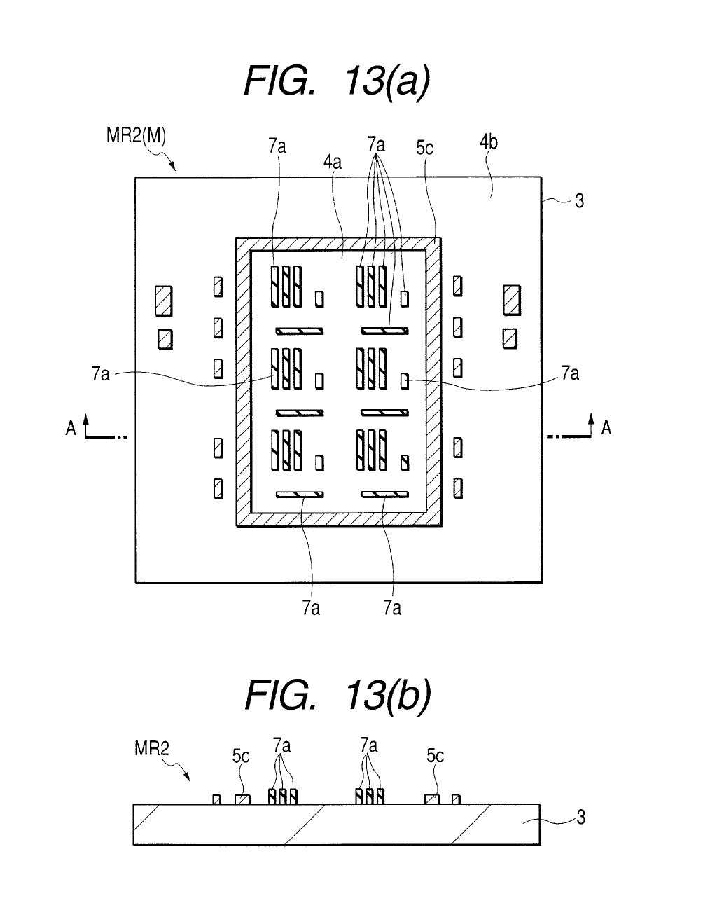

FIG. 13(a) is a plan view illustrating one example of a photomask used in the fabrication step of a semiconductor integrated circuit device, and FIG. 13(b) is a cross-sectional view taken along a line A-A of FIG. 13(a);

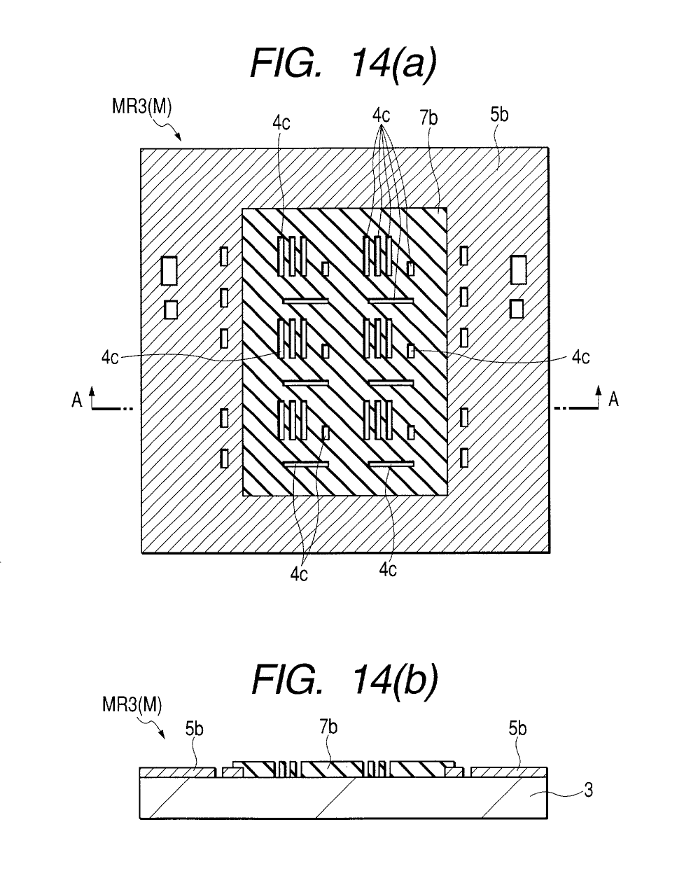

FIG. 14(a) is a plan view illustrating one example of a photomask used in the fabrication step of a semiconductor integrated circuit device, and FIG. 14(b) is a cross-sectional view taken along a line A-A of FIG. 14(a);

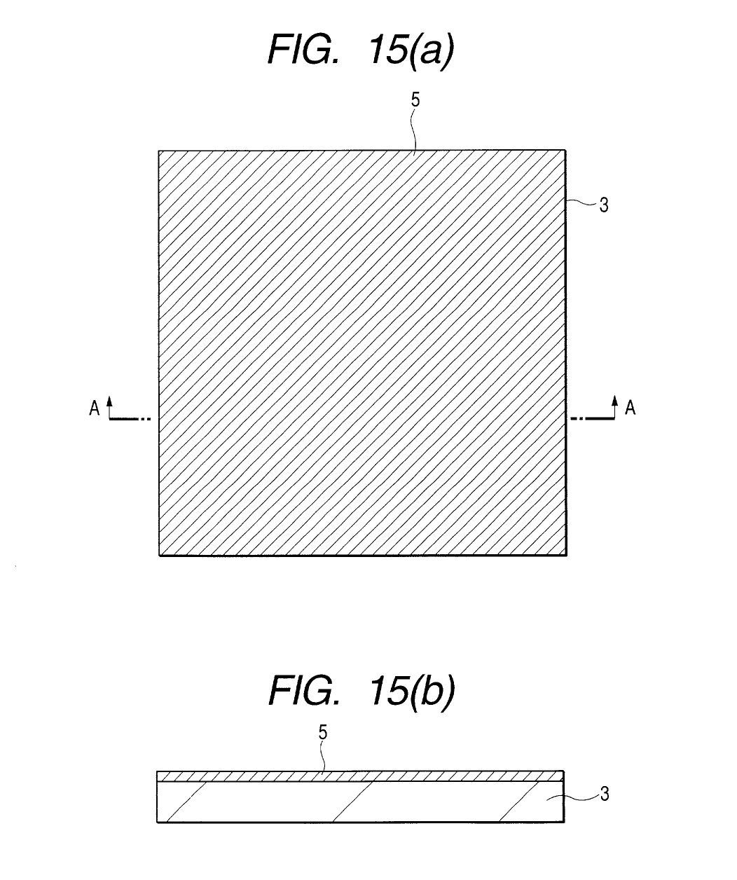

FIG. 15(a) is a plan view of the photomask of FIG. 12 during its fabrication step, and FIG. 15(b) is a cross-sectional view taken along a line of A-A of FIG. 15(a);

FIG. 16(a) is a plan view of the photomask of FIG. 12 during its fabrication step following the step of FIG. 15, and FIG. 16(b) is a cross-sectional view taken along a line of A-A of FIG. 16(a);

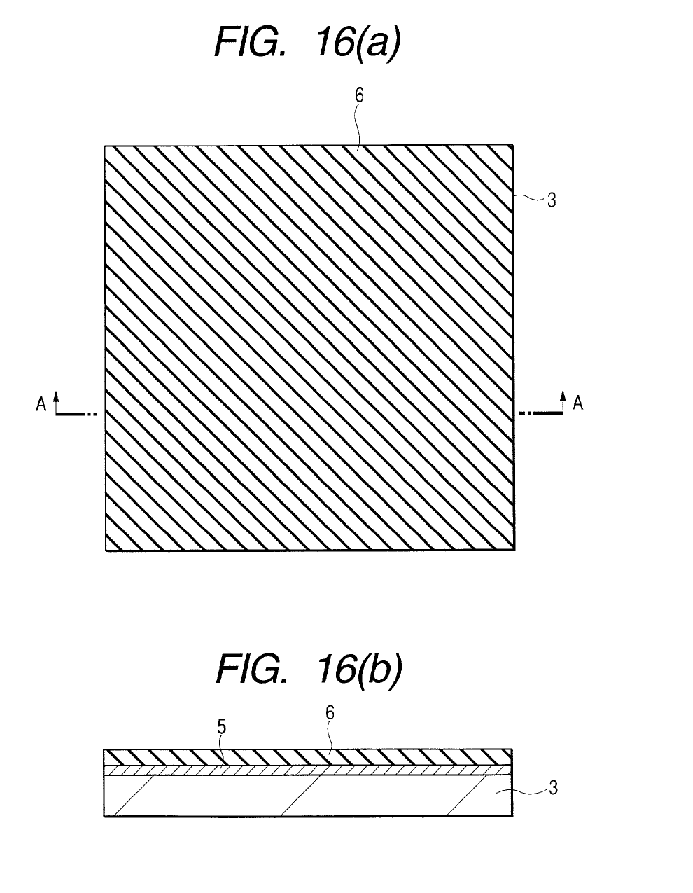

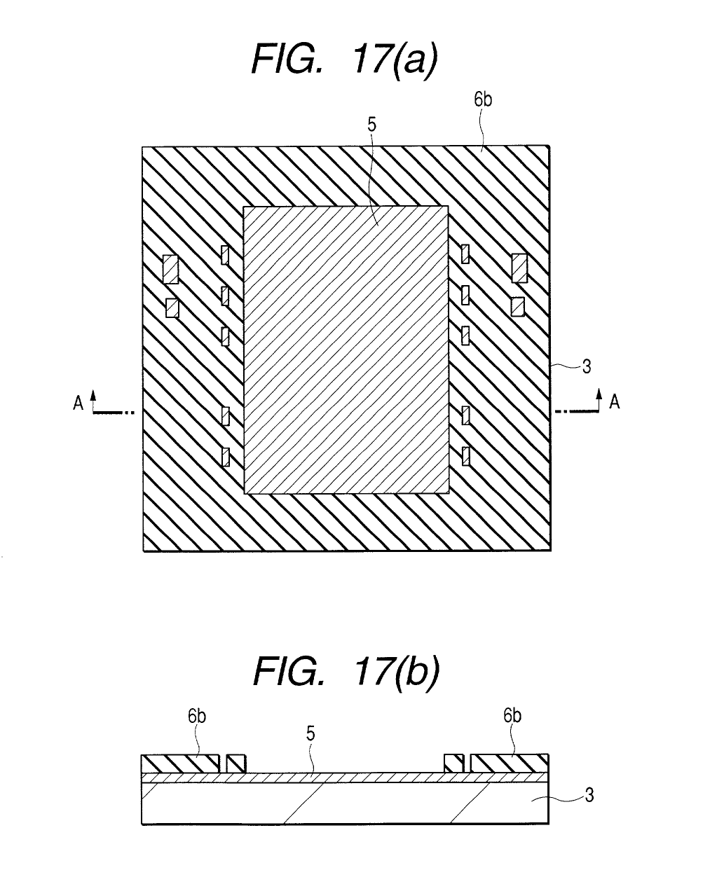

FIG. 17(a) is a plan view of the photomask of FIG. 12 during its fabrication step following the step of FIG. 16, and FIG. 17(b) is a cross-sectional view taken along a line of A-A of FIG. 17(a);

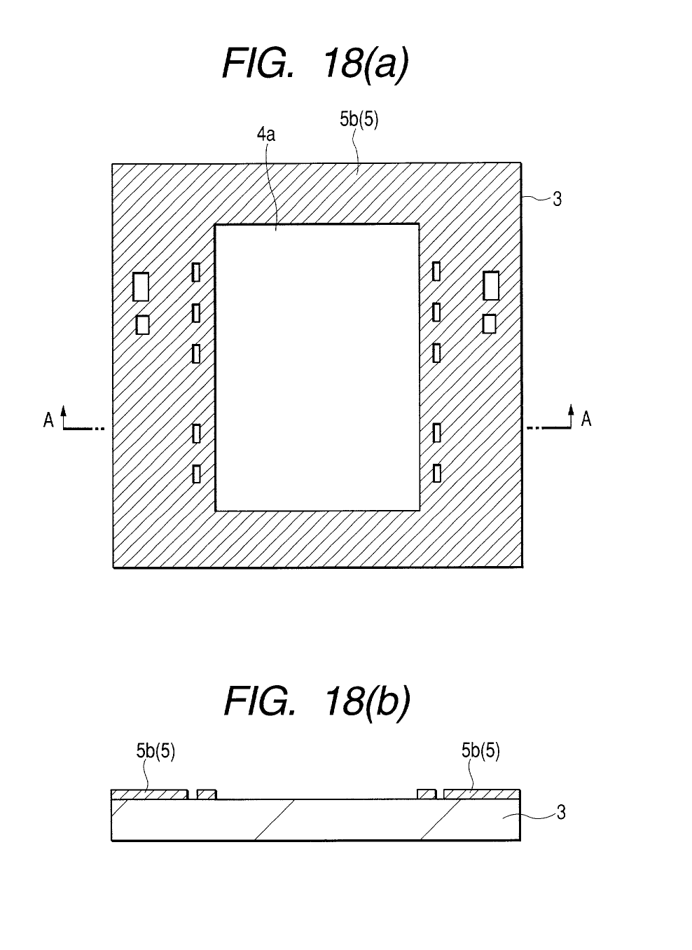

FIG. 18(a) is a plan view of the photomask of FIG. 12 during its fabrication step following the step of FIG. 17, and FIG. 18(b) is a cross-sectional view taken along a line of A-A of FIG. 18(a);

FIG. 19(a) is a plan view of the photomask of FIG. 12 during its fabrication step following the step of FIG. 18, and FIG. 19(b) is a cross-sectional view taken along a line of A-A of FIG. 19(a);

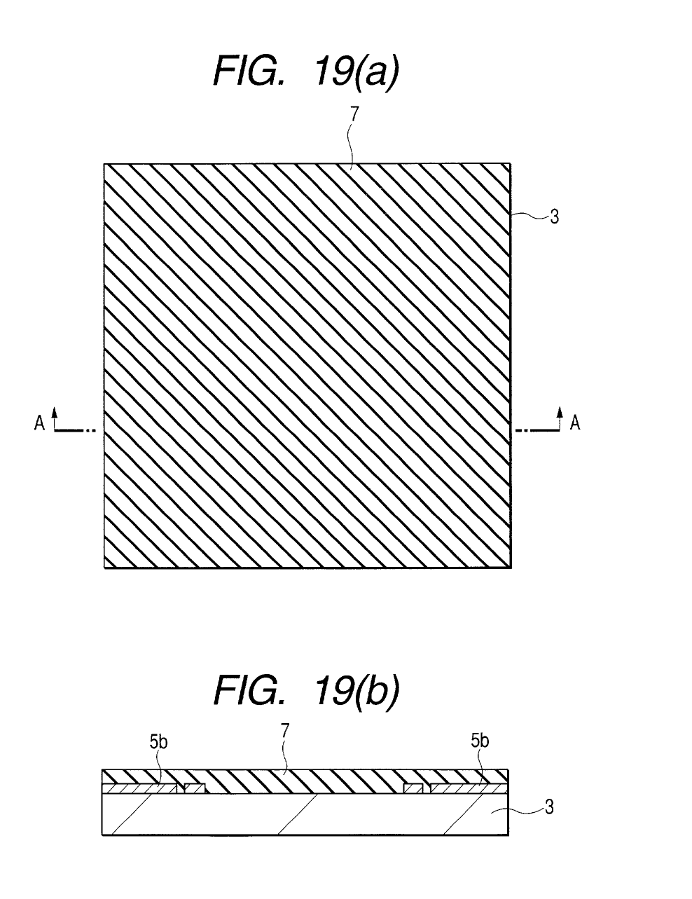

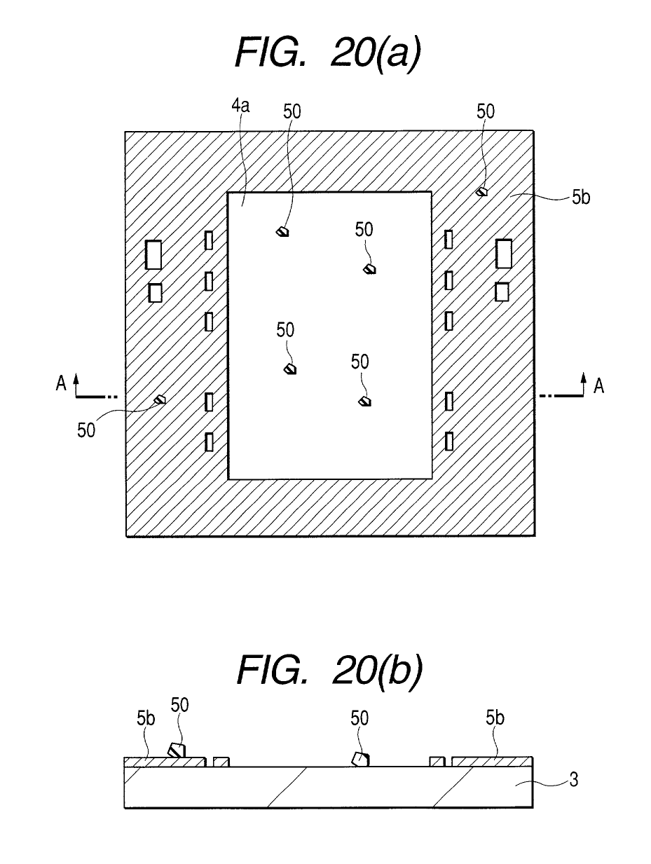

FIG. 20(a) is a plan view of the photomask of FIG. 12 during its re-fabrication step, and FIG. 20(b) is a cross-sectional view taken along a line of A-A of FIG. 20(a);

FIG. 21(a) is a plan view of the photomask of FIG. 12 during its re-fabrication step following the step of FIG. 20, and FIG. 21(b) is a cross-sectional view taken along a line of A-A of FIG. 21(a);

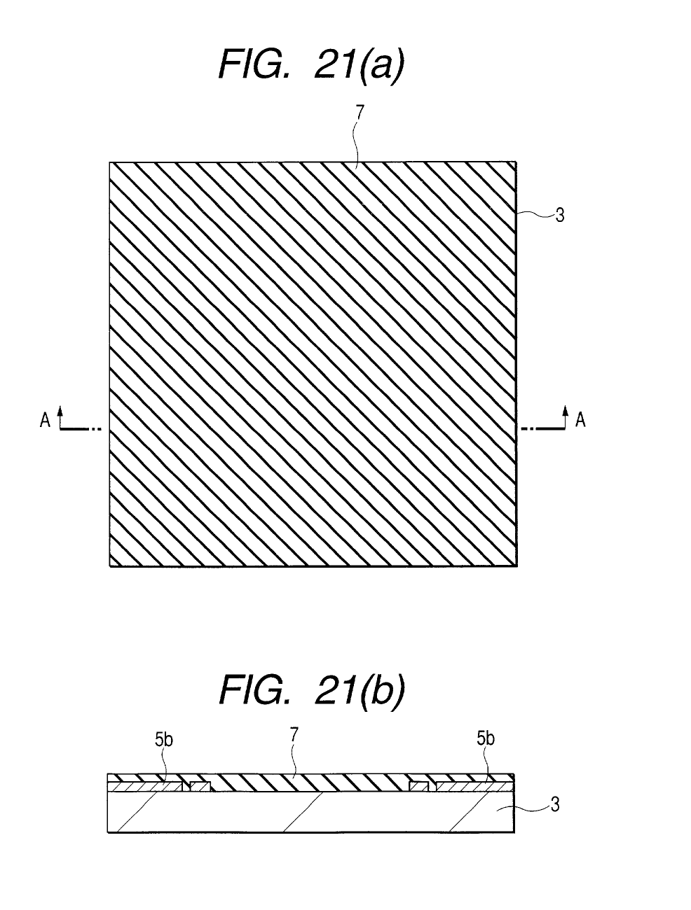

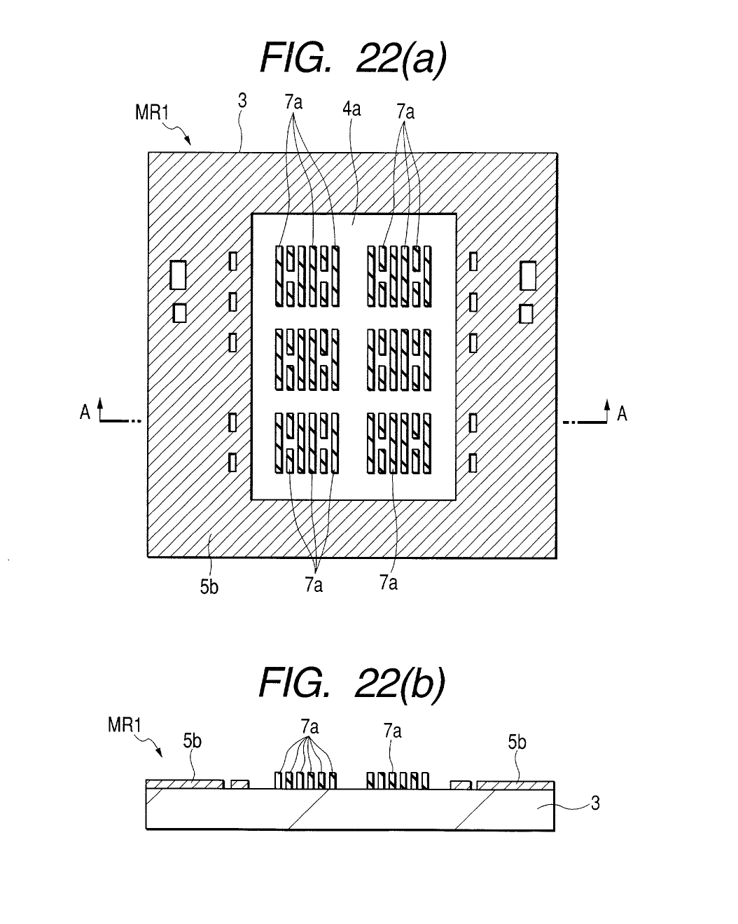

FIG. 22(a) is a plan view of the photomask of FIG. 12 during its re-fabrication step following the step of FIG. 21, and FIG. 22(b) is a cross-sectional view taken along a line of A-A of FIG. 22(a);

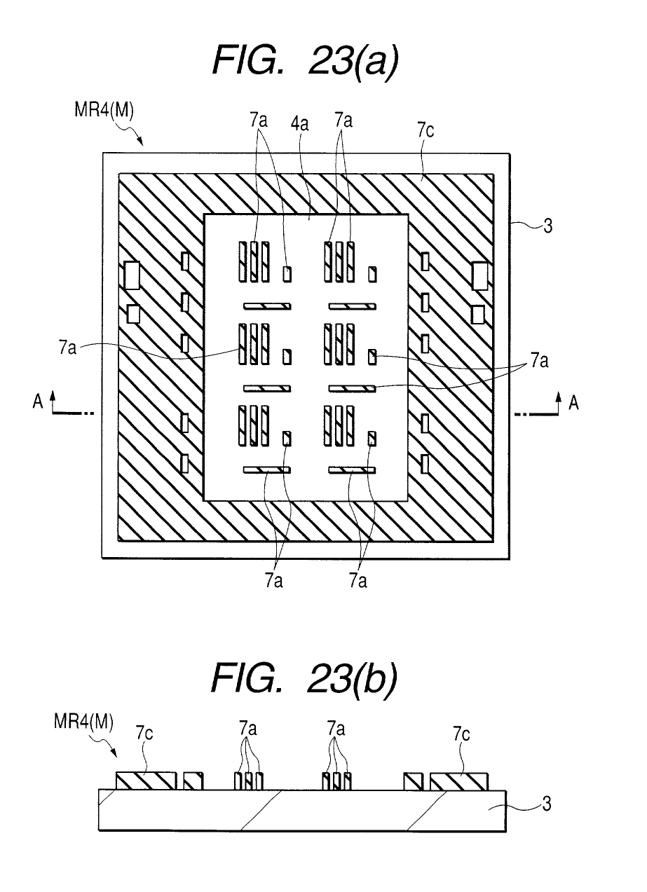

FIG. 23(a) is a plan view illustrating one example of a photomask used in the fabrication step of a semiconductor integrated circuit device, and FIG. 23(b) is a cross-sectional view taken along a line of A-A of FIG. 23(a);

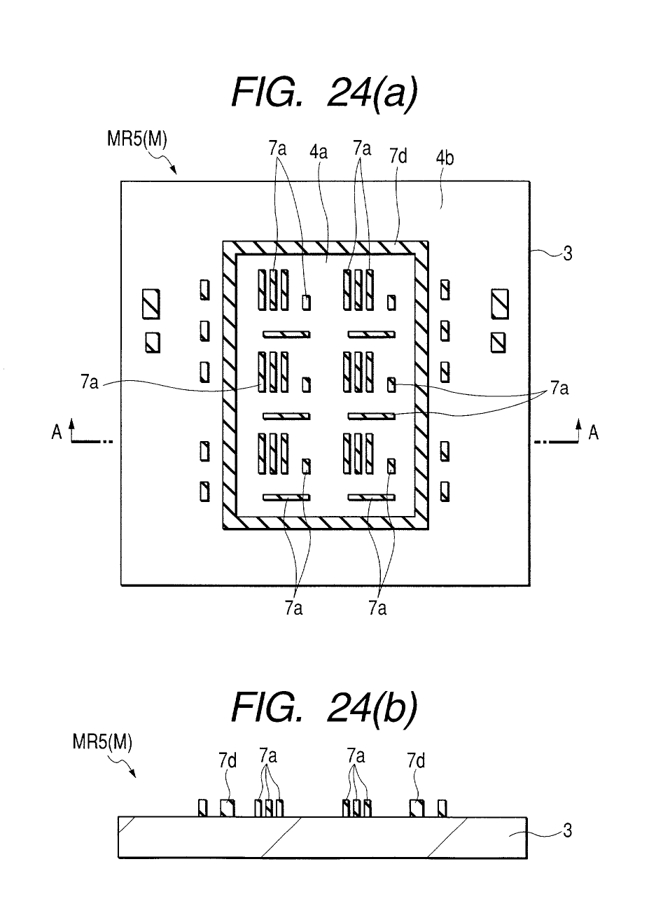

FIG. 24(a) is a plan view illustrating one example of a photomask used in the fabrication step of a semiconductor integrated circuit device, and FIG. 24(b) is a cross-sectional view taken along a line of A-A of FIG. 24(a);

FIG. 25(a) is a plan view illustrating one example of a photomask used in the fabrication step of a semiconductor integrated circuit device, and FIG. 25(b) is a cross-sectional view taken along a line of A-A of FIG. 25(a);

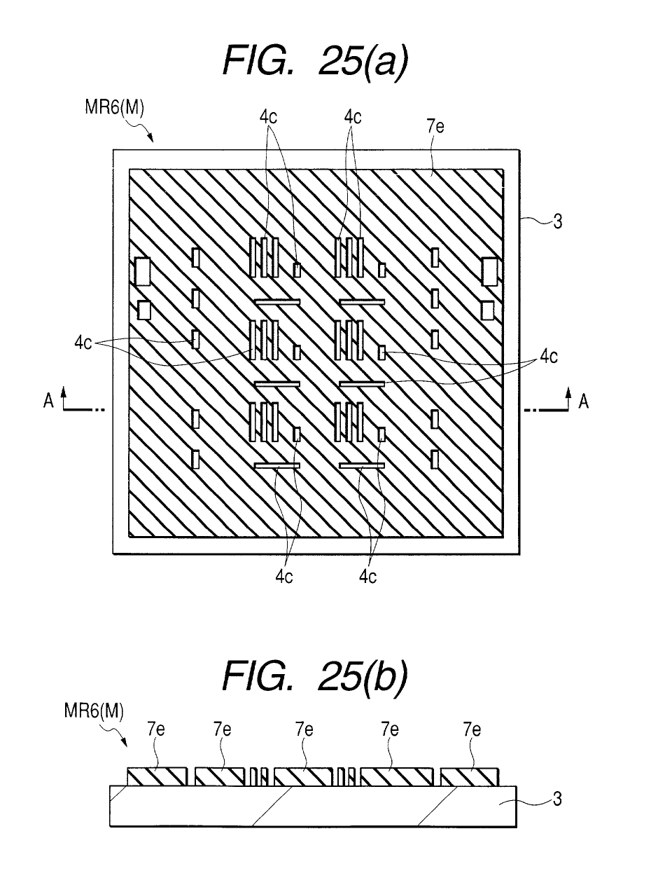

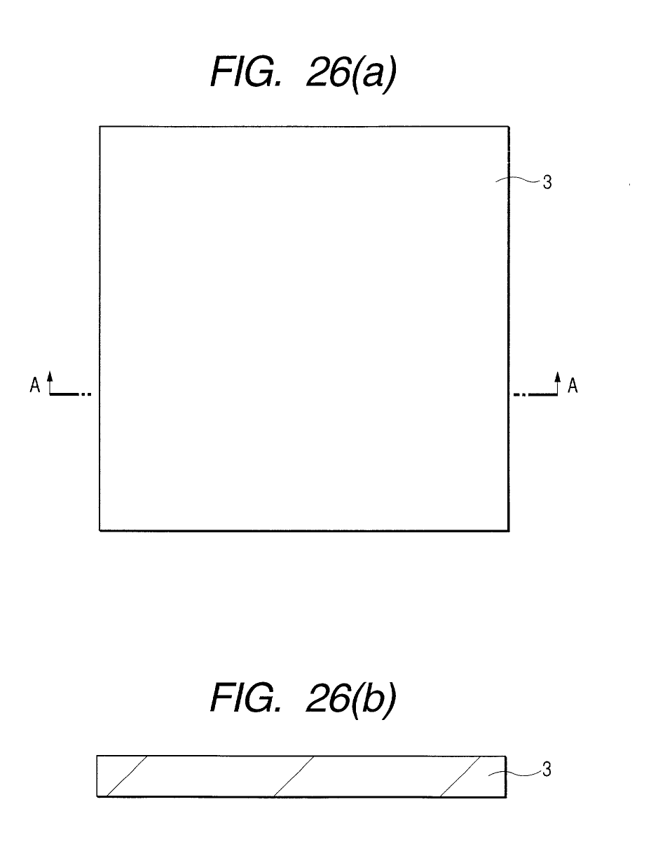

FIG. 26(a) is a plan view illustrating the photomask of FIG. 23 during its fabrication step, and FIG. 26(b) is a cross-sectional view taken along a line of A-A of FIG. 26(a);

FIG. 27(a) is a plan view illustrating the photomask of FIG. 23 during its fabrication step following the step of FIG. 26, and FIG. 27(b) is a cross-sectional view taken along a line of A-A of FIG. 27(a);

FIG. 28(a) is a plan view illustrating the photomask of FIG. 23 during its re-fabrication step, and FIG. 28(b) is a cross-sectional view taken along a line of A-A of FIG. 28(a);

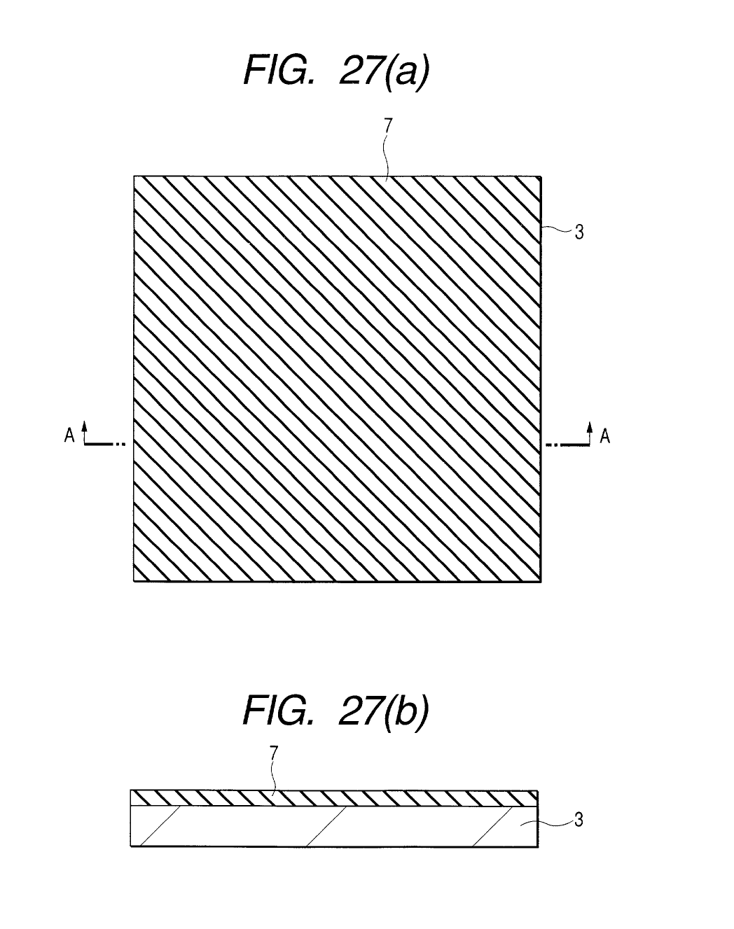

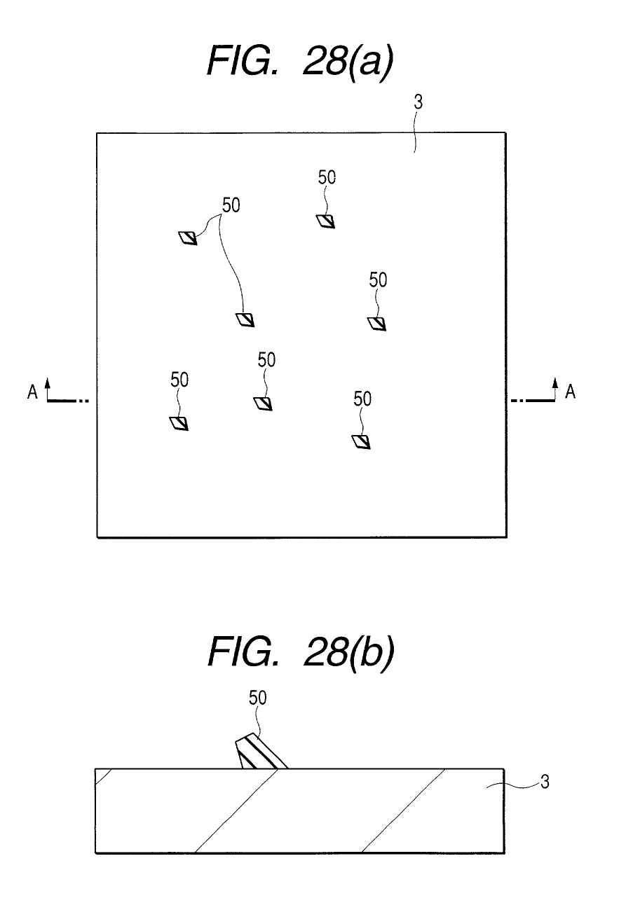

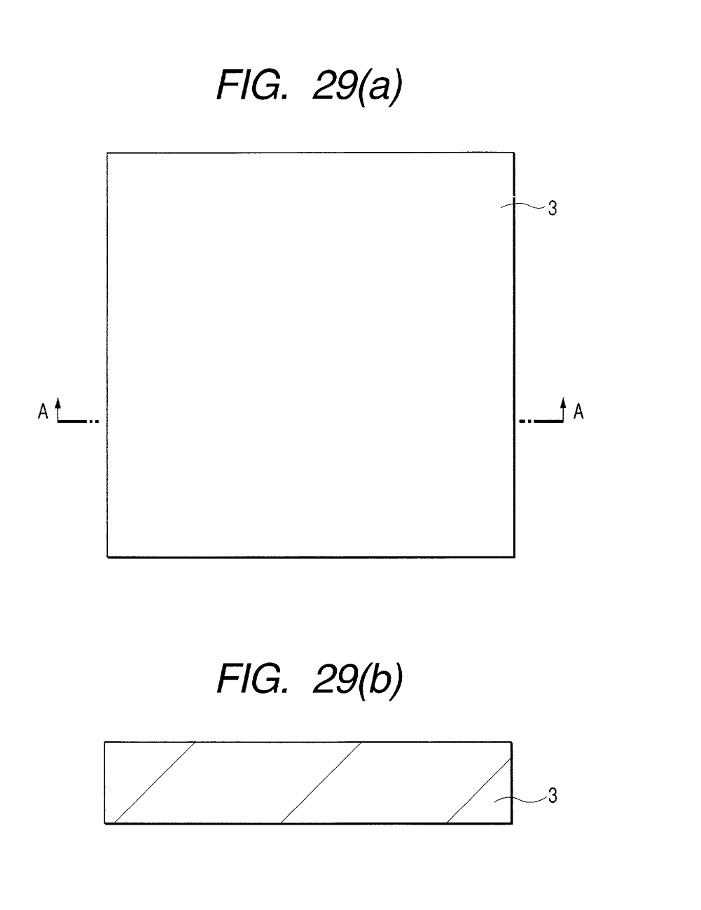

FIG. 29(a) is a plan view illustrating the photomask of FIG. 23 during its re-fabrication step following the step of FIG. 28, and FIG. 29(b) is a cross-sectional view taken along a line of A-A of FIG. 29(a);

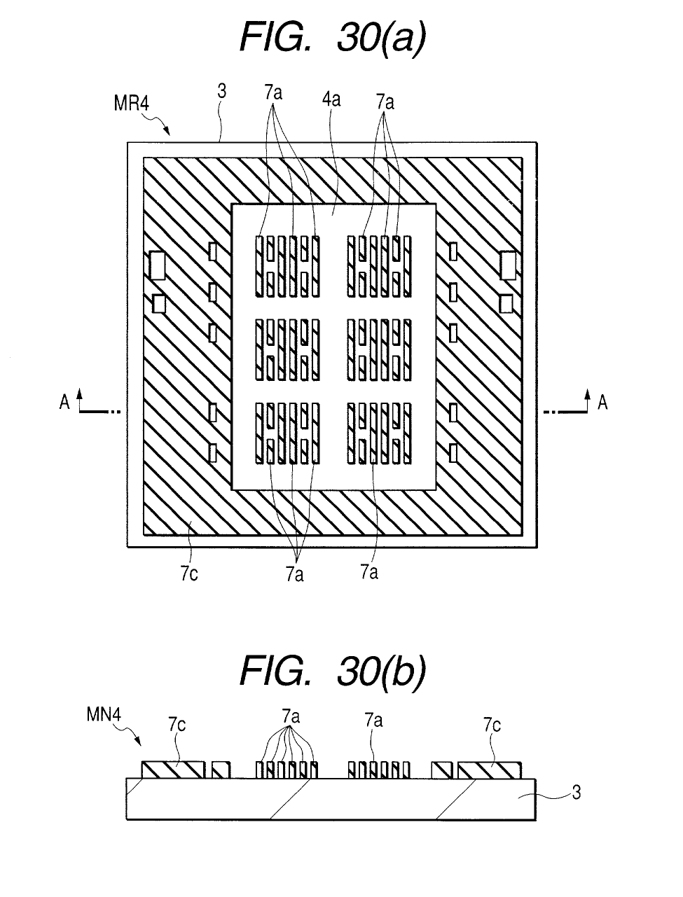

FIG. 30(a) is a plan view illustrating the photomask of FIG. 23 during its re-fabrication step following the step of FIG. 29, and FIG. 30(b) is a cross-sectional view taken along a line of A-A of FIG. 30(a);

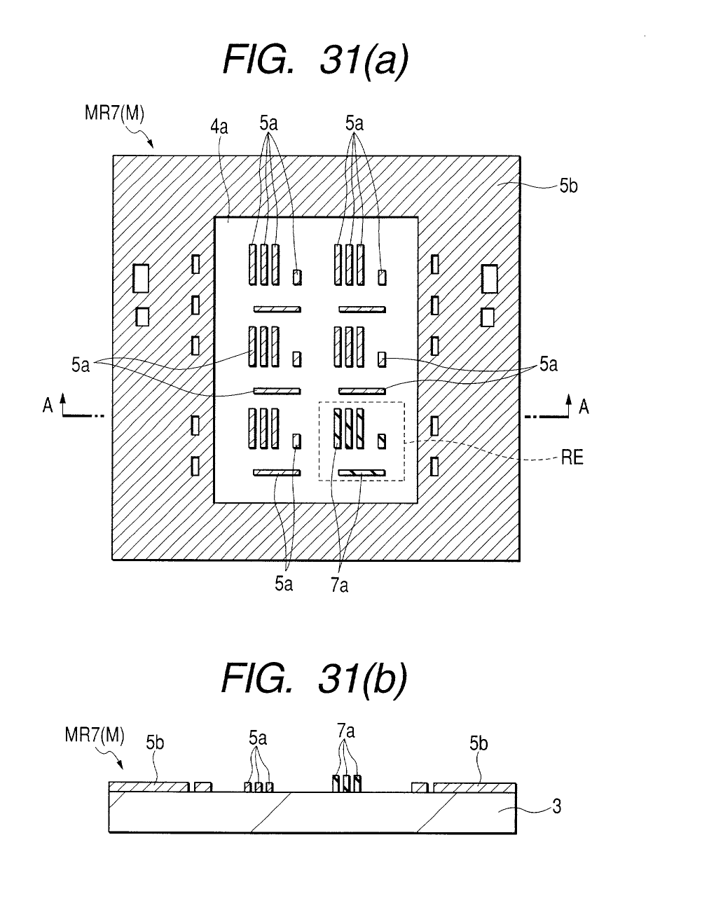

FIG. 31(a) is a plan view illustrating one example of a photomask used in the fabrication step of a semiconductor integrated circuit device, and FIG. 31(b) is a cross-sectional view taken along a line of A-A of FIG. 31(a);

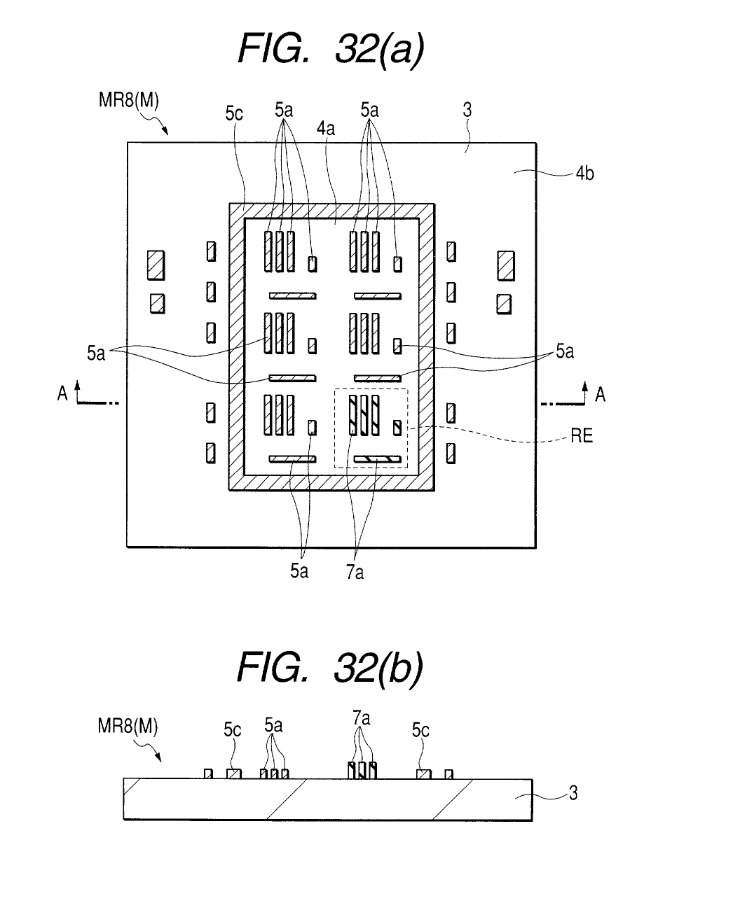

FIG. 32(a) is a plan view illustrating one example of a photomask used in the fabrication step of a semiconductor integrated circuit device, and FIG. 32(b) is a cross-sectional view taken along a line of A-A of FIG. 32(a);

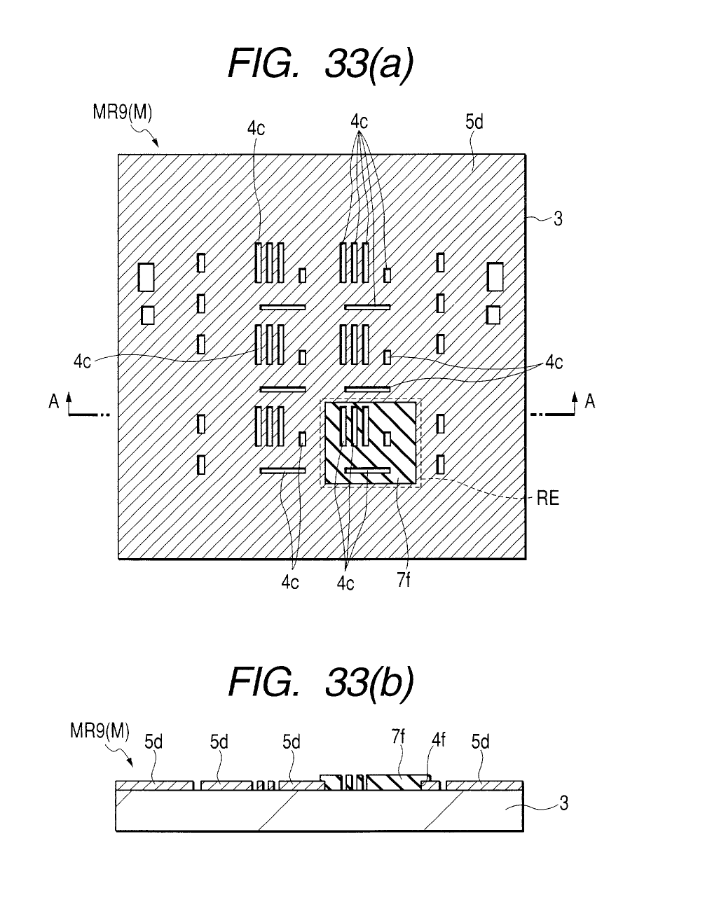

FIG. 33(a) is a plan view illustrating one example of a photomask used in the fabrication step of a semiconductor integrated circuit device, and FIG. 33(b) is a cross-sectional view taken along a line of A-A of FIG. 33(a);

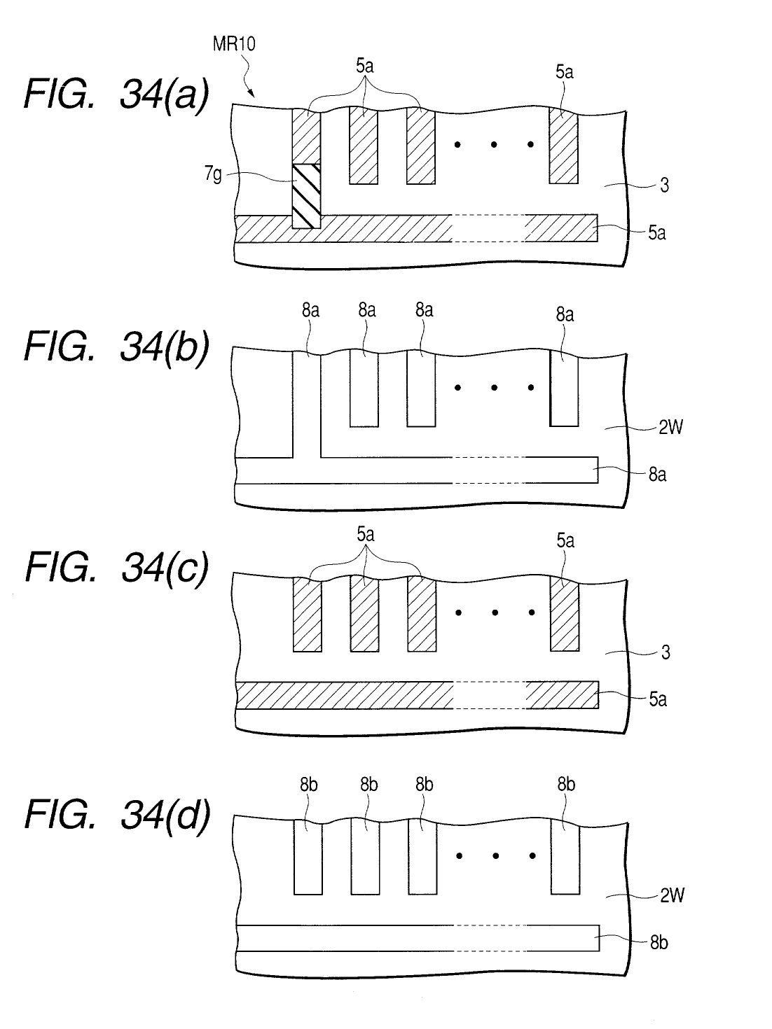

FIG. 34(a) is a fragmentary plan view illustrating one example of a photomask used in the fabrication step of a semiconductor integrated circuit device, FIG. 34(b) is a fragmentary plan view of a semiconductor wafer illustrating patterns to be transferred through the photomask of FIG. 34(a), FIG. 34(c) is a fragmentary plan view illustrating the state of the photomask of FIG. 34(a) after removal of a light blocker made of an organic material containing an organic photosensitive resin; and FIG. 34(d) is a fragmentary plan view of the semiconductor wafer illustrating patterns to be transferred onto the semiconductor wafer through the photomask of FIG. 34(c);

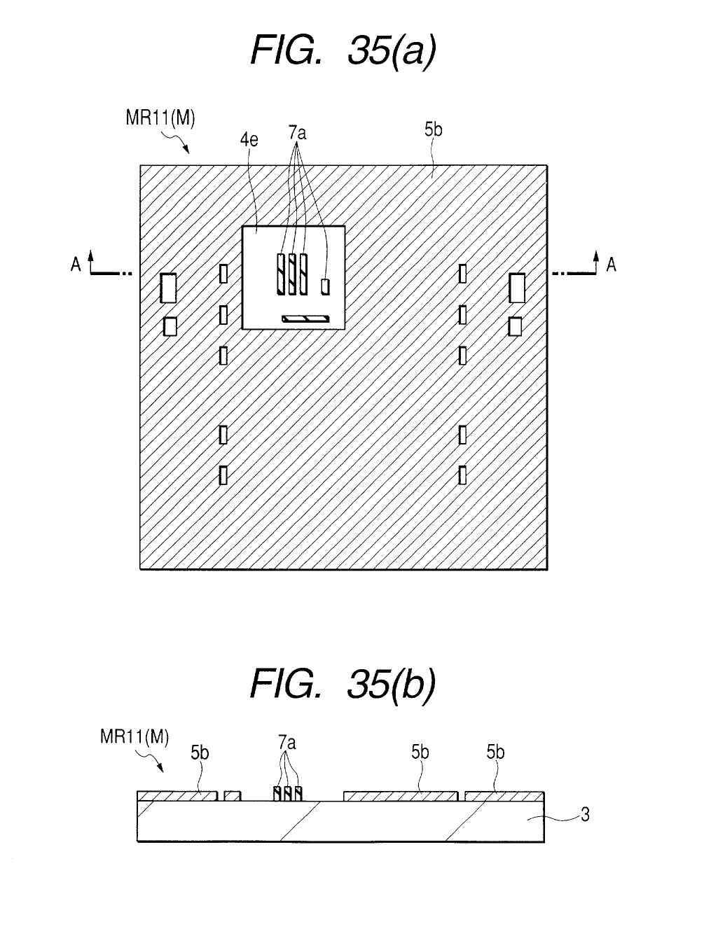

FIG. 35(a) is a plan view illustrating one example of a photomask used in the fabrication step of a semiconductor integrated circuit device, and FIG. 35(b) is a cross-sectional view taken along a line A-A of FIG. 35(a);

FIG. 36(a) is a plan view of the photomask of FIG. 31 during its fabrication step and FIG. 36(b) is a cross-sectional view taken along a line A-A of FIG. 36(a);

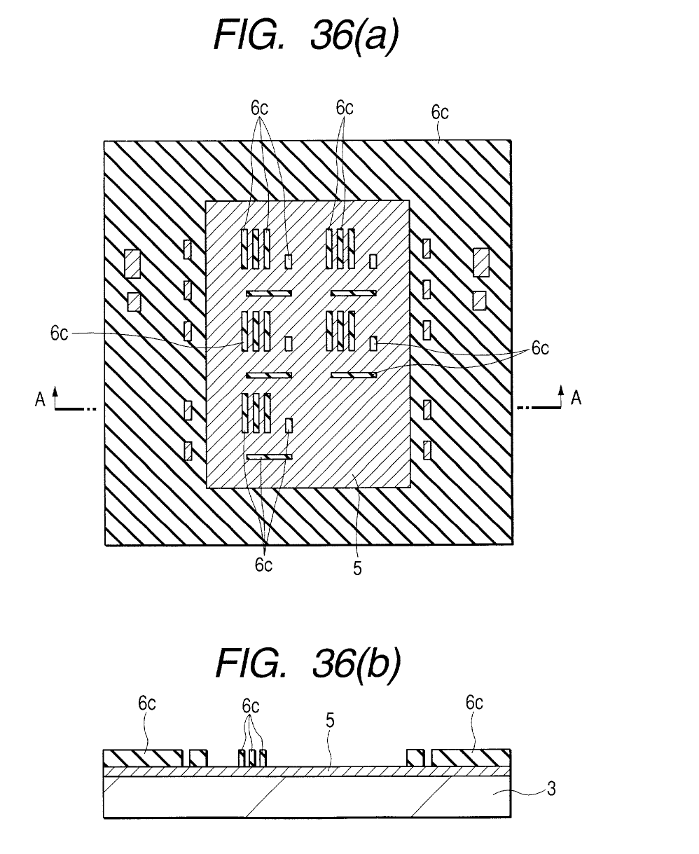

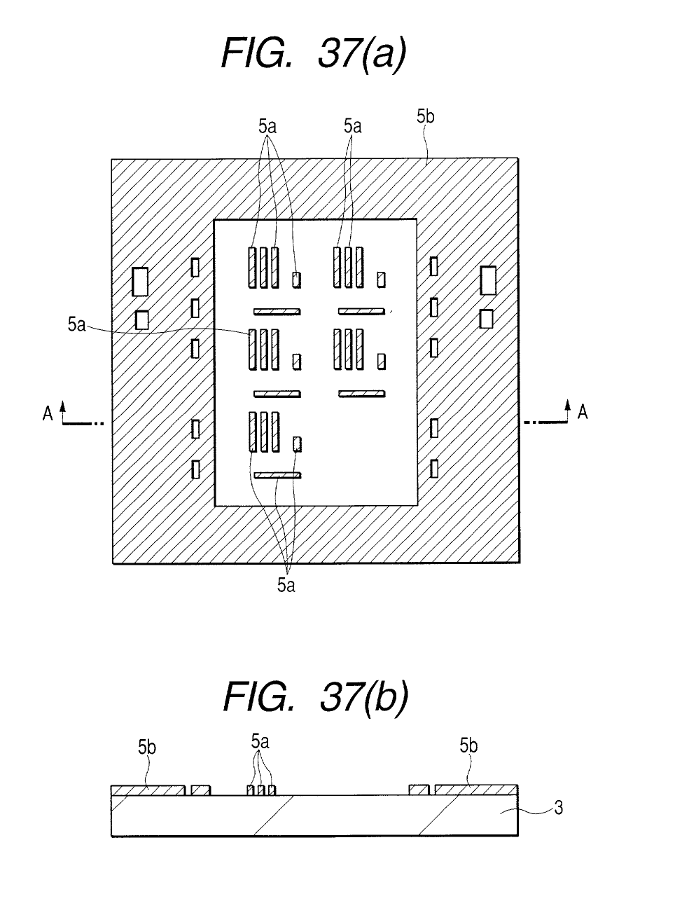

FIG. 37(a) is a plan view of the photomask of FIG. 31 during its fabrication step following the step of FIG. 36 and FIG. 37(b) is a cross-sectional view taken along a line A-A of FIG. 37 (a);

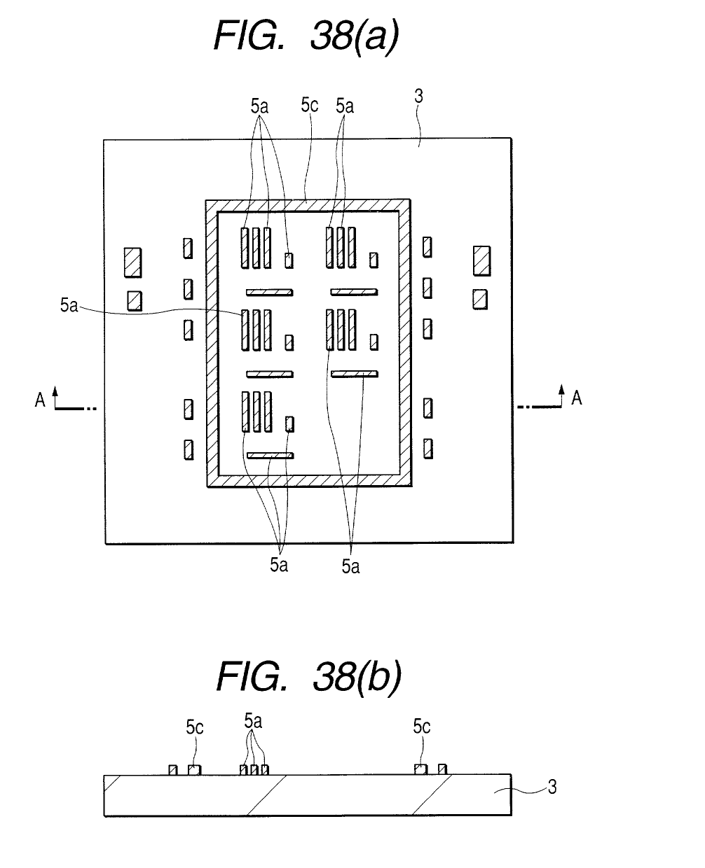

FIG. 38(a) is a plan view of the photomask of FIG. 32 during its fabrication step and FIG. 38(b) is a cross-sectional view taken along a line A-A of FIG. 38(a);

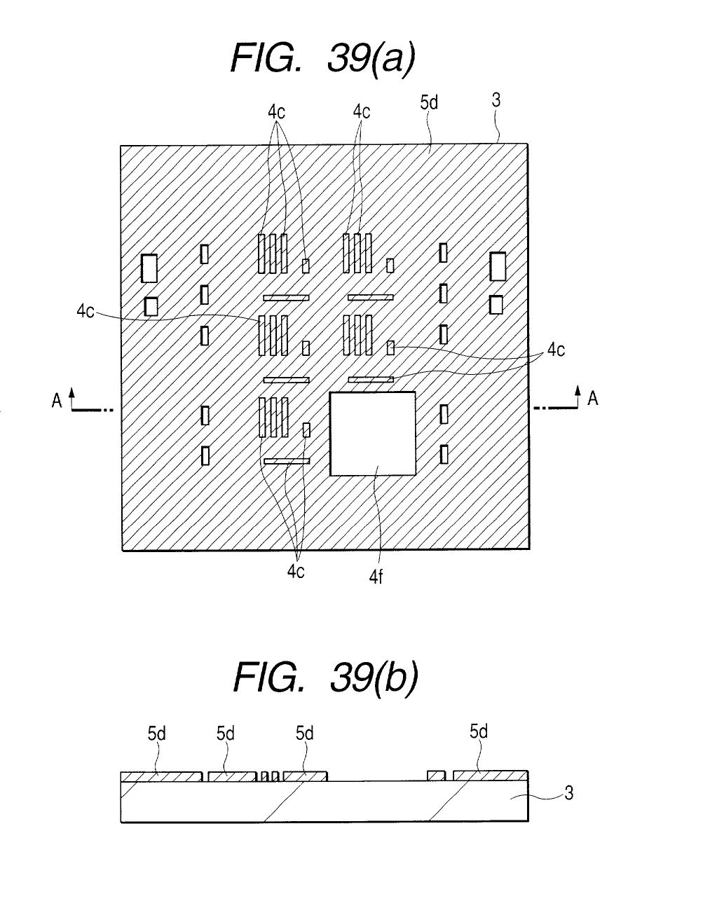

FIG. 39(a) is a plan view of the photomask of FIG. 33 during its fabrication step and FIG. 39(b) is a cross-sectional view taken along a line A-A of FIG. 39(a);

FIG. 40(a) is a plan view of the photomask of FIG. 33 during its fabrication step following the step of FIG. 39 and FIG. 40(b) is a cross-sectional view taken along a line A-A of FIG. 40(a);

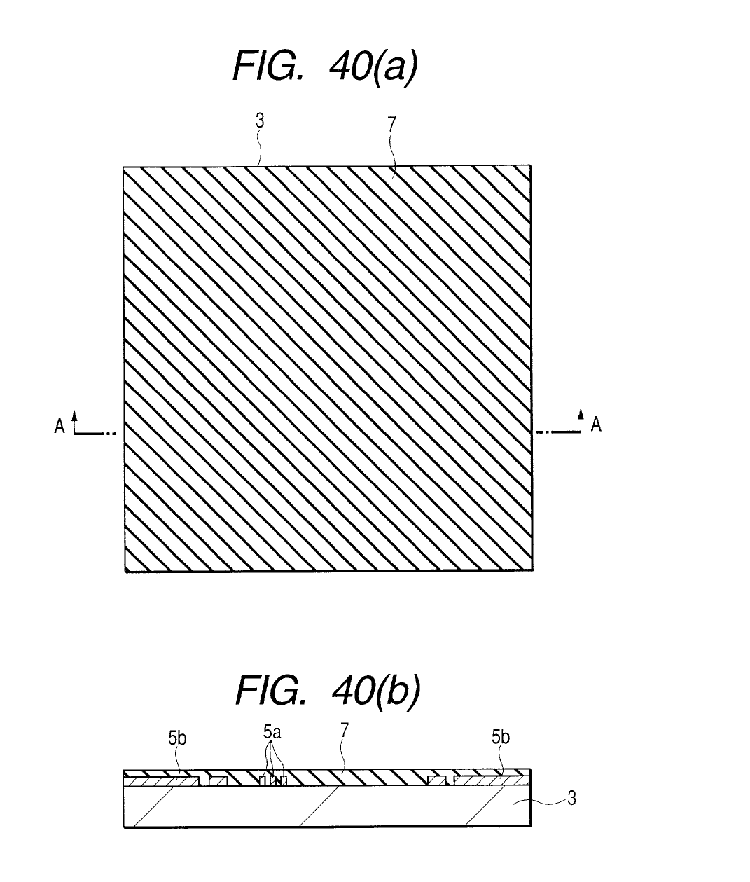

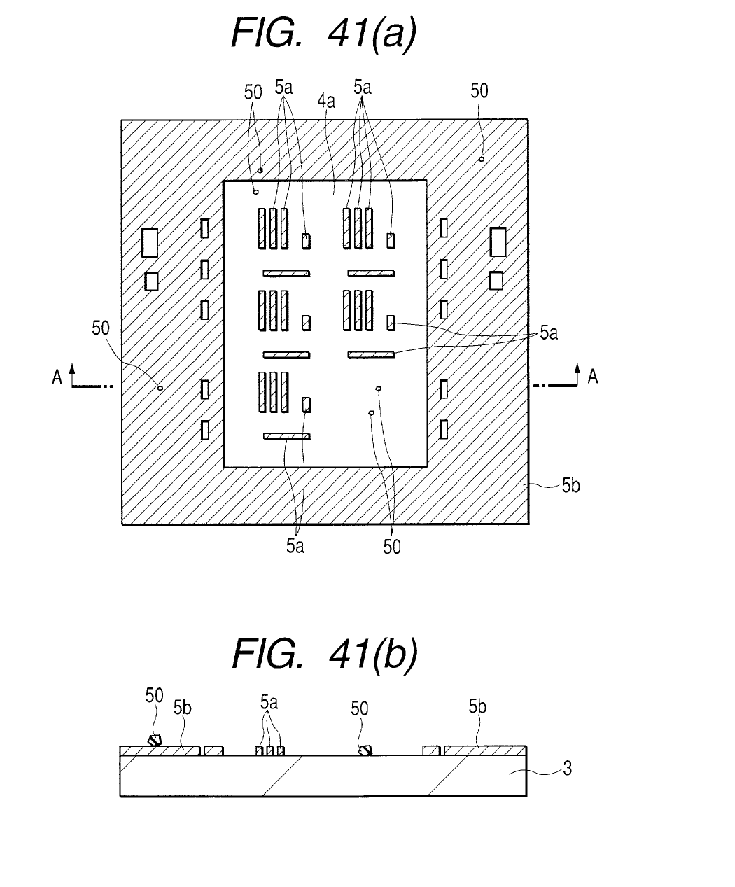

FIG. 41(a) is a plan view of the photomask of FIG. 31 during its re-fabrication step and FIG. 41(b) is a cross-sectional view taken along a line A-A of FIG. 41(a);

FIG. 42(a) is a plan view of the photomask FIG. 31 during its re-fabrication step following the step of FIG. 41 and FIG. 42(b) is a cross-sectional view taken along a line A-A of FIG. 42(a);

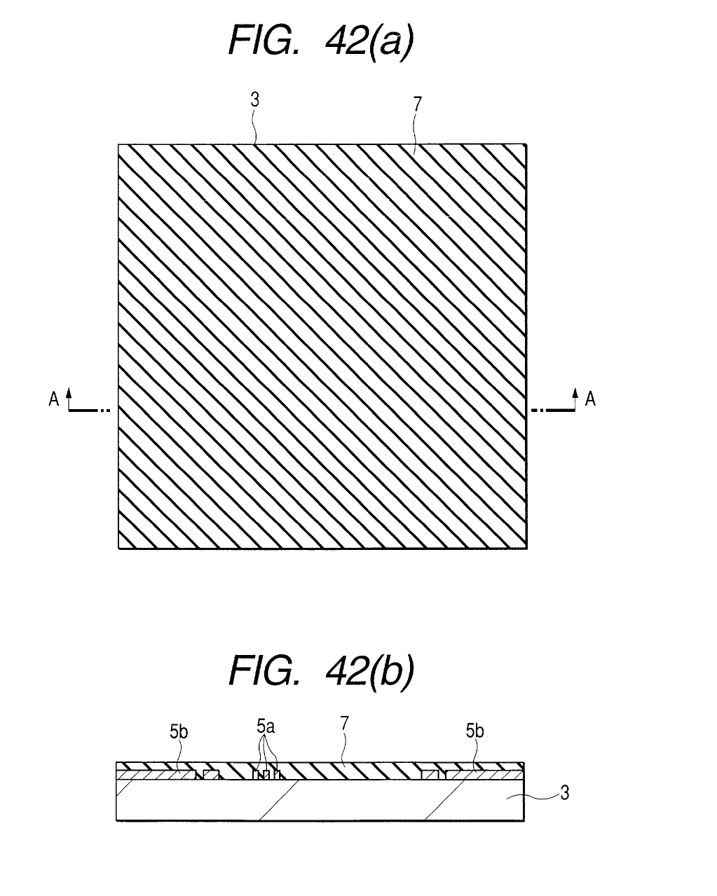

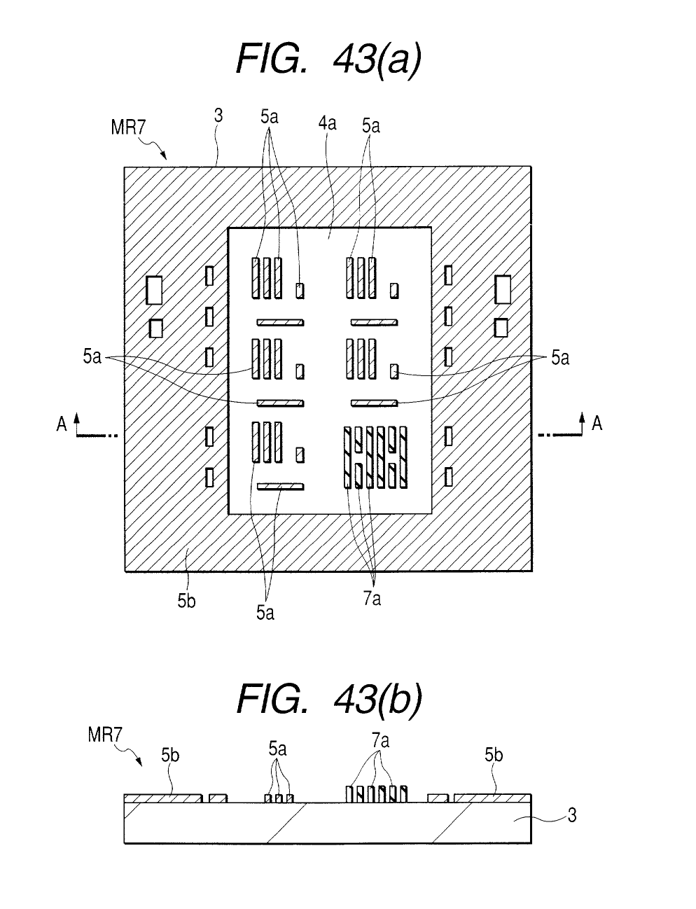

FIG. 43(a) is a plan view of the photomask FIG. 31 during its re-fabrication step following the step of FIG. 42 and FIG. 43(b) is a cross-sectional view taken along a line A-A of FIG. 43(a);

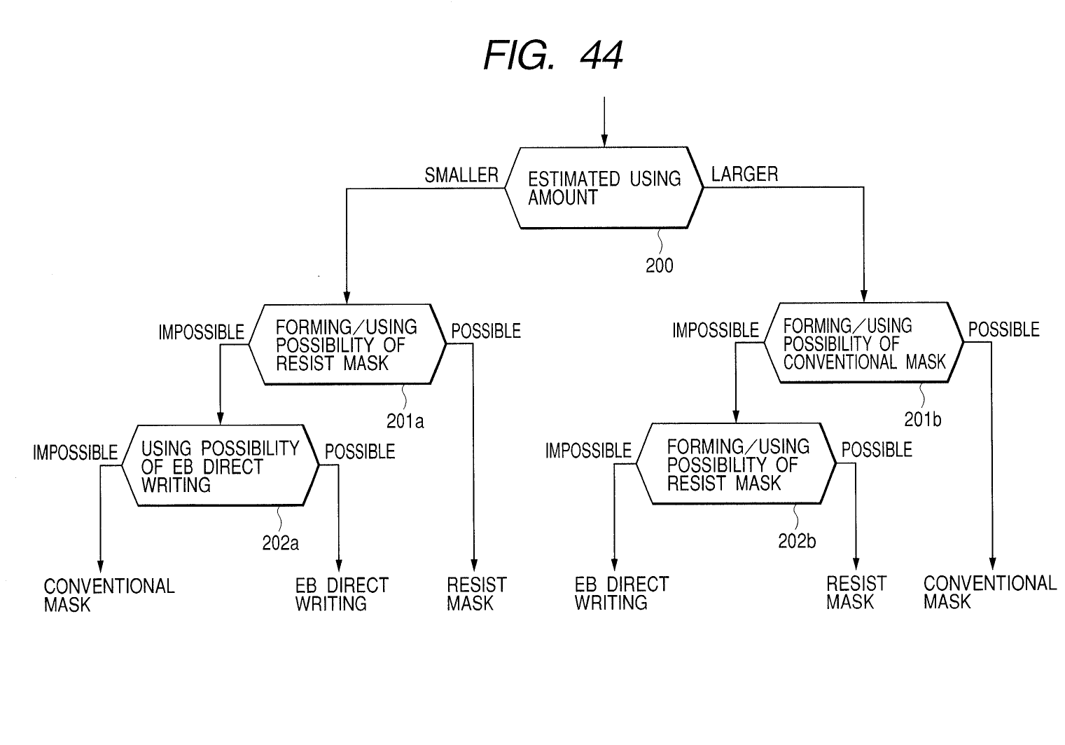

FIG. 44 illustrates proper use of a conventional mask, resist mask and electron-beam direct writing treatment in the fabrication (test) step of a semiconductor integrated circuit device according to another embodiment of the present invention;

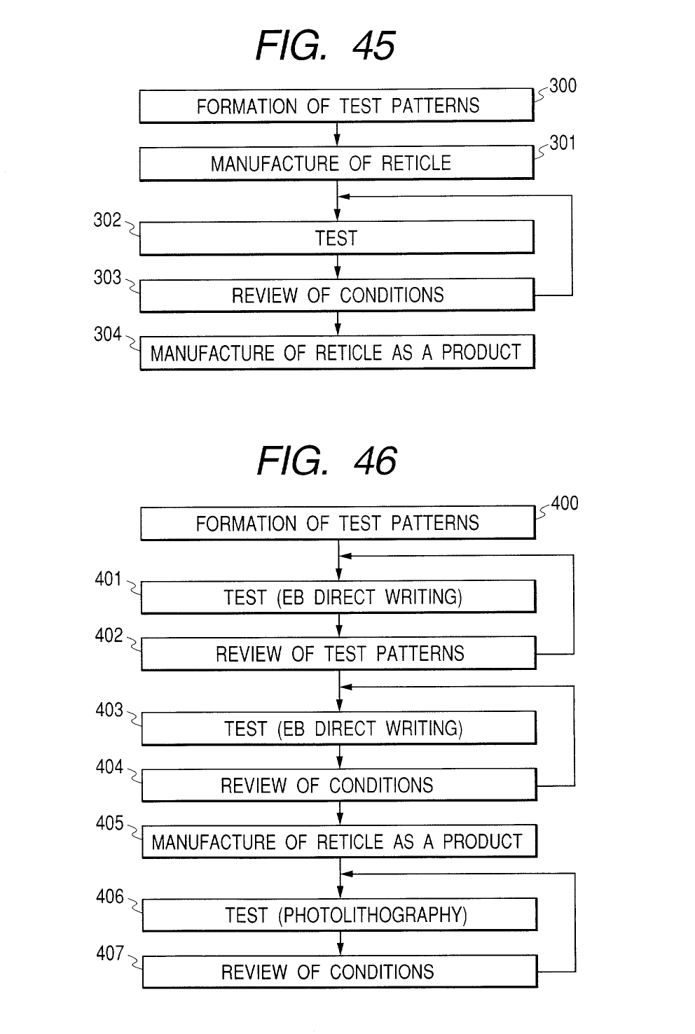

FIG. 45 illustrates the fabrication (test) step of a semiconductor integrated circuit device by using the conventional mask according to FIG. 44;

FIG. 46 illustrates the fabrication (test) step of a semiconductor integrated circuit device by using the electron-beam direct writing method according to FIG. 44;

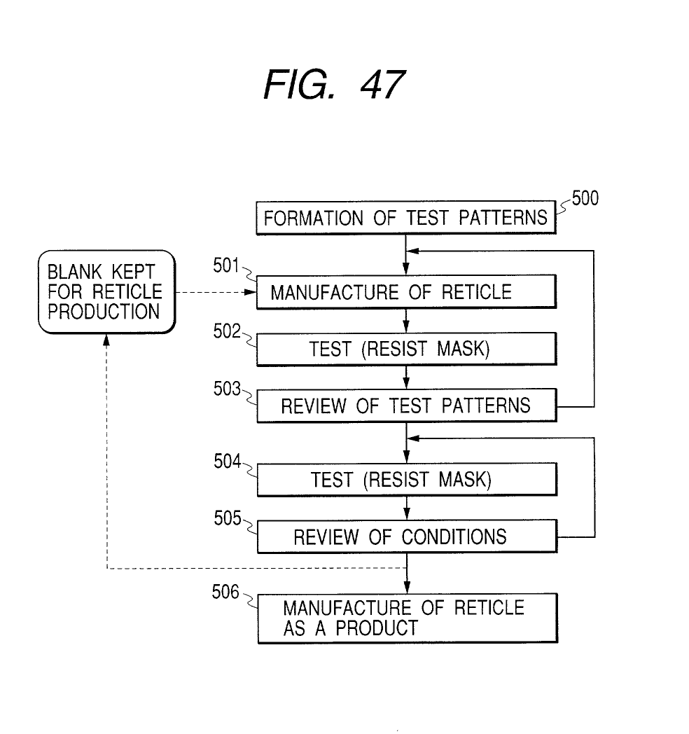

FIG. 47 illustrates the fabrication (test) step of a semiconductor integrated circuit device by using the resist mask according to FIG. 44;

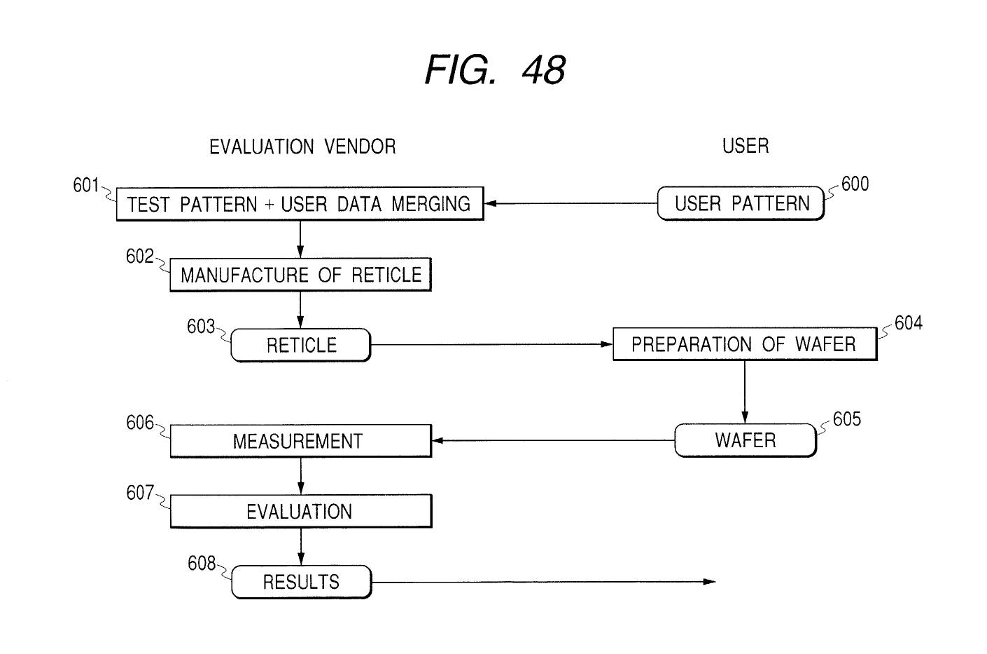

FIG. 48 illustrates the evaluation step by using a resist mask in the fabrication step of a semiconductor integrated circuit device according to a further embodiment of the present invention;

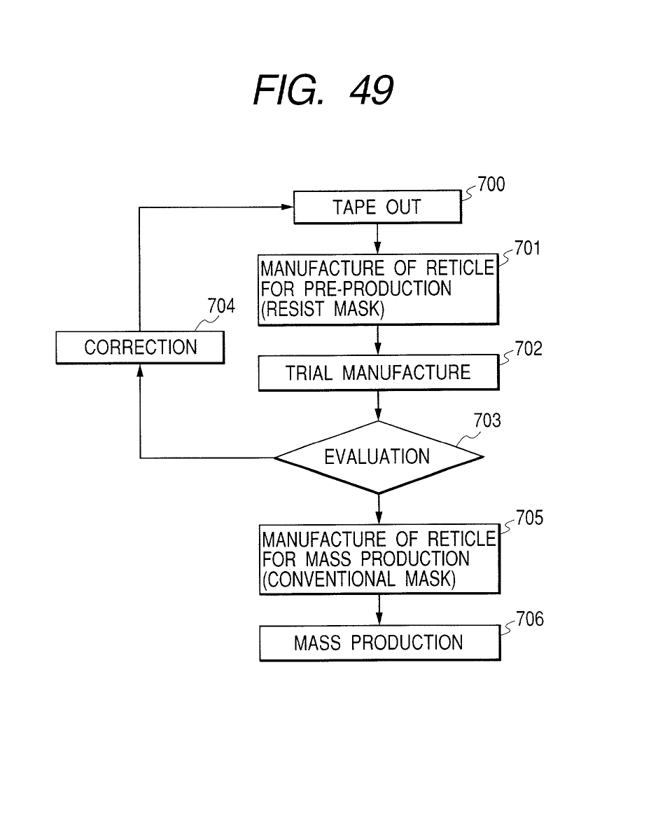

FIG. 49 is a flow chart of the fabrication step of a semiconductor integrated circuit device according to a still further embodiment of the present invention;

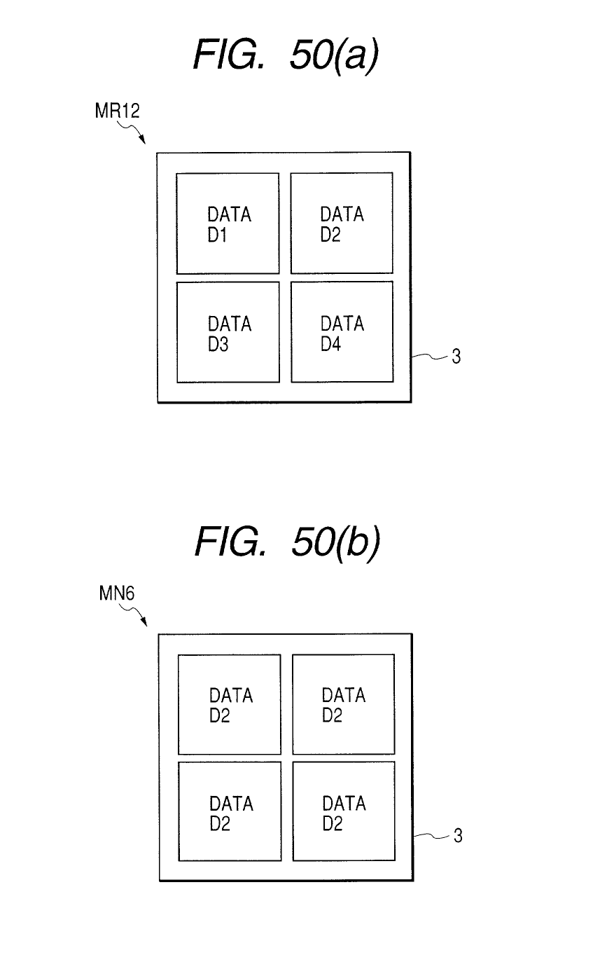

FIG. 50(a) illustrates a resist mask used in the fabrication step of the semiconductor integrated circuit device of FIG. 49, and FIG. 50(b) illustrates a conventional mask;

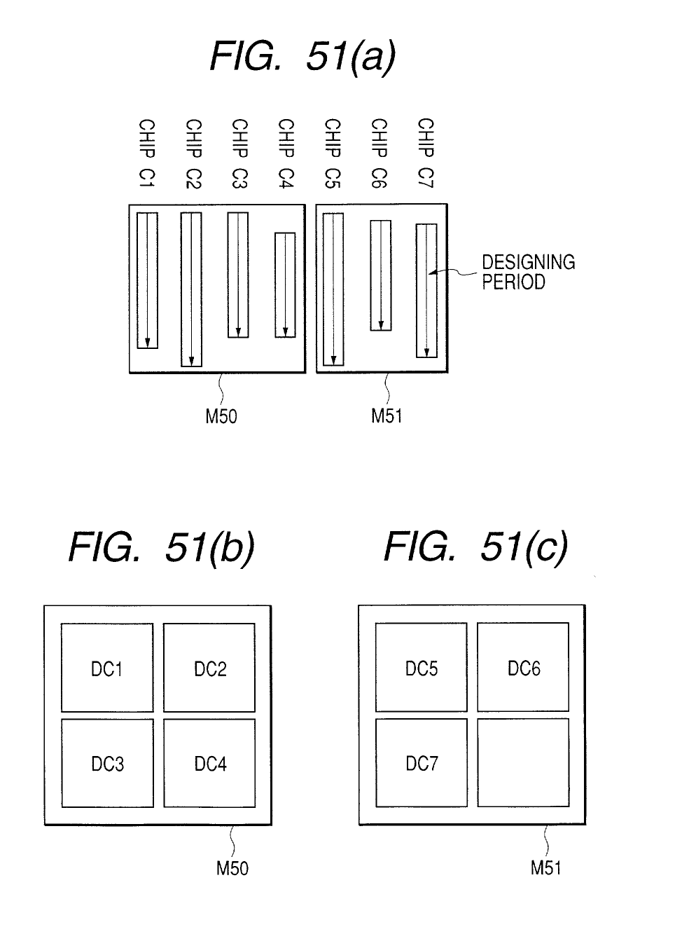

FIG. 51(a) illustrates a pre-production lot of a mask investigated by the present inventors, and FIGS. 51(b) and FIG. 51(c) illustrate the mask used in FIG. 51(a);

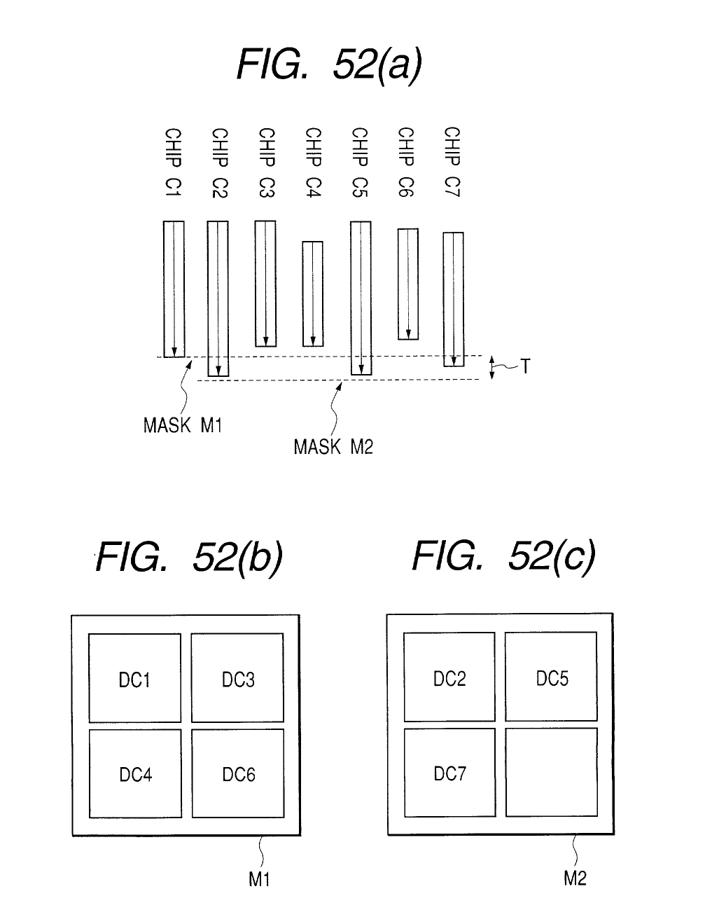

FIG. 52(a) illustrates a pre-production lot of a mask used in the trial manufacture of a semiconductor integrated circuit device according to a still further embodiment of the present invention, and FIGS. 52(b) and FIG. 52(c) illustrate one example of the mask used in FIG. 52(a);

FIG. 53(a) illustrates the pre-production step of a semiconductor integrated circuit device according to a still further aspect of the present invention, and FIGS. 53(b) and FIG. 53(c) illustrate one example of the mask used in FIG. 53(a);

FIG. 54 illustrates a fabrication step of a semiconductor integrated circuit device according to a still further embodiment of the present invention;

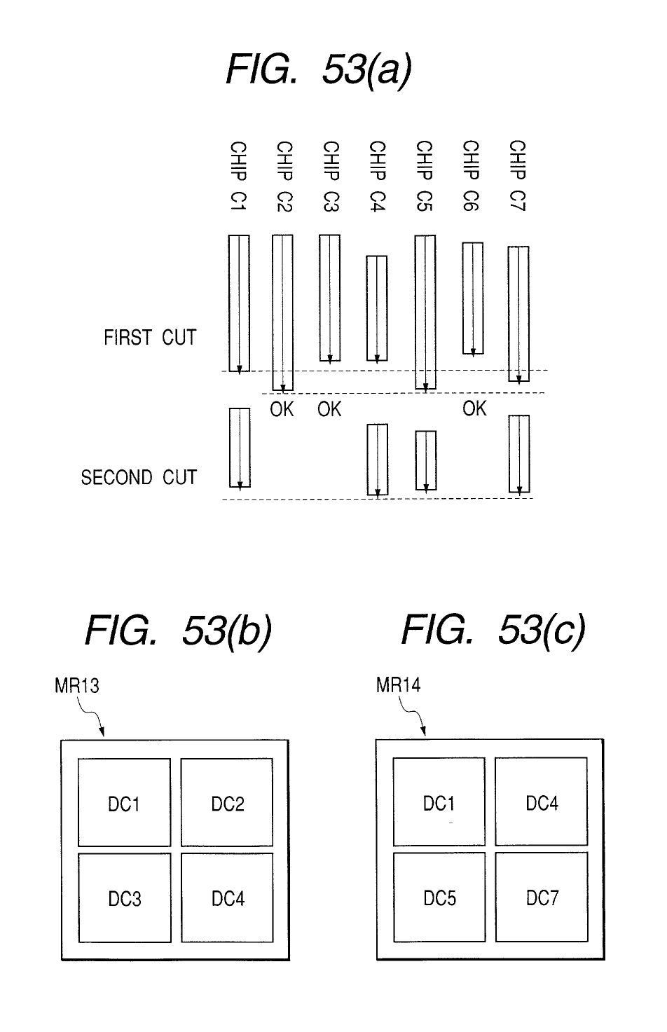

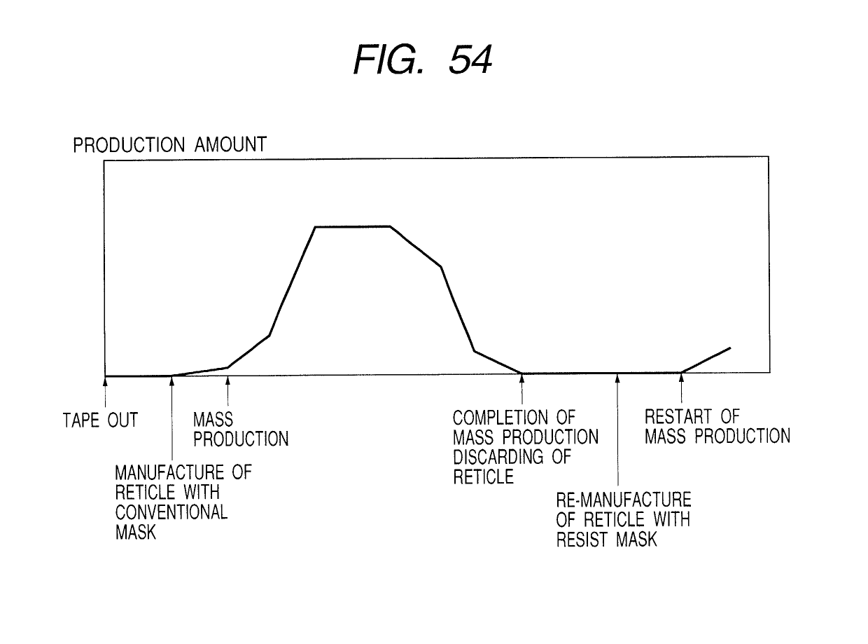

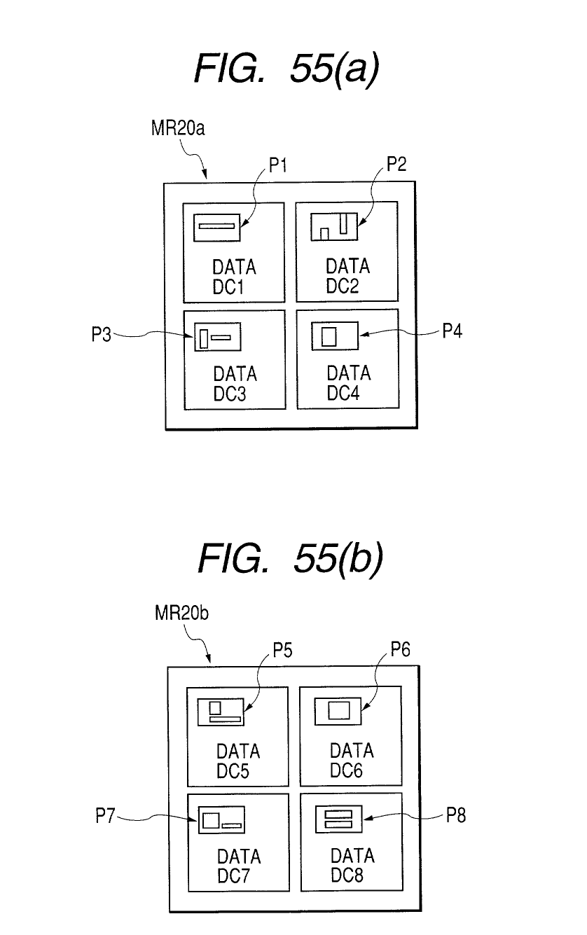

FIGS. 55(a) and 55(b) each illustrates a mask used in the fabrication step of a semiconductor integrated circuit device according to a still further embodiment of the present invention;

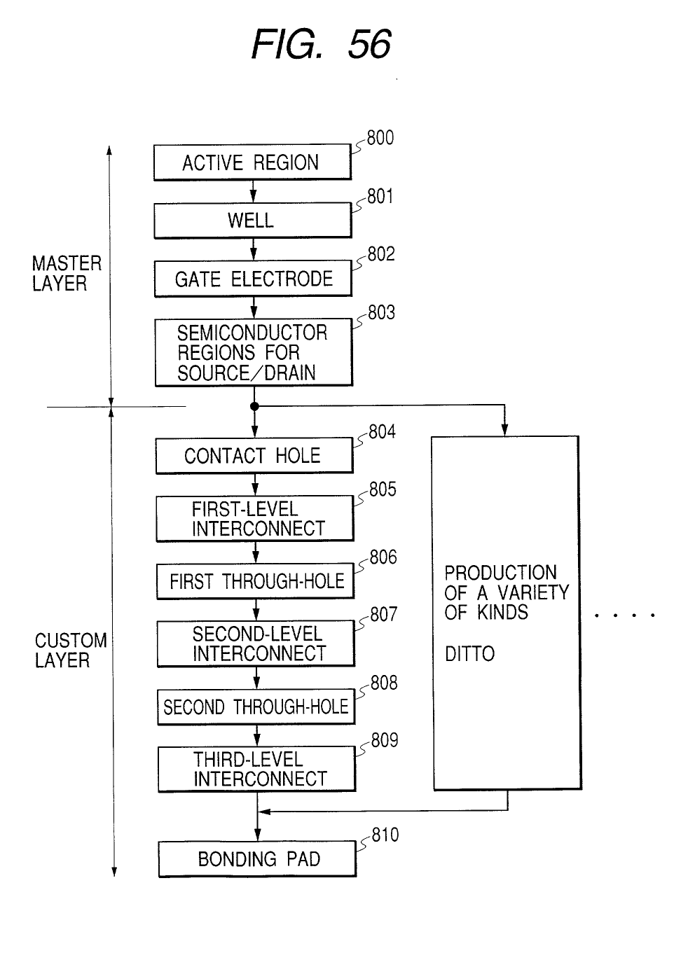

FIG. 56 is a fabrication flow chart of a semiconductor integrated circuit device according to a still further embodiment of the present invention;

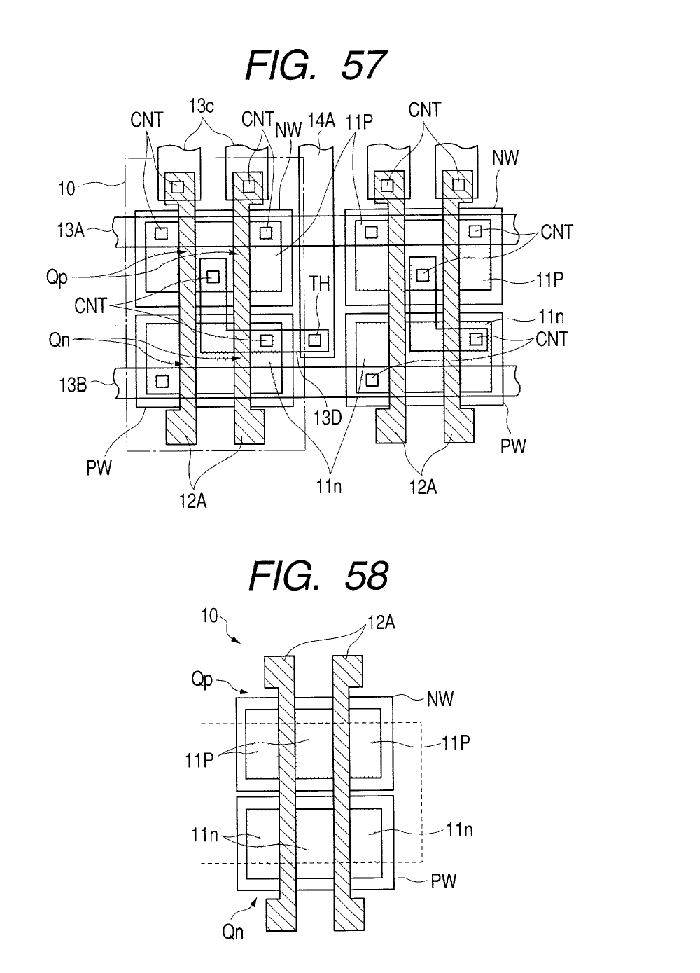

FIG. 57 is a fragmentary plan view of the semiconductor integrated circuit device of FIG. 56;

FIG. 58 is a plan view of the unit cell of FIG. 57;

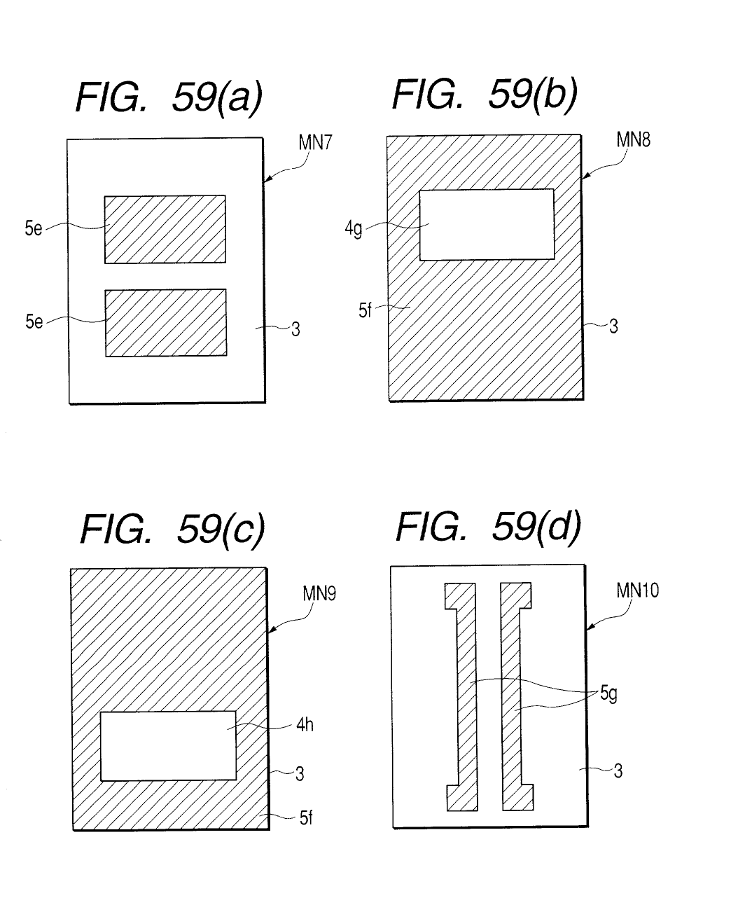

FIGS. 59(a) to (d) are each a plan view of the mask used for the fabrication of the unit cell of FIG. 58;

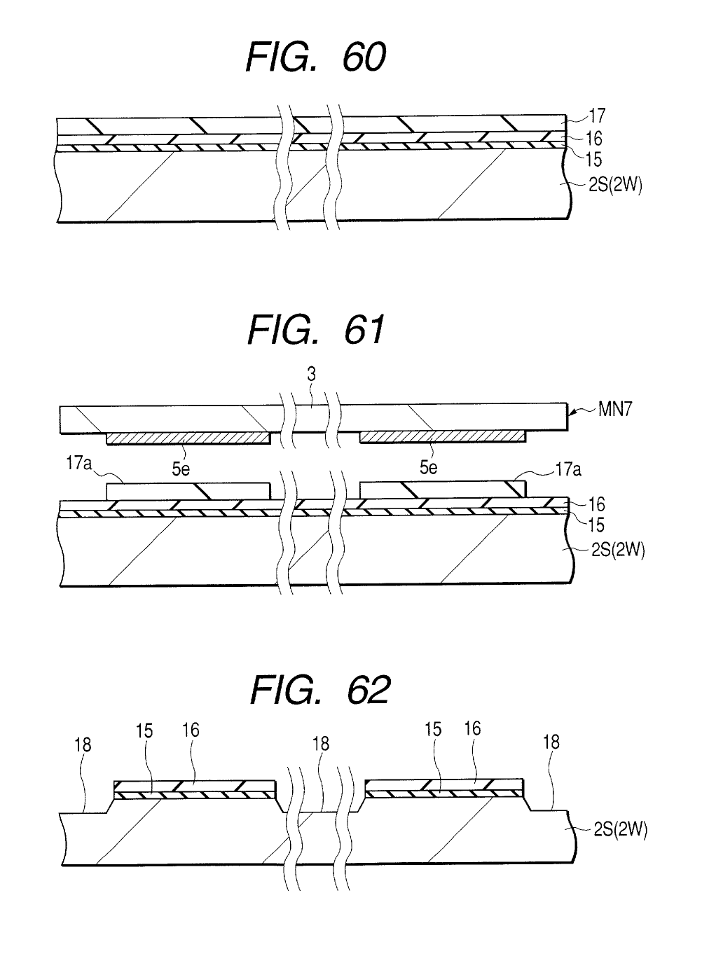

FIG. 60 is a fragmentary cross-sectional view of a semiconductor wafer during a fabrication step of the semiconductor integrated circuit device of FIG. 56;

FIG. 61 is a fragmentary cross-sectional view of the semiconductor wafer during a fabrication step of the semiconductor integrated circuit device following the step of FIG. 60;

FIG. 62 is a fragmentary cross-sectional view of the semiconductor wafer during a fabrication step of the semiconductor integrated circuit device following the step of FIG. 61;

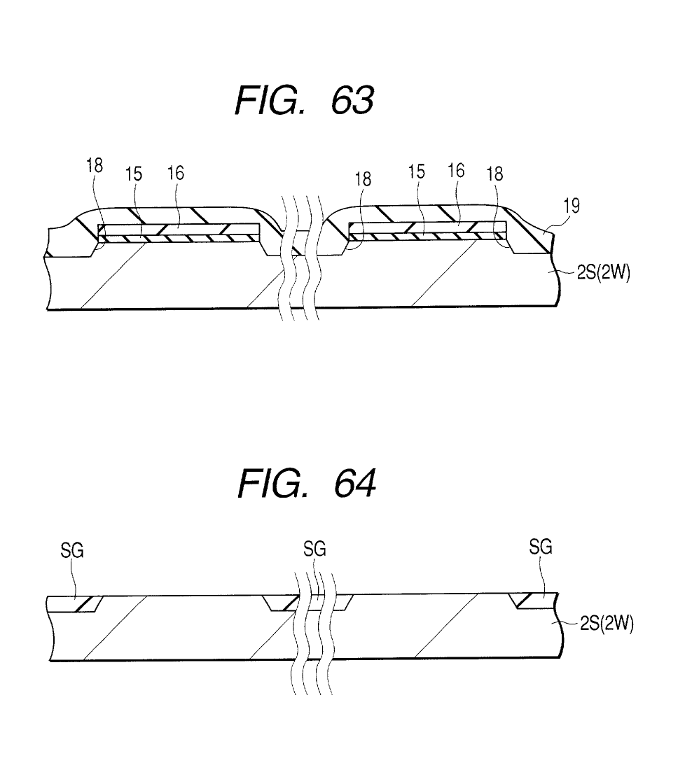

FIG. 63 is a fragmentary cross-sectional view of the semiconductor wafer during a fabrication step of the semiconductor integrated circuit device following the step of FIG. 62;

FIG. 64 is a fragmentary cross-sectional view of the semiconductor wafer during a fabrication step of the semiconductor integrated circuit device following the step of FIG. 63;

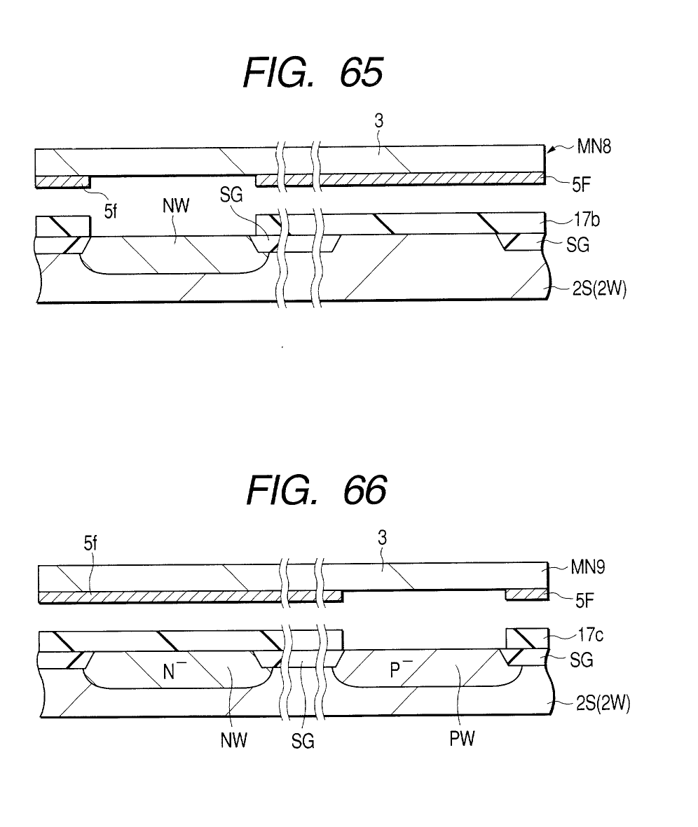

FIG. 65 is a fragmentary cross-sectional view of the semiconductor wafer during a fabrication step of the semiconductor integrated circuit device following the step of FIG. 64;

FIG. 66 is a fragmentary cross-sectional view of the semiconductor wafer during a fabrication step of the semiconductor integrated circuit device following the step of FIG. 65;

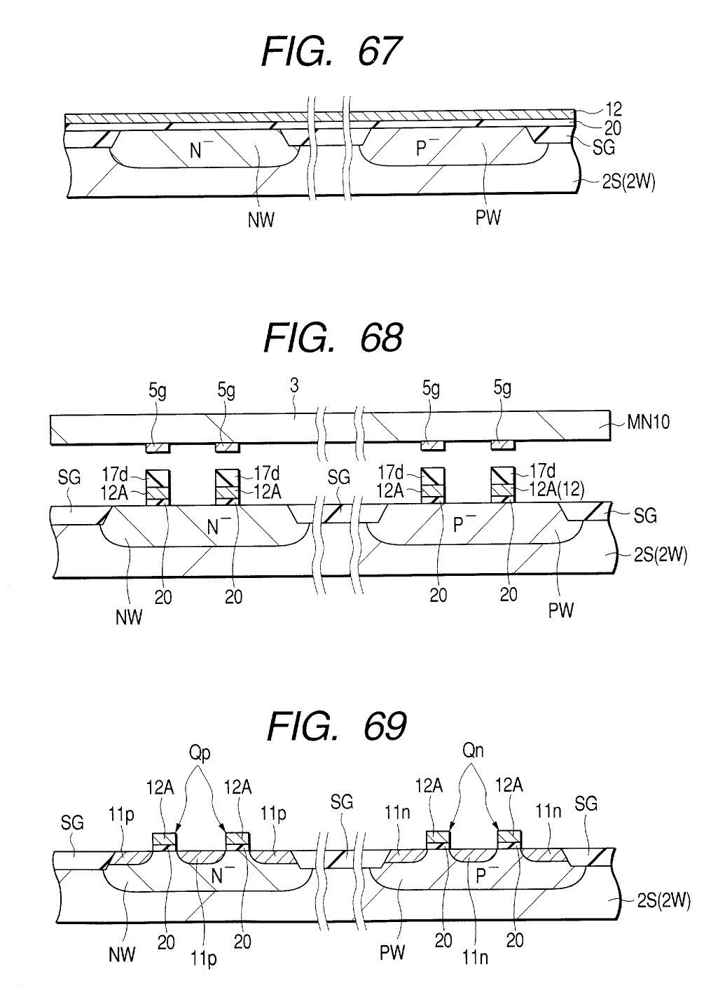

FIG. 67 is a fragmentary cross-sectional view of the semiconductor wafer during a fabrication step of the semiconductor integrated circuit device following the step of FIG. 66;

FIG. 68 is a fragmentary cross-sectional view of the semiconductor wafer during a fabrication step of the semiconductor integrated circuit device following the step of FIG. 67;

FIG. 69 is a fragmentary cross-sectional view of the semiconductor wafer during a fabrication step of the semiconductor integrated circuit device following the step of FIG. 68;

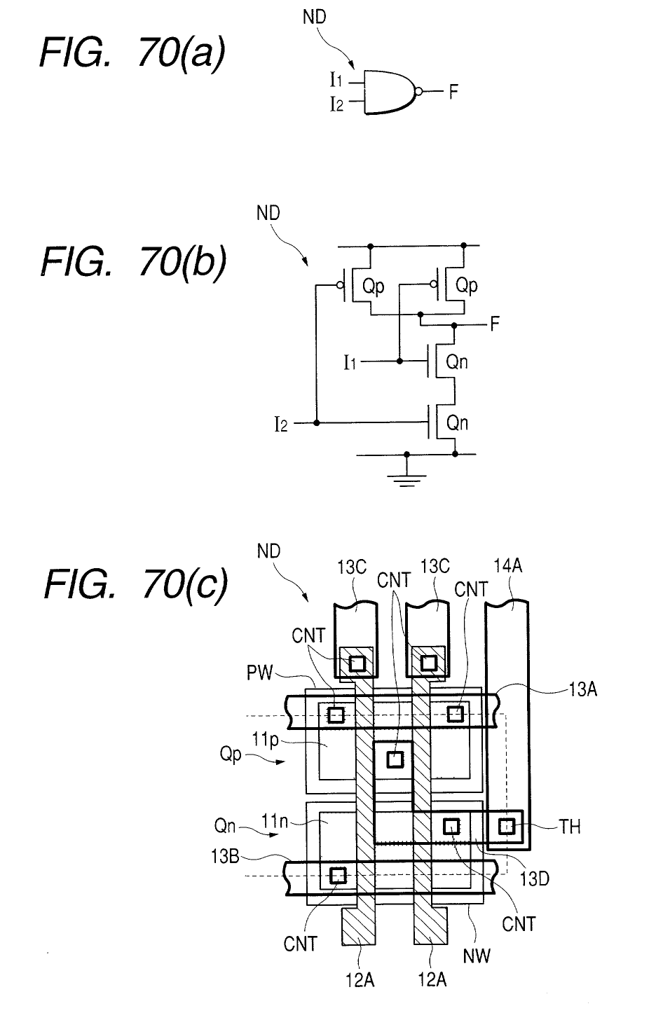

FIG. 70 (a) illustrates the symbols of an NAND gate circuit constituting the semiconductor integrated circuit device of FIG. 56, FIG. 70(b) is its circuit diagram and FIG. 70(c) is its layout plan view;

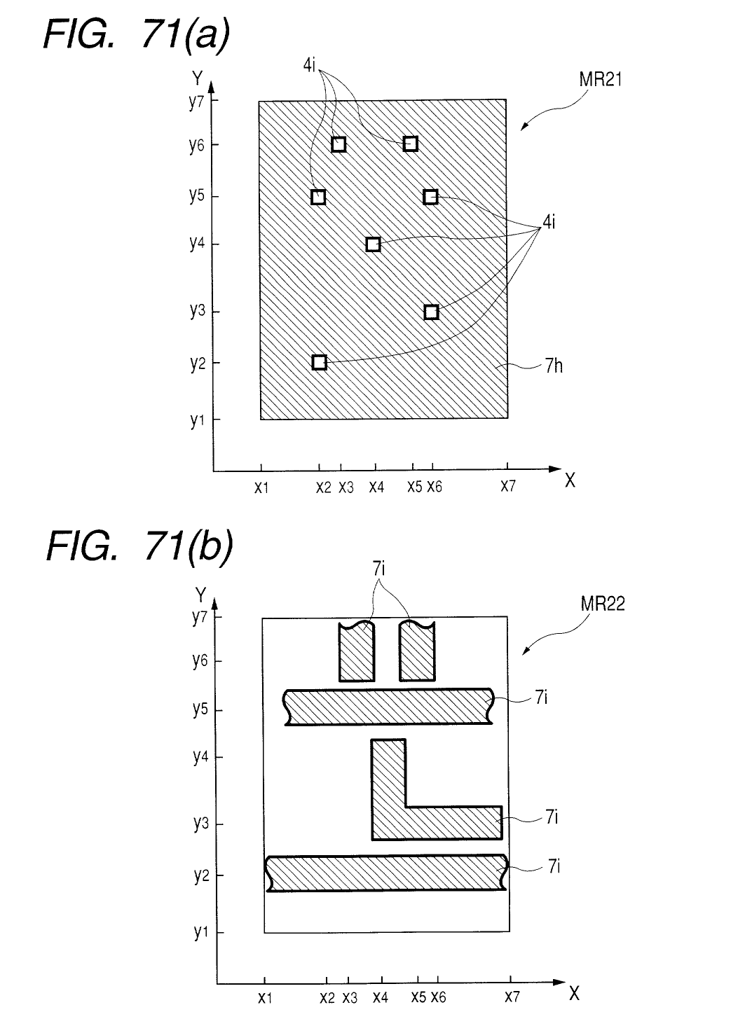

FIG. 71(a) is a fragmentary plan view of a photomask for forming the contact hole of the NAND gate circuit of FIG. 70, and FIG. 71(b) is a fragmentary plan view of a photomask for forming an interconnect of the NAND gate circuit of FIG. 70;

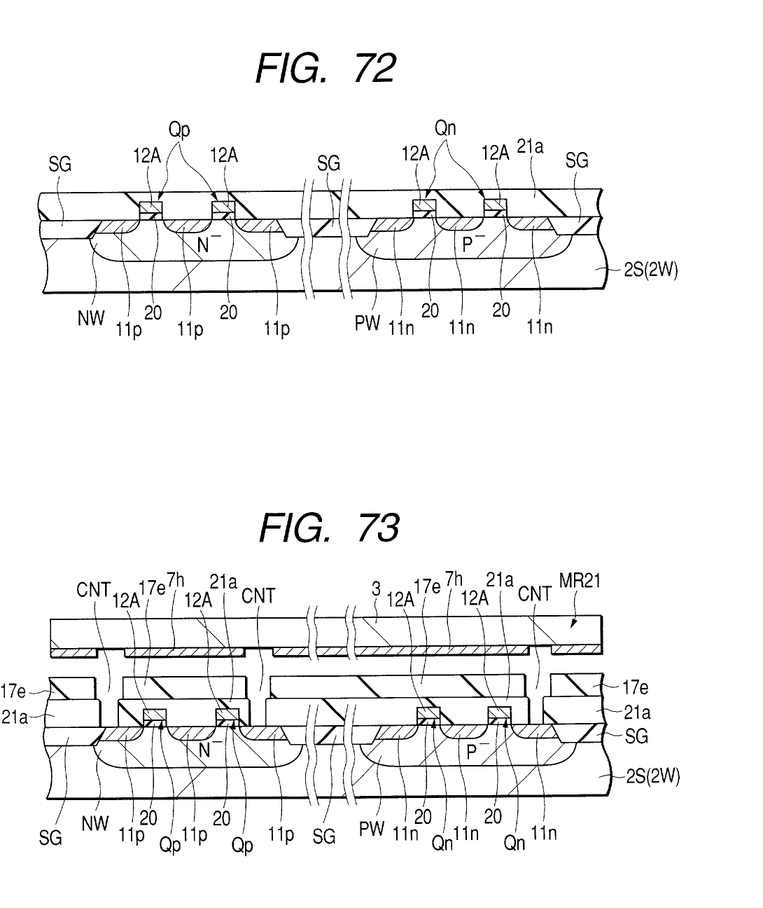

FIG. 72 is a fragmentary cross-sectional view of the semiconductor wafer during a fabrication step of the semiconductor integrated circuit device of FIG. 56;

FIG. 73 is a fragmentary cross-sectional view of the semiconductor wafer during a fabrication step of the semiconductor integrated circuit device following the step of FIG. 72;

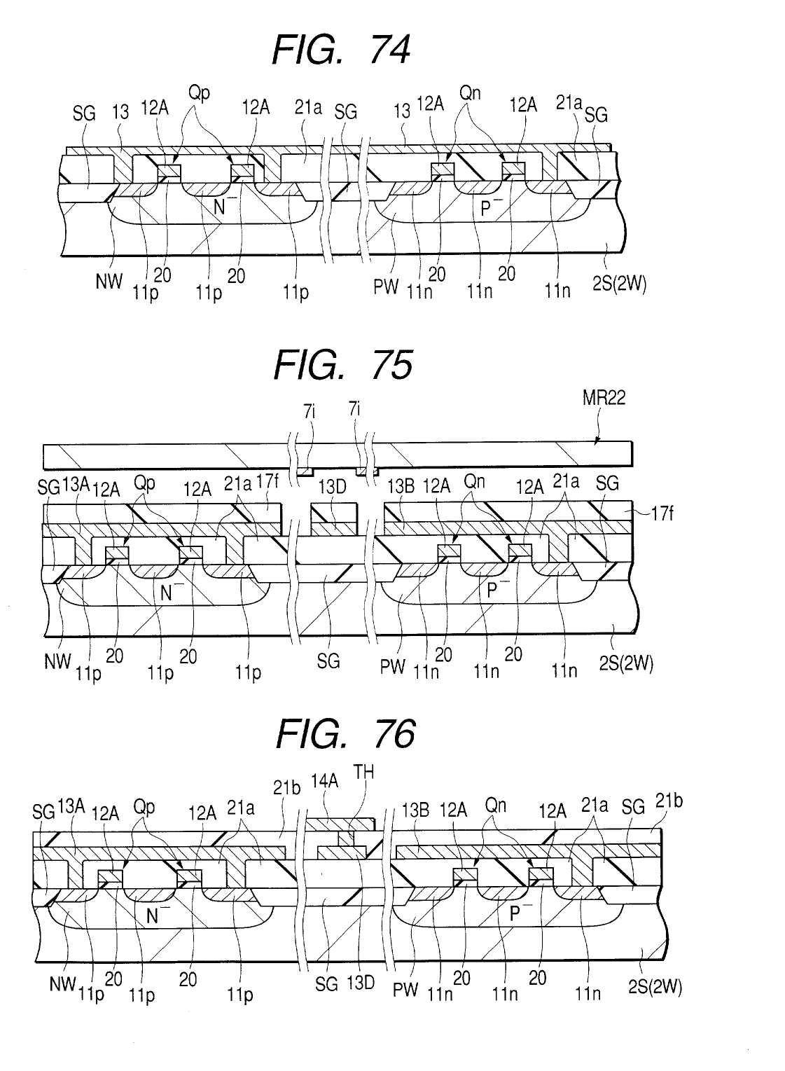

FIG. 74 is a fragmentary cross-sectional view of the semiconductor wafer during a fabrication step of the semiconductor integrated circuit device following the step of FIG. 73;

FIG. 75 is a fragmentary cross-sectional view of the semiconductor wafer during a fabrication step of the semiconductor integrated circuit device following the step of FIG. 74;

FIG. 76 is a fragmentary cross-sectional view of the semiconductor wafer during a fabrication step of the semiconductor integrated circuit device following the step of FIG. 75;

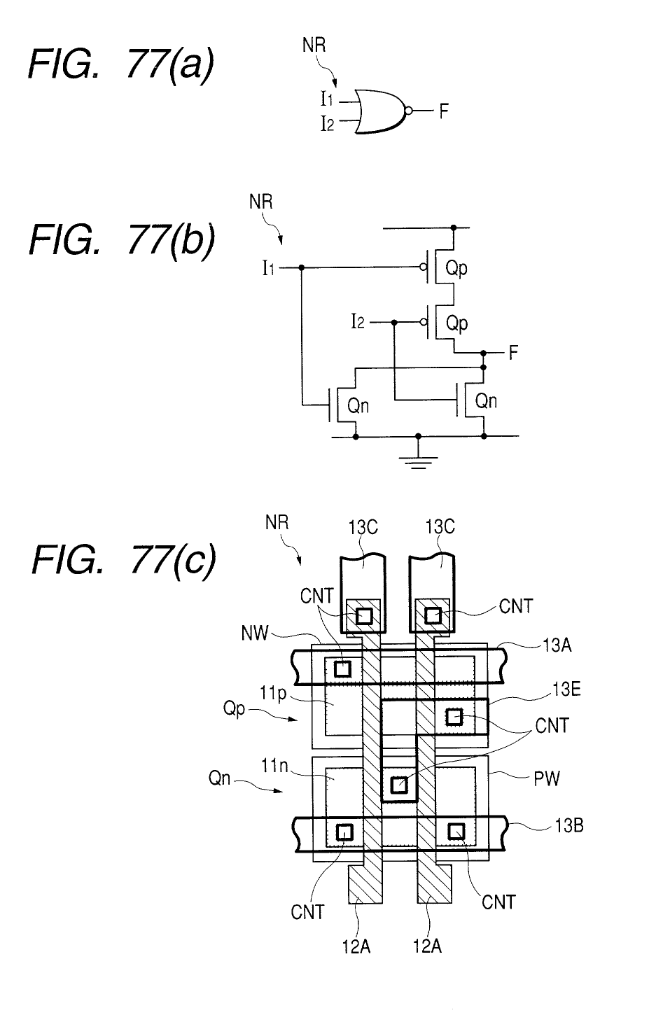

FIG. 77(a) illustrates the symbols of an NOR gate circuit constituting the semiconductor integrated circuit device of FIG. 56, FIG. 77(b) is its circuit diagram and FIG. 77(c) is its layout plan view;

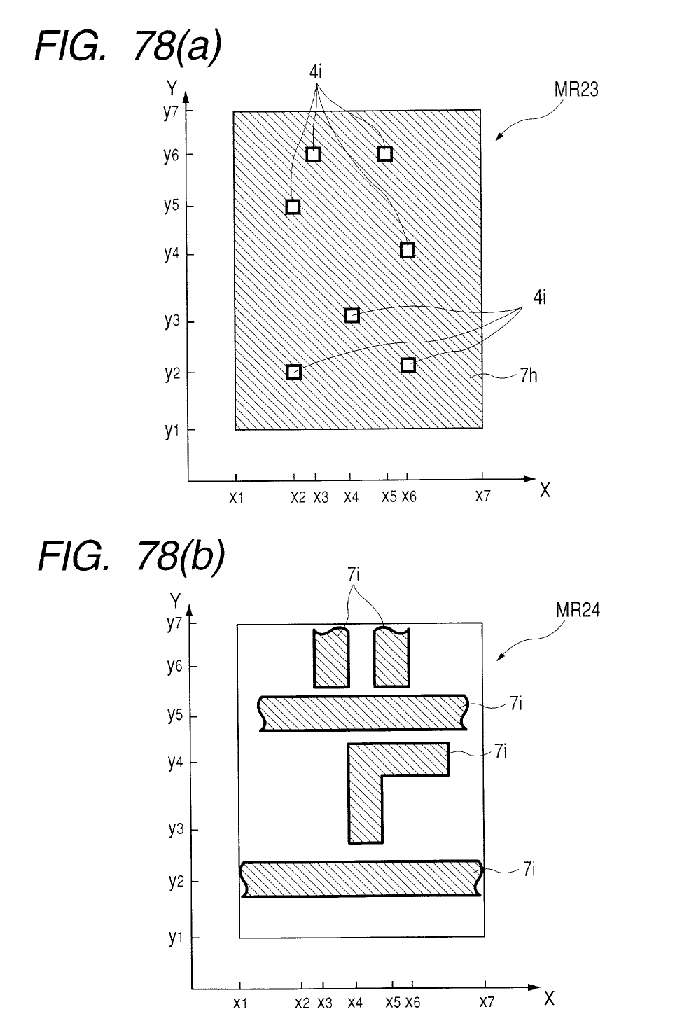

FIG. 78(a) is a fragmentary plan view of a photomask for forming a contact hole of the NOR gate circuit of FIG. 77, and FIG. 78(b) is a fragmentary plan view of a photomask for forming the interconnect of the NOR gate circuit of FIG. 77;

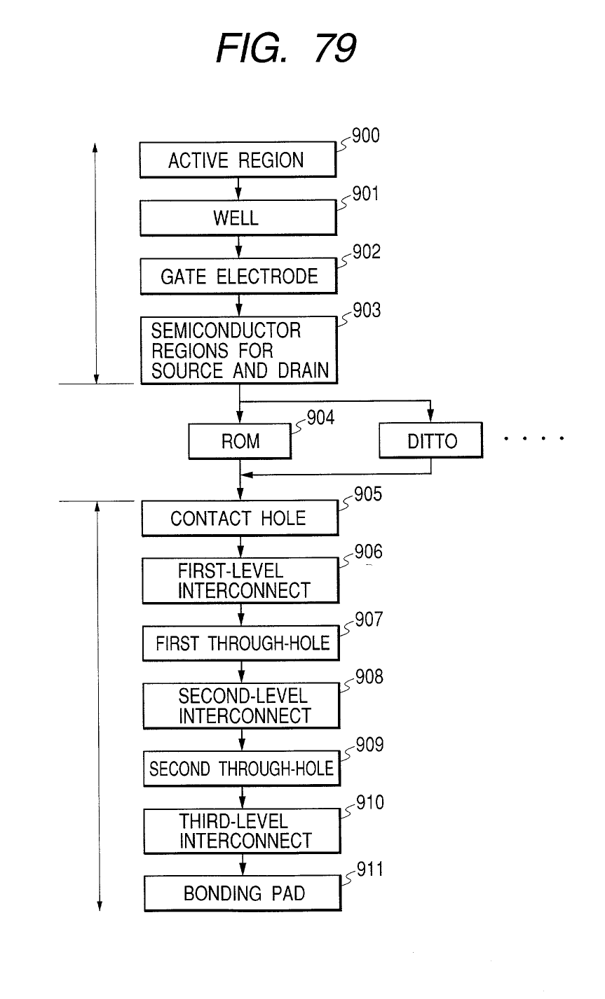

FIG. 79 is a fabrication flow chart of a semiconductor integrated circuit device according to a still further embodiment of the present invention;

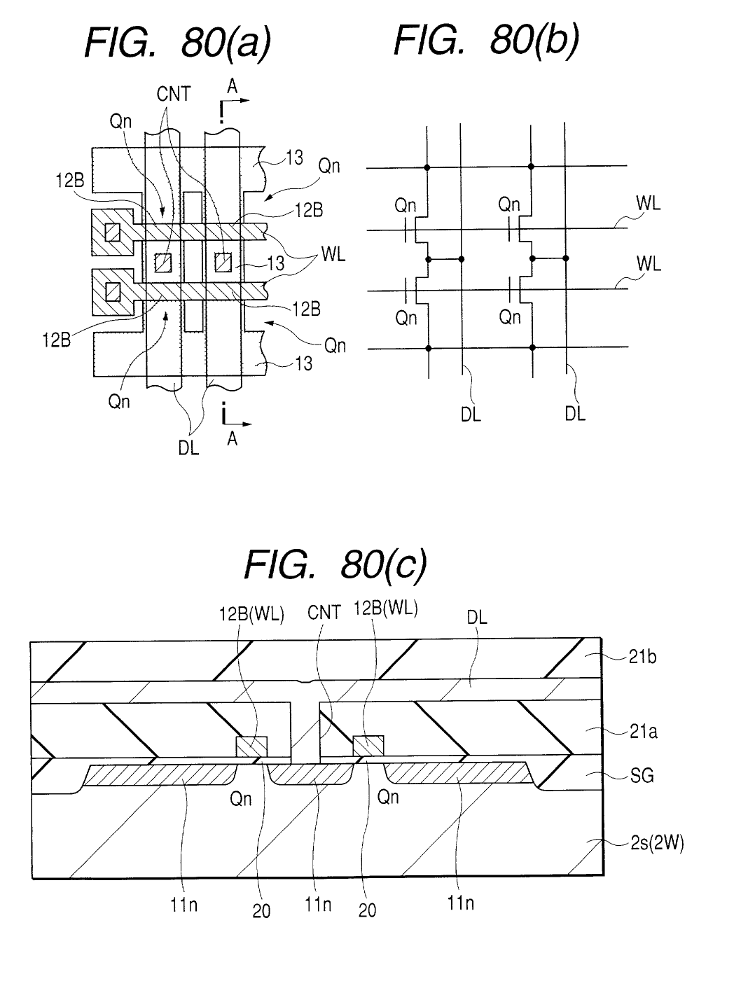

FIG. 80(a) is a layout plan view of the memory cell region of the semiconductor integrated circuit device of FIG. 79, FIG. 80(b) is its circuit diagram, and FIG. 80(c) is a cross-sectional view taken along a line A-A of FIG. 80(a);

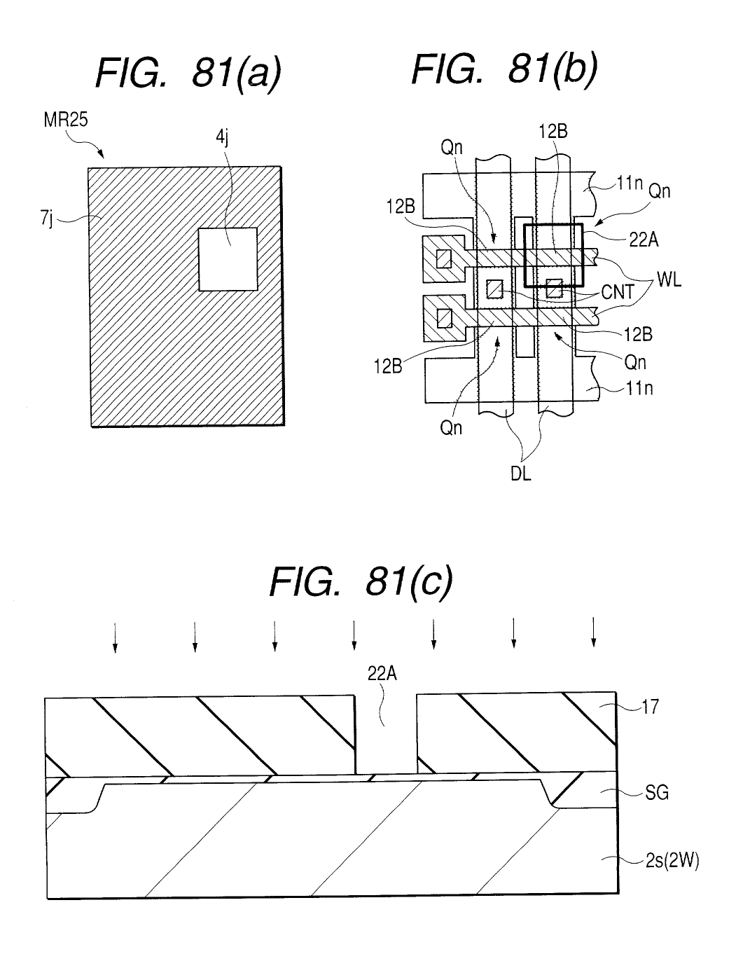

FIG. 81(a) is a fragmentary plan view, in an integrated circuit pattern region, of the photomask used in the fabrication step of the semiconductor integrated circuit device of FIG. 79, FIG. 81(b) is a layout plan view of the memory cell region of a mask ROM showing patterns for data writing; and 81(c) is a cross-sectional view of a portion corresponding to the line A-A of FIG. 80(a) upon data writing step;

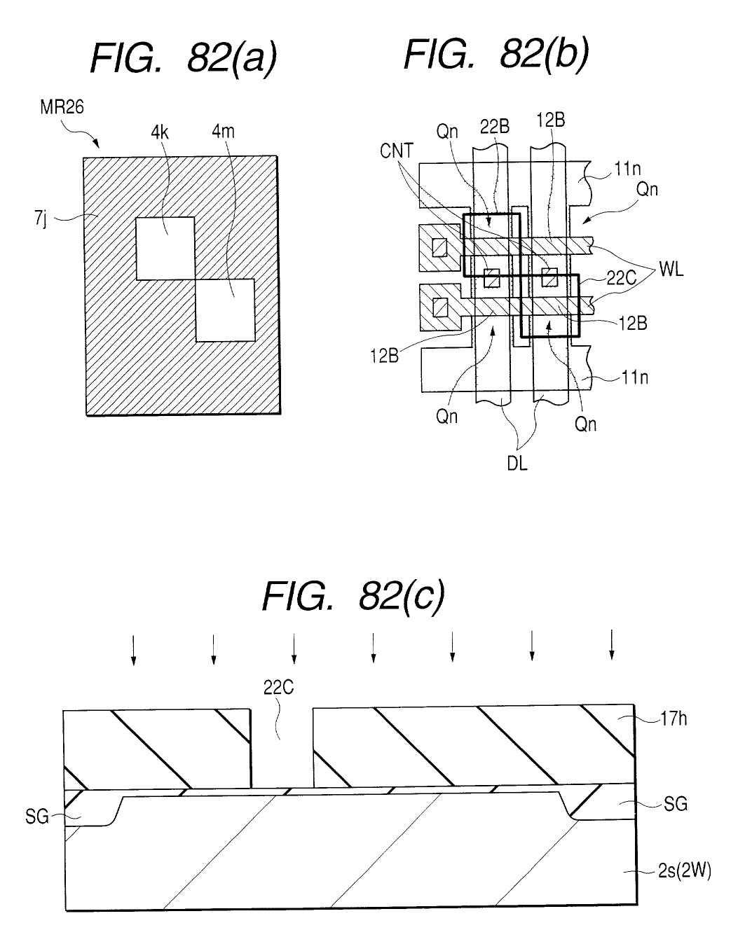

FIG. 82(a) is a fragmentary plan view, in an integrated circuit pattern region, of the photomask used in the fabrication step of the semiconductor integrated circuit device of FIG. 79, FIG. 82(b) is a layout plan view of the memory cell region of a mask ROM showing patterns for data writing; and 82(c) is a cross-sectional view of a portion corresponding to the line A-A of FIG. 80(a) upon data writing step;

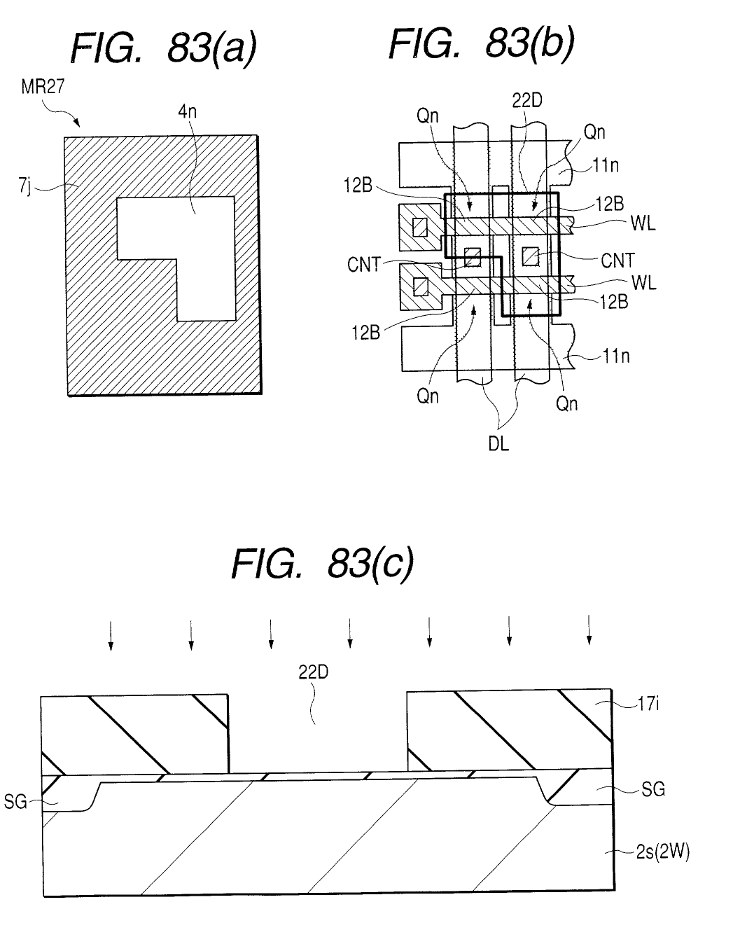

FIG. 83(a) is a fragmentary plan view, in an integrated circuit pattern region, of the photomask used in the fabrication step of the semiconductor integrated circuit device of FIG. 79, FIG. 83(b) is a layout plan view of the memory cell region of a mask ROM showing patterns for data writing; and 83(c) is a cross-sectional view of a portion corresponding to the line A-A of FIG. 80(a) upon data writing step;

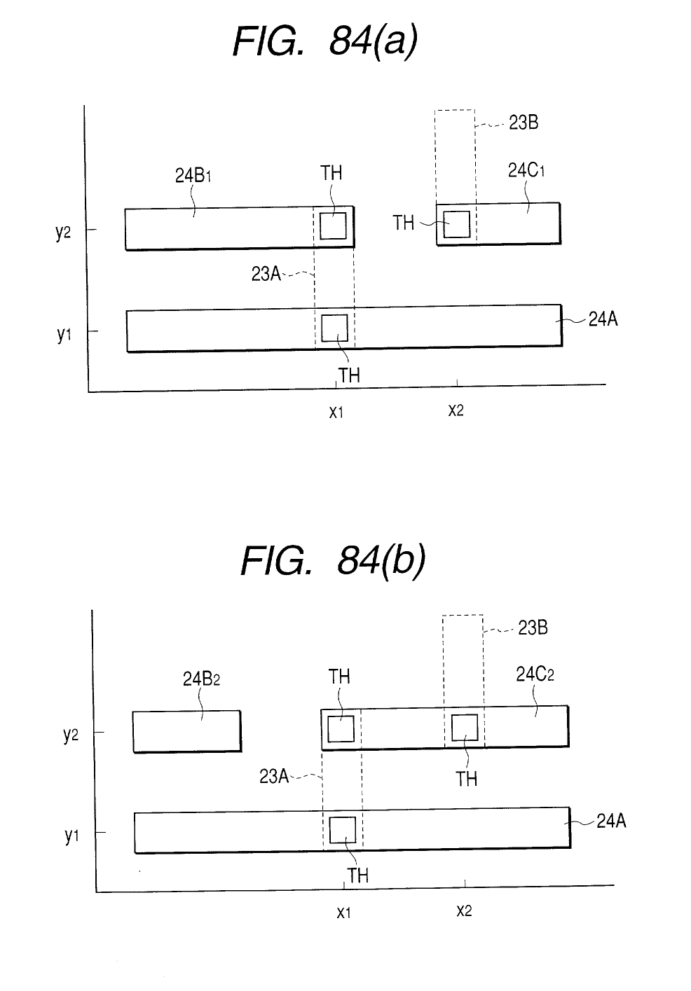

FIG. 84(a) is a fragmentary plan view of a semiconductor wafer before correction in the fabrication step of a semiconductor integrated circuit device according to a still further embodiment of the present invention, and FIG. 84(b) is a fragmentary plan view of the semiconductor wafer after correction;

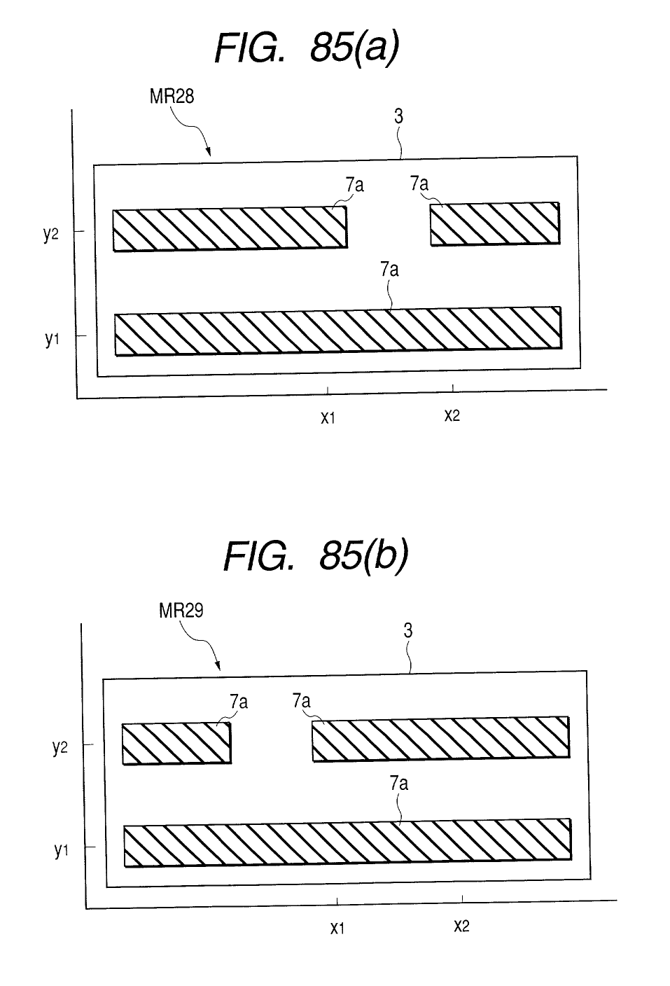

FIG. 85(a) is a fragmentary plan view of a photomask used for the formation of the patterns of FIG. 84(a), and FIG. 85(b) is a fragmentary plan view of a photomask used for the formation of the patterns of FIG. 84(b); and

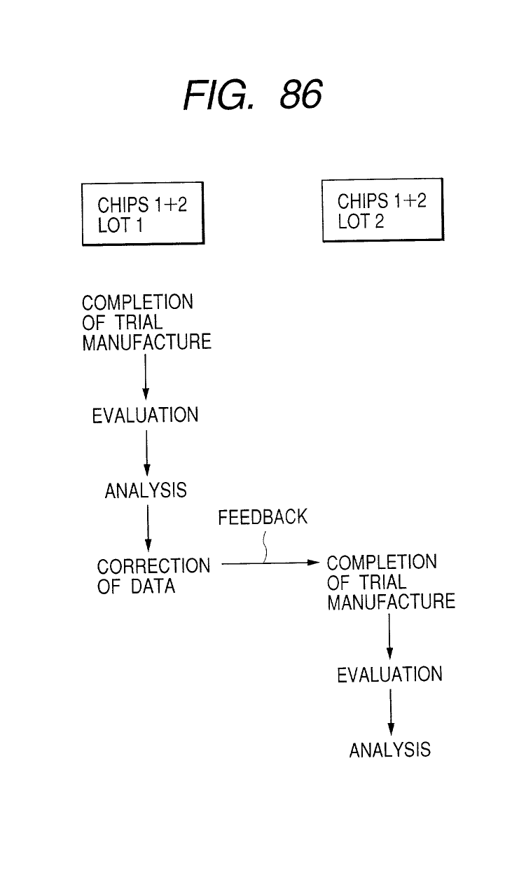

FIG. 86 is a fabrication flow chart of a semiconductor integrated circuit device according to a still further embodiment of the present invention.

### DETAILED DESCRIPTION OF THE PREFERRED EMBODIMENTS

Prior to detailed description of the present invention, the meaning of each of the terms used in this application will next be described.

1. Mask (photomask): having light blocking patterns or light phase shifting patterns formed on a mask substrate. It includes a reticle which contains patterns of several times greater than the final size. The “first main surface of a mask” means a surface on which the light blocking patterns or light phase shifting patterns have been formed, while the “second surface of the mask” means a surface opposite to the first main surface.

2. Conventional mask (second photomask): means an ordinarily employed mask having, on a mask substrate, mask patterns composed of light blocking patterns made of a metal and light transmitting patterns. In this embodiment, it includes a phase shift mask having a means for causing a phase difference in an exposure light transmitting through the mask. A groove made in a mask substrate to a predetermined depth or a transparent or semi-transparent film of a predetermined thickness disposed on a mask substrate serves as a phase shifter for causing a phase difference in an exposure light.

3. Resist mask (first photomask): means a mask having a light blocker (light blocking film, light blocking pattern, light blocking region) made of an organic material containing an organic photosensitive resin on a mask substrate. The term “organic material” as used herein embraces a single film of an organic photosensitive resin, an organic photosensitive resin film having, added thereto, a light absorbing material or light attenuating material and a laminate of an organic photosensitive resin film and another film (for example, an antireflection film, light absorbing resin film or light attenuating resin film).

4. The pattern surface of a mask (the above-described conventional mask or resist mask) is classified into the following regions: that is, “integrated circuit pattern region” wherein integrated circuit patterns to be transferred are disposed and “peripheral region” which exists outer periphery thereof.

5. Although no particular limitation is imposed, the resist mask is classified in this specification for the sake of convenience into three groups: mask blank (hereinafter be called “blank” simply), metal mask and resist mask, from the viewpoint of its manufacturing step. The “mask blank” is a mask in the initial stage and not completed as a mask for transferring desired patterns. It is a mask having no patterns formed in the integrated circuit pattern region but is highly common (usable for general purposes) because of having a basic constitution necessary for mask manufacture. “The metal mask” is not completed as a mask but has, in the integrated circuit pattern region, patterns made of a metal. Difference between this metal mask and the conventional mask resides in that whether it is completed or not as a mask capable of transferring desired patterns to a substrate. The “resist mask” is completed as a mask and means a mask having, in the integrated circuit pattern region, patterns formed of an organic material containing an organic photosensitive resin such as a resist film. It includes a mask on which patterns for transferring desired patterns are all made of a resist film and that made of both a metal film and a resist film.

6. The term “wafer” means a silicon single crystal substrate (usually in the form of a substantially plane disc), a sapphire substrate, a glass substrate or the other insulating, anti-insulating or semiconductor substrate, or composite thereof to be employed for the fabrication of an integrated circuit. The term “semiconductor integrated circuit device” as used herein means not only that formed on a semiconductor or insulator substrate such as silicon wafer or sapphire substrate but also that formed on another insulating substrate, for example, glass such as TFT (Thin-Film-Transistor) or STN (Super-Twisted Nematic) liquid crystals or the like unless otherwise specifically indicated.

7. The term “device surface” means the main surface of a wafer on which device patterns corresponding to a plurality of chip regions are to be formed by lithography.

8. The term “light blocker”, “light blocking region”, “light blocking film” or “light blocking pattern” as used herein means that it has optical properties to transmit less than 40% of a light to which it is exposed. Usually, that of several % to less than 30% is employed. The term “transparent”, “transparent film”, “light transmitting region” or “light transmitting pattern”, on the other hand, means that it has optical properties to transmit at least 60% of a light to which it is exposed. Usually, that of at least 90% is used.

9. Transferred pattern: means a pattern transferred onto a wafer through a mask, more specifically, a resist pattern or a pattern practically formed on the wafer with a resist pattern as a mask.

10. Resist pattern: means a film pattern obtained by patterning a photosensitive organic film by photolithography.

11. Hole pattern: means a minute pattern, on a wafer, such as contact hole or through-hole having a two-dimensional size equivalent or not greater than the exposure wavelength. Usually, it has a square, an almost square but rectangular, or an octagonal shape, but it tends to be circular on the wafer.

12. Line pattern: means a strip-like pattern for forming a wiring pattern or the like on a wafer.

13. Ordinary illumination: means unmodified illumination having relatively uniform light intensity distribution.

14. Modified illumination: means illumination having illuminance reduced at the center portion thereof. Examples includes off-axis illumination, zonal illumination, and multipole illumination such as tetrapole illumination and pentapole illumination and superresolution technique by pupil filter which is equivalent thereto.

15. Scanning exposure: means an exposing method by successively moving (scanning) an exposure strip in the form of a slender slit to a direction perpendicular to the longitudinal direction of the slit (oblique movement is possible) relative to a wafer and a mask, thereby transferring a circuit pattern on the mask to a desired portion on the wafer.

16. Step and scan exposure: means a method of exposing the whole portion of a wafer to be exposed, by using the above-described scanning exposure and stepping exposure in combination. This corresponds to the subordinate concept of the above-described scanning exposure.

17. Step and repeat exposure: means an exposure method of repeating steps on a wafer to the projection image of a circuit pattern on a mask, thereby transferring the circuit pattern on the mask to a desired portion on the wafer.

In the below-described embodiments, if necessary for convenience' sake, a description will be made after divided into plural sections or plural embodiments. They however relate to each other and unless otherwise specifically indicated, one section or embodiment is a modification example, details or a complementary description of one or whole portion of another section or embodiment.

In the below-described examples, reference is made to the number of elements (including the number, numerical value, quantity and range). The number of the elements is however not limited to a specific one and elements may be used in the number less or greater than the specific number unless otherwise particularly indicated or apparently limited to a specific number in principle.

Furthermore in the below-described embodiments, it is obvious that constituting elements (including elemental steps or the like) are not always indispensable unless otherwise particularly specified or unless otherwise presumed to be apparently indispensable in principle.

Similarly, when reference is made to the shape, positional relationship or the like of constituting elements, those substantially close or similar to their shapes or the like are included unless otherwise specifically indicated or presumed to be apparently different in principle. This also applies to the above-described numerical value and range.

In all the drawings for describing the embodiments of the present invention, like members of a function will be identified by like reference numerals and overlapping descriptions will be omitted.

In the drawings used in these embodiments, a light shielding pattern made of a metal or an organic material is sometimes hatched even in a plan view for facilitating understanding of the drawings.

In the below-described embodiments, MIS-FET (Metal Insulator Semiconductor Field Effect Transistor) representative of field effect transistors will be abbreviated as MIS, and a p-channel type MIS.FET and an n-channel type MIS.FET will be abbreviated as pMIS and nMIS, respectively.

The embodiments of the present invention will hereinafter be described specifically based on accompanying drawings.

(Embodiment 1)

First, manufacture of a mask to be used for the fabrication of the semiconductor integrated circuit device of one embodiment of the present invention will be described.

One example of the production flow of a mask selected by a customer upon fabrication of a semiconductor integrated circuit device is shown in FIG. 1. After formation of pattern layout design data of a mask by using pattern layout design data of a semiconductor integrated circuit device (Step 100), judge whether the semiconductor integrated circuit device is a lifetime production product or not (Step 101). This judgment is made, for example, based on the following equation: total unit price of semiconductor integrated circuit device=((cost of mask×estimated changing frequency+the other cost)/the number of lifetime production)+manufacturing cost. In this equation, “the other cost” includes, for example, a development cost. By predetermining a ratio of the cost of mask in this total unit price (for example, 2%), a threshold lifetime production amount is determined. If the production amount of the semiconductor integrated circuit device to be fabricated exceeds the threshold value, the device is judged as a lifetime production product, while it is less than the threshold value, the device is judged as not a lifetime production product.

The production flow on the left side in FIG. 1 applies to the case where a semiconductor integrated circuit device is not a lifetime production product (in other words, the lifetime production amount is less than the above-described threshold value). In this case, a resist mask is principally used as a mask. In the flow on the left side of FIG. 1, after pre-production step of a resist mask, the fabrication step of a semiconductor integrated circuit device with the resist mask starts. From the pre-production step of a resist mask to the fabrication step of a semiconductor integrated circuit device by using the resist mask, tape-out of a semiconductor integrated circuit device which has a large development factor is performed (Step 102a1), followed by trial manufacture (Step 102a2) of a resist mask for the fabrication of the semiconductor integrated circuit device. Then, after evaluation (Step 102a3) of the resist mask thus manufactured on a trial basis, the quality of its function is judged (Step 102a4). When the resist mask is judged good, it is used upon exposure treatment for the production of a semiconductor integrated circuit (Step 103a). When its function is judged bad, on the other hand, the trial mask is corrected (Step 102a6) and the corrected mask is subjected to the above-described procedure starting from tape-out (Step 102a1). Use of such a resist mask makes it possible to correct or change a mask pattern easily in a short time as described later and at the same time, to reduce a material cost, step cost and fuel cost. By applying such a production flow to a development period or a pre-production period (prior to mass production step) of a semiconductor integrated circuit device, time for development or pre-production of the semiconductor integrated circuit device can be shortened and a development cost or pre-production cost of the semiconductor integrated circuit device can be reduced. This enables production of a semiconductor integrated circuit device, whose production amount is relatively small, at a relatively low cost. It is also possible to switch over to the flow on the most right side and use the above-described conventional mask after judging, in the stage when a subsequent demand for the semiconductor integrated circuit device shows an increase, whether the production amount has increased or not (Step 104) and recognizing the expansion of the production amount. Expansion of production is judged in a similar manner to that for the lifetime production. Such a conventional mask is rich in durability and has high reliability and can therefore be utilized for a great deal of exposure treatment so that it is suited for mass production. By using a conventional mask at the time when expansion of the production of a semiconductor integrated circuit device is confirmed (in other words, at the time when mass production step is started), it is possible to aim at improvement in reliability of the mask upon mass production, leading to an improvement in reliability and yield of the semiconductor integrated circuit device produced using the mask.

In the case where a semiconductor integrated circuit device is judged as a lifetime production product in the step 101 (when the lifetime production amount exceeds the threshold value), the certainty of its function is judged (Step 102b1). This step is for judging the certainty of the function of a semiconductor integrated circuit device. If the judgment results suggest that the design of a customer contains many development factors and the mask must be corrected or changed even several times, the central flow of FIG. 1 is adopted. In this central flow of FIG. 1, the above-described resist mask is employed as a mask used upon development or pre-production period and then, at the time when the customer judges that his target specifications are satisfied, a conventional mask is fabricated and mass production using it is started. Here, after tape-out (Step 102b2) of a semiconductor integrated circuit device which has many development factors, a resist mask for the fabrication of the semiconductor integrated circuit device is manufactured on a trial basis (Step 102b3). Then, the resist mask thus manufactured is evaluated (Step 102b4) and quality of its function is judged (Step 102b5). If the resist mask is judged good, a conventional mask is formed and by exposure treatment therethrough, a semiconductor integrated circuit device is produced. If the resist mask is judged bad, on the other hand, the resist mask thus pre-produced is corrected (Step 102b6) and the corrected resist mask is subjected to the above-described procedures starting from tape-out (Step 102b2). When the customer is satisfied with the target specifications, a conventional mask is formed and by exposure treatment therethrough, a semiconductor integrated circuit device is produced (Step 103b) . In such a development or trial manufacture stage of a semiconductor integrated circuit device when the function is not certain, a resist mask permitting change or correction of mask patterns in a short time at a low cost is adopted. By using this resist mask, it is possible to shorten the time for development or trial manufacture of a semiconductor integrated circuit device and also to drastically reduce the development cost or trial manufacturing cost of the semiconductor integrated circuit device. When the function becomes definite, a conventional mask having rich durability and high reliability and usable for a great deal of exposure treatment is employed. By using a conventional mask, it is possible to aim at an improvement in the reliability of a mask upon mass production, leading to an improvement in reliability and yield of a semiconductor integrated circuit device produced using the mask. Accordingly, a total cost of a semiconductor integrated circuit device produced after going through a development period, trial manufacture period and mass production period can be reduced. In addition, production efficiency of the semiconductor integrated circuit device can be improved.

When the semiconductor integrated circuit device is judged as a lifetime production product in the step 101, the details of the design by a customer have already been debugged, and the function is recognized to be definite in the function certainty step 102bl, there is a little possibility of the mask being changed or modified. In such a case, the flow on the right side of FIG. 1 is adopted. Described specifically, after tape-out (step 102c), a conventional mask is fabricated from the beginning and by using this mask upon exposure treatment, the semiconductor integrated circuit device is produced (step 103c). This makes it possible to reduce the total cost or first cost for the production of a semiconductor integrated circuit device. For the above-described exposure treatment, either one of the step-and-repeat exposure method or the step.and.scan exposure method may be used.

Upon production of such a semiconductor integrated circuit device, a maker or supplier of the semiconductor integrated circuit device proposes the production style of a semiconductor integrated circuit device as illustrated in FIG. 2 to a customer. Here, illustrated are four production types, that is, exclusive use of a resist mask, use of a resist mask for initial production, use of a resist mask for development and exclusive use of a conventional mask. The “exclusive use of a resist mask” is a type as described using the flow on the left side of FIG. 1. The “use of a resist mask for initial production” is a type switched over from the flow on the left side of FIG. 1 to the flow to that on the right side through the step 104. The “use of a resist mask for development” is a type as described using the central flow of FIG. 1, while the “exclusive use of a conventional mask” is a type as described using the flow on the right side of FIG. 1. After investigation of various factors such as lifetime production amount of a semiconductor integrated circuit device estimated from the market data or certainty of the details of a customer's design, a customer can select a production type most suited for each product or each production step from the menu of FIG. 2. The customer can therefore select a desired production style without a particularly difficult judgement.

A maker can post the above-described production type menu on its Web site or special communication area. A customer can select the production type by accessing the Web page or exclusive communication area through a communication line such as internet line or private line. In this case, it is preferred to build a navigation system permitting automatic selection of the optimum production type for a customer. For example, in the Web page or exclusive communication area, a customer who has accessed it is asked questions about various factors such as type, production amount, development cost, development TAT and possibility of pattern change as shown in FIG. 2. This system is designed so that successive answers of the customer to these questions automatically lead to the optimum production type. Of course, it is possible to post, on a Web page or exclusive communication area, the menu for customer as illustrated in FIG. 2 as it is and ask a customer to select the optimum production type. The customer can then easily select the production type most suited for a product or step, thereby producing a semiconductor integrated circuit device efficiently. Makers can supply various data on a semiconductor integrated circuit device immediately in a wide area. The production type can also be selected using a telephone line or another communication means.

FIG. 3 specifically illustrates the production step of a semiconductor integrated circuit device suited for the “development with a resist mask” type. In this diagram, illustrated is proper use of a mask in a vertical integration type semiconductor manufacturing enterprise who carries out designing, development, trial manufacture and production of a semiconductor integrated circuit device consistently by itself. A reduction in the cost of the mask and shortening of the development period or pre-production period are aimed at by the use of a resist mask in the development stage (first quarter to the middle of the fourth quarter) extending over several cuts of TEG (Test Element Group), Prototype and Product version (unit from design to trial manufacture). When the specifications of a product concerning its function and a rise of a demand are confirmed, the production of the mask is switched over from a resist mask to a conventional mask and mass production of a semiconductor integrated circuit device is initiated.

In the next place, an exposure equipment employed in this embodiment is exemplified in FIG. 4.

The exposure equipment 1 is, for example, an ordinarily employed reduction projection exposure system having a light path 1a introducing a light emitted from a light source, a diffuser 1b, aperture 1c of lighting, illumination optics (condenser lens) 1d, mask stage 1e, projection optics 1f and wafer stage 1g. Mask M and wafer 2W are disposed on the mask stage 1e and the wafer stage 1 g, respectively, and mask patterns on the mask M are transferred to the wafer 2W. Examples of an exposure light source include i line (wavelength: 365 nm), KrF excimer laser light (wavelength: 248 nm), ArF excimer laser light (wavelength: 193 nm) and F₂ laser light (wavelength: 157 nm). As the exposure method, either one of the step and repeat exposure method or step and scanning exposure method may be used. As the mask M on the mask stage le, the above-described conventional mask or resist mask is used properly. The mask M on the mask stage 1e is changed as needed depending on the desired kind of patterns to be transferred. A pericle may be disposed on the surface of the mask M. The position of the mask stage 1e is controlled by a driving system 1h, while the position of the wafer stage 1g is controlled by a driving system 1i. The driving systems 1h, 1i are driven according to the control instruction from the main control system 1j. The position of the wafer 2W is determined by using a laser length measuring machine 1k to detect the position of a mirror fixed to the wafer stage 1g. The positional information obtained there is transmitted to the main control system 1j. The main control system 1j drives the driving system 1i based on the information. The main control system 1j is electrically connected to a net work apparatus 1m, which enables remote control of the state of the exposure equipment 1.

A description will next be made of the mask M. The mask M used in this embodiment is a reticle for transferring original integrated circuit patterns of about 1 to 10 times greater than the final size to a wafer through a reduction projection optics. Here, a mask to be used for the transfer of line patterns to a wafer is exemplified. The technical concept of the present invention is not limited to the mask but can be applied to various ones. It is also applicable to a mask for transferring the above-described hole patterns. A conventional mask and resist mask which will hereinafter be described are only examples shown to facilitate understanding of the description and a conventional mask and resist mask usable in the present invention are not limited by them.

FIGS. 5 to 9 each illustrates one example of the conventional mask. In each of FIGS. 5 to 9, (b) is a cross-sectional view taken along a line A-A of (a) of each diagram.

Mask substrate 3 of each of Masks MN1 to MN3, MN4a and MN4b (M) is, for example, made of a transparent synthetic quartz glass substrate which is two-dimensional square in shape and has a thickness of about 6 mm. When the mask MN1, MN2, MN4a or MN4b is employed, a posi resist film is used on the wafer, while when the mask MN3 is employed, a nega resist film is used on the wafer.

The mask MN1 of FIG. 5 shows a mask having a light blocking region at the periphery of a semiconductor chip. In the integrated circuit pattern region at the center of the main surface (pattern formed surface) of the mask substrate 3 in the mask MN1, a two-dimensional rectangular light transmitting region 4a is formed, from which a portion of the main surface of the mask substrate 3 is exposed. In this light transmitting region 4a, light blocking patterns 5a made of a metal are disposed. These light blocking patterns 5a are transferred as line patterns (integrated circuit patterns) on the wafer. The peripheral region at the outer periphery of the integrated circuit pattern region is covered with a light blocking pattern 5b (metal frame) made of a metal. The light blocking patterns 5a, 5b are patterned in the same step and they are formed, for example, from chromium or by depositing chromium oxide on chromium. The metal used as the material of the light blocking pattern is not limited to the above-described one, but various metals can be employed. A description on this metal material will be made later.

In FIG. 6, illustrated is mask MN2 having a light blocking region at the peripheral profile of a semiconductor chip. A description on the integrated circuit pattern region of the mask MN2 is omitted, because it is similar to that of the mask MN1. The integrated circuit pattern region on the main surface of the mask substrate 3 of this mask MN2 is surrounded by a strip-like light blocking pattern 5c (metal frame) made of a metal. The material of the light blocking pattern 5c is similar to that of the light blocking pattern 5a or 5b. A light blocking film is removed from more than half portion of the peripheral region of the mask MN2 so that this region becomes a light transmitting region 4.

In FIG. 7, illustrated is a mask MN3 having reversal patterns relative to the masks MN1, MN2. More than half of the main surface of the mask substrate 3 of this mask MN3 is covered with a light blocking film 5d made of a metal. The material of the light blocking film 5d is similar to that of the light blocking patterns 5b, 5c. In the integrated circuit pattern region of the mask MN3, a portion of the light blocking film 5d is removed and light transmitting patterns 4c are formed. These light transmitting patterns 4c are transferred as line patterns on the wafer. It is possible to form the peripheral region of the mask MN3 of FIG. 7 as that of FIG. 6.

The mask MN4a of FIG. 8 and the mask MN4b of FIG. 9 are masks used for so called overlapping exposure wherein one pattern or one group of patterns is formed by exposure of a plurality of overlapped masks to light.

In the integrated circuit pattern region of the mask MN4a of FIG. 8, a two-dimensional reversed L-shape light transmitting region 4d is formed. In a light transmitting region 4d, the light blocking patterns 5a made of a metal are disposed. More than half of the light transmitting region 4d is covered with a light blocking pattern 5b. The integrated circuit pattern region of the mask MN4 is partially covered with the light blocking pattern 5b. This mask MN4a is used as a mask for transferring circuit patterns constituted of a standard pattern group essentially free from modification or change of pattern in a semiconductor integrated circuit device.

In an integrated circuit pattern region of the mask MN4b of FIG. 9, a two-dimensional square light transmitting region 4e having a relatively small area has been formed. This light transmitting region 4e is formed in a region corresponding to the portion of the integrated circuit pattern region of the mask MN4a covered with the light blocking pattern 5b. Light blocking patterns 5a are disposed in this light transmitting region 4e. A more than half of the light transmitting region 4e is surrounded with the light blocking pattern 5b made of a metal. This mask MN4b serves as a mask for transferring patterns of a circuit constituted of a pattern group to be corrected or changed in the semiconductor integrated circuit device. Described specifically, when the pattern must be corrected or changed, only the mask MN4b is replaced with a new one, leading to saving of a manufacturing time. In addition, a material cost, step cost and fuel cost upon mask manufacture can be reduced. Upon exposure treatment, the wafer is subjected to exposure treatment using the masks MN4a and MN4b. After completion of the exposure treatment with these masks MN4a and MN4b, a resist mask on the wafer is subjected to development or the like, whereby resist patterns are formed on the wafer.

One example of the manufacturing step of such a conventional mask is illustrated in FIG. 10. First, a blocking film 5 made of chromium or the like is deposited over a mask substrate 3, followed by application thereto a resist film 6 photosensitive to an electron beam (FIG. 7(a)). The light blocking film 5 is not limited to chromium but various films can be employed. For example, refractory metals such as tungsten (W), molybdenum (Mo), tantalum (Ta) and titanium (Ti), refractory metal nitrides such as tungsten nitride (WN) and refractory metal silicides (compounds) such as tungsten silicide (WSix) and molybdenum silicide (MoSix), and a laminate film thereof may be used. In the case of a resist mask which will be described later, a light blocking pattern is preferably made of a metal rich in peeling resistance and abrasion resistance, because there is a possibility of washing and then using the mask substrate again after removal of the light blocking pattern made of a resist film. Refractory metals such as tungsten are rich in oxidation resistance, abrasion resistance and peeling resistance so that they are suited as a material for the light blocking pattern made of a metal. Then, resist patterns 6a are formed by exposure of the resist film 6 to electron beams EB having predetermined pattern data and then, development (FIG. 7b). With these resist patterns 6a as an etching mask, the light blocking film 5 is etched to form light blocking patterns 5a, 5b are formed (FIG. 7(c)). The resist patterns 6a photosensitive to electron beams are then removed in the end, whereby a conventional mask M is fabricated (FIG. 7(b)). Such a conventional mask has rich durability and high reliability and can therefore be utilized for a great deal of exposure treatment so that it is suited as a mask used upon mass production of a semiconductor integrated circuit device.

In FIG. 11, another conventional mask MN5 (M) is illustrated. FIG. 11(a) is a plan view of the mask MN5, FIG. 11(b) is a fragmentary enlarged cross-sectional view of (a) and (c) is a modification example and also a fragmentary enlarged cross-sectional view of (a). The mask MN5 of FIG. 11 illustrates the above-described phase shift mask. In a part of a light blocking film 5d deposited over the main surface of a mask substrate 3, light transmitting patterns 4c are formed. On one of the two adjacent patterns of these light transmitting patterns 4c, a phase shifter S is disposed as illustrated in FIG. 11(b) or (c). In FIG. 11(b), illustrated is the phase shifter S formed by cutting a groove in the mask substrate 3. A portion of the groove in its width direction extends even under the light blocking film 5d. This relaxes optical waveguide reduction, thereby making it possible to improve the transfer accuracy. In FIG. 11(c), on the other hand, illustrated is a phase shifter (S) formed by a transparent film. A reversal of phase shift by 180° occurs between a light which has transmitted through the light transmitting patterns 4c with such a phase shifter and a light which has transmitted through the light transmitting patterns 4c without such a phase shifter. The depth of the groove or thickness of the transparent film (d) for forming this phase shifter S is set to satisfy the equation: d=λ/(2(n−1)) wherein λ represents the wavelength of light and n represents a refractive index of the phase shifter. This phase shifter S is only an example and various ones may be used instead. For example, a halftone mask obtained by depositing a semi-transparent film on a mask substrate and then forming light transmitting patterns in this film is usable. In this case, reversal of a phase by 180° occurs between the light which has transmitted through the semi-transparent film and the light which has transmitted through the light transmitting patterns.

In each of FIGS. 12 to 14, one example of the above-described resist mask is illustrated. In each of FIGS. 12 to 14, (b) is a cross-sectional view taken along a line A-A of FIG. (a).

The mask MR1 (M) shown in FIG. 12 illustrates a mask having a light blocking region at the periphery of a semiconductor chip. In the integrated circuit pattern region at the center of the main surface of a mask substrate 3 in this mask MR1, a light transmitting region 4a is formed as a two-dimensional rectangular shape and from it, a portion of the main surface of the mask substrate 3 is exposed. In this light transmitting region 4a, light blocking patterns 7a made of an organic material containing an organic photosensitive resin film such as resist film are disposed. These light blocking patterns 7a are transferred as line patterns on the wafer. By forming the light blocking patterns 7a from a resist mask, removal of the light blocking patterns 7a can be carried out relatively easily as will be described later. And, new light blocking patterns 7a can be formed instead in a convenient matter and at the same time, in a short time. The resist film constituting these light blocking patterns 7a has a property of absorbing an exposure light such as i line, Kr excimer laser light, ArF excimer laser light or F₂ laser light, thus having an almost similar light blocking function to a light blocking pattern made of a metal.

The light blocking patterns 7a may be formed of a single resist film as illustrated in FIG. 12(c) or a light absorbing material or light reducing material may be added to the single film. As illustrated in FIG. 12(d), they may be formed by stacking a photosensitive organic film 7a2 over a light absorptive organic film 7a1, or by stacking an antireflection film over a photosensitive organic film. Such a laminated structure makes it possible to impart them with sufficient light-reducing property even to an exposure light, such as i line or KrF having a wavelength of 200 nm or greater. When the light blocking patterns 7a are formed of a single resist film, sufficient light reducing property even against an exposure light having a wavelength of 200 nm or greater is available by adding a light absorbing material to the resist film. The material of this resist film will be described later. More than half of the outer peripheral region of the integrated circuit pattern region is, similar to the structure of the mask MN1 of FIG. 5, covered with light blocking pattern 5b (metal frame) made of a metal. A technique of forming light blocking patterns from a resist film is described in Japanese Patent Application No. Hei 11(1999)-185221 (filed on Jun. 30, 1999) by the present inventors.

In FIG. 13, illustrated is a mask MR2 (M) having a light blocking region at the peripheral profile of a semiconductor chip. This mask is similar to the conventional mask MN2 of FIG. 6 except that light blocking patterns 7a made of a resist film are disposed in the integrated circuit pattern region 4a.

In FIG. 14, illustrated is a mask MR3 (M) having reversal patterns relative to the mask MR1 or MR2. The integrated circuit pattern region on the main surface of a mask substrate 3 of this mask MR3 is covered with a light blocking film 7b. This light blocking film 7b is made of a similar material to that of the light blocking patterns 7a. In the integrated circuit pattern region of the mask MR3, light blocking film 7b is partially removed and light transmitting patterns 4c are formed. These light transmitting patterns 4c are transferred as line patterns on the wafer. The peripheral region of the mask MR3 of this FIG. 14 may be formed as that of FIG. 13.

In FIGS. 15 to FIG. 19, illustrated is one example of the manufacturing process of such a resist mask. In each of these diagrams, FIG. (b) is a cross-sectional view taken along a line A-A of FIG. (a). Here, the manufacturing process of the mask MR1 of FIG. 12 is illustrated.

After deposition of the light blocking film 5 made of a metal over the mask substrate 3 (FIG. 15), a resist film 6 photosensitive to electron beams is applied onto the light blocking film 5. Then, electron beams having predetermined pattern data are irradiated, followed by development, whereby a resist pattern 6b is formed (FIG. 17). With this resist pattern 6b as an etching mask, the light blocking film 5 is etched to form light blocking pattern 5b. The resist pattern 6b is then removed. The mask substrate 3, at this stage, having the light blocking pattern 5b correspond to one example of the above-described mask blank (FIG. 18). Onto the main surface of the mask substrate 3 having the light blocking pattern 5b, a resist film 7, for example, made of an organic material containing an organic photosensitive resin film to be photosenstive to electron beams is applied to give a film thickness of about 150 nm (FIG. 19). By mask pattern writing and development, light blocking patterns 7a made of the resist film as illustrated in FIG. 12 are then formed, whereby the mask MR1 is manufactured.

As the resist film 7, that composed mainly of a copolymer of α-methylstyrene and α-chloroacrylic acid, a novolac resin and quinone diazide, a novolac resin and polymethylpentene-1-sulfone, or chloromethylated polystyrene is employed. A so-called chemically amplified resist obtained by mixing a phenol resin such as polyvinyl phenol resin or novolac resin with an acid generator is usable. A material of the resist film 7 usable here is not limited to the above-described material, but various materials can be used instead insofar as they have light blocking properties against a light source of a projection exposure equipment and at the same time, to have properties having a sensitivity to a light source of a pattern writing apparatus in the mask manufacturing step, for example, electron beams or a light of 230 nm or greater. The film thickness is not limited to 150 nm and any film thickness satisfying the above-described conditions may be adopted.

When a polyphenol or novolac resin is formed into a film of about 100 nm thickness, transmittance at a wavelength of 150 nm to 230 nm is substantially 0 so that the film has sufficient masking effects against an ArF excimer laser light having a wavelength of 193 nm and an F² laser light of 157 nm in wavelength. Here, a vacuum ultraviolet light having a wavelength not greater than 200 nm is exemplified, but not limited thereto. As a masking material against i line having a wavelength of 365 nm or an KrF excimer laser light having a wavelength of 248 nm, it is preferred to use another material, to add a light absorbing material, light blocking material or light reducing material to a resist film, or to form, as a resist film, a laminate of a light absorptive organic film and an organic photosensitive resin film or a laminate of an organic photosensitive resin film and an antireflection film. Alternatively, so-called hardening treatment of a resist film by forming a light blocking pattern 7a or a light blocking film 7b made of a resist film and then subjecting it to additional heat treatment or preliminary strong exposure to an ultraviolet light in order to improve resistance to light exposure is effective.

In FIGS. 20 to 22, one example of correction or change of the mask pattern of such a mask will next be described. In each of FIGS. 20 to 22, FIG. (b) is a cross-sectional view taken along a line A-A of FIG. (a). In these diagrams, the correcting or changing method of the mask pattern of the mask MR1 of FIG. 12 is illustrated.

First, the light blocking patterns 7a made of a resist film are released from the mask MR1 by using, for example, n-methyl-2-pyrrolidone as an organic solvent. Release of the light blocking patterns made of a resist film may be carried out using a heated amine organic solvent or acetone. It is also possible to remove them by using an aqueous solution of tetramethylammonium hydroxide (TMAH), a mixture of ozone and sulfuric acid, or a mixture of aqueous hydrogen peroxide and concentrated sulfuric acid. When the aqueous TMAH solution is used, adjustment of its concentration to about 5% is preferred, because light blocking patterns made of a resist film can be removed without corroding the metal (light blocking patterns 5b and the like) at such a concentration.

As an alternative method for removing the light blocking patterns made of a resist film, oxygen plasma ashing may be adopted. This oxygen plasma ashing is found to have the highest releasing capacity. This method is particularly effective when the light blocking patterns made of a resist film have been subjected to the above-described hardening treatment. The resist film subjected to hardening treatment is hardened so that it is sometimes not removed completely by the above-described chemical removing method.

The light blocking patterns made of a resist film may be released mechanically by peeling. Described specifically, the light blocking patterns made of a resist film are removed by sticking an adhesive tape to the surface of the mask MR1 on which the light blocking patterns made of a resist film have been formed and then peeling the adhesive tape. Since there is no necessity of preparing a vacuum condition, the light blocking patterns made of a resist film can be released in a relatively easy manner in a short time.

After removal of the light blocking patterns made of a resist film as described above, the mask MR1 is washed to remove foreign maters 50 from the surface of the mask, whereby the state of a mask blank as illustrated in FIG. 18 is formed. For washing, ozone-sulfuric acid washing and brush washing are used in combination, but washing method is not limited thereto but various ones are usable insofar as it has high foreign-matter removing capacity and does not corrode the light blocking patterns made of a metal.

Then, as described above in the resist mask manufacturing step, a resist film 7 is applied to the mask substrate 3 (FIG. 21), followed by mask pattern writing and development, whereby light blocking patterns 7a made of a resist film are formed and thus, the mask MR1 is fabricated (FIG. 22). Here, illustrated is the formation of light blocking patterns 7a different in shape and arrangement from the light blocking patterns 7a of FIG. 12. It is needless to say that the same patterns as the light blocking patterns 7a of FIG. 12 may be formed.

In such a resist mask, problems upon attachment of the mask to various apparatuses such as a mask detecting apparatus and exposure equipment can be avoided owing that a light blocker made of a metal is formed in the peripheral region of the mask or the mask substrate 3 is exposed. When the attached portion of a mask to various apparatuses is brought into contact with a blocker made of a resist film on the mask, abrasion or release of the resist film thereon happens to cause generation of foreign matters and pattern failure. In the above-described resist mask, however, the attached portion to various apparatuses is brought into contact with a blocker made of a metal or mask substrate so that such problems can be avoided. In addition, by forming, from not a metal but a resist film, a light blocker for transferring an integrated circuit pattern, release and regeneration of the mask substrate can be carried out more easily in a shorter time compared with a conventional mask, and at the same time, can be carried out while maintaining the reliability of the mask substrate. The light blocker can be regenerated from the stage after formation of a light blocker made of a metal so that the step cost, material cost and fuel cost can be reduced, which makes it possible to reduce the total cost of the mask drastically. This type of a resist mask is therefore suited for use in a development period or pre-production period of a semiconductor integrated circuit device, or a step for multikind small-quantity production of a semiconductor integrated circuit device wherein a change or correction of the mask pattern tends to occur or sharing frequency of a mask is low.

In FIGS. 23 to 25, another example of a resist mask is shown. Here, illustrated is a mask having all the light blocking patterns on the mask substrate made of a resist film. In each diagram, FIG. (b) is a cross-sectional view taken along a line A-A of FIG. (a).

In the mask MR4 (M) of FIG. 23, the light blocking pattern 5b at the periphery of the mask MR1 of FIG. 12 is formed of a light blocking pattern 7c made of a resist film having the same structure as that of the light blocking patterns 7a. The light blocking pattern 7c is formed using the same material in the same step as the light blocking patterns 7a except that from the light blocking pattern 7c, a portion to be brought into mechanical contact with the mask attached portion of a mask detecting apparatus or exposure equipment has been removed and at this portion, the mask substrate 3 is exposed. This makes it possible to control or prevent generation of foreign matters upon attachment of the mask.

In the mask MRS (M) of FIG. 24, the light blocking pattern 5c of the mask MR2 illustrated in FIG. 13 is formed of a light blocking pattern 7d made of a resist film having the same structure as that of the light blocking patterns 7a. The light blocking pattern 7d is formed using the same material in the same step as those of the light blocking patterns 7a.

In the mask MR6 (M) of FIG. 25, the light blocking film 5d of the conventional mask MN3 illustrated in FIG. 7 is formed of a light blocking film 7e made of a resist film having the same structure as that of the light blocking patterns 7a. The light blocking film 7e has however been removed at a portion to be brought into mechanical contact with the mask attached part of a mask detecting apparatus or exposure equipment and from this portion, the mask substrate 3 is exposed. This makes it possible to control or prevent generation of foreign maters upon mask attachment.

Based on FIGS. 26 to 30, one example of a resist mask forming step and its correction or change step will next be described. In these diagrams, FIG. (b) is a cross-sectional view taken along a line A-A of FIG. (a). Here, a forming step and correcting or changing step of the mask R4 of FIG. 23 are exemplified.

The mask substrate 3 is prepared as a blank (FIG. 26) and a resist film 7 made of a photosensitive organic resin film for forming the above-described light blocker is applied onto the substrate (FIG. 27). Mask pattern writing and development are then carried out to form the light blocking patterns 7a, 7c of FIG. 23 made of a resist film, whereby a mask MR4 is manufactured. The light blocking patterns 7a, 7c made of a resist film may be added with a light absorbing material, light blocking material or light reducing material, or the resist film may be a laminate of a light absorptive organic film and an organic photosensitive resin film or a laminate of an organic photosensitive resin film and an antireflection film. Alternatively, the light blocking patterns 7a, 7c formed from a resist film may be subjected to the above-described hardening treatment.

Then, the mask patterns of the mask MR4 are corrected or changed by removing the light blocking patterns 7a, 7c by using the above-described organic solvent, oxygen plasma ashing or peeling as described above (FIG. 28). The mask substrate 3 is then subjected to washing treatment to remove the foreign matters 50 from the surface of the mask substrate 3, whereby the substrate returns to the state of a blank as illustrated in FIG. 26 (FIG. 29). In a similar manner to the manufacturing step of a resist mask, mask MR4 is manufactured by applying a resist film 7 to the mask substrate 3 and carrying out mask pattern writing and development, thereby forming light blocking patterns 7a, 7c made of a resist film (FIG. 30). Here, illustrated is an example of formation of light blocking patterns 7a different in shape and arrangement from the light blocking patterns 7a of FIG. 23. Of course, the light blocking patterns similar to those of FIG. 23 may be formed.

Since such a resist mask is manufactured without using a metal, a light blocker can be corrected or changed easily in a short time compared with a conventional mask, and more over can be corrected or changed while maintaining the reliability of the mask substrate. In addition, a step cost, material cost and fuel cost can be decreased, making it possible to drastically reduce the total cost of the mask. This type of a resist mask is therefore suited for use in a development period or pre-production period of a semiconductor integrated circuit device, or in a step of multikind small-quantity production of a semiconductor integrated circuit device wherein the mask pattern tends to be corrected or changed or sharing frequency of a mask is low.

In FIGS. 31 to 35, further examples of the above-described resist mask are illustrated. Here, illustrated are masks each having, as a pattern for transferring an integrated circuit pattern on a mask substrate, both light blocking patterns made of a metal and light blocking patterns made of a resist film. In FIGS. 31 to 33 and FIG. 35, FIG. (b) is a cross-sectional view taken along a line A-A of FIG. (a).

In mask MR7 (M) of FIG. 31, a group of the light blocking patterns 5a in a part of the integrated circuit pattern circuit region of the conventional mask MN1 of FIG. 5 are formed of a group of light blocking patterns 7a made of a resist film.

In a mask MR8 (M) of FIG. 32, a group of light blocking patterns 5a in a part of the integrated circuit pattern region of the conventional mask MN2 of FIG. 6 are formed of a group of light blocking patterns 7a made of a resist film.

In a mask MR9 (M) of FIG. 33, a two-dimensional square light transmitting region 4f having a relatively small area is opened in a part of the light blocking film 5d in the integrated circuit pattern circuit region of the conventional mask MN3 of FIG. 7 and the light transmitting region 4f is covered with a light blocking film 7f made of a resist film having the same structure as that of the above-described light blocking pattern 7a. This light blocking film 7f is partially removed to form light transmitting patterns 4c for transferring an integrated circuit pattern.

Illustrated in FIG. 34(a) is a mask MR10 (M) having, partially disposed thereon, a light blocking pattern 7g made of a resist film having the same structure as that of the light blocking pattern 7a. Here, the light blocking pattern 7g is disposed so as to connect the two light blocking patterns 5a which are made of a metal and disposed apart. FIG. 34(b) shows patterns 8a to be transferred onto a wafer upon exposure treatment using the mask MR10 of FIG. 34(a). FIG. 34(c) shows a state of a metal mask from which the light blocking pattern 7g made of a resist film has been removed. FIG. 34(d) schematically illustrates the patterns 8b available by transferring the metal mask patterns of (c) onto a wafer.

The mask MR11(M) illustrated in FIG. 35 is one of the masks used for the above-described overlapping exposure. A group of light blocking patterns 5a made of a metal in the light transmitting region 4e of the mask MN4b of FIG. 9 is formed of a group of light blocking patterns 7a made of a resist film in the mask MR11. In this case, correction or change of the light blocking patterns 7a can be carried out in a easier manner in a shorter time compared with the mask MN4b of FIG. 9. In addition, a step cost, material cost and fuel cost can be reduced, making it possible to drastically reduce the total cost of the mask. The other mask used for overlapping exposure is similar to the mask MN4a of FIG. 8 so that a description of it is omitted. Such overlapping exposure of MN4a and MR11 and formation of a resist pattern are similar to those of the above-described masks MN4a and MN4b.

FIGS. 36 to 43 illustrate one example of a manufacturing step and correcting or changing step of such a resist mask. In these diagrams, FIG. (b) is a cross-sectional view taken along a line A-A of FIG (a). Here, explanation of the manufacturing step and correcting or changing step is mainly made using the mask MR7 of FIG. 31 as an example.

After deposition of a light blocking film 5 made of a metal over a mask substrate 3, a resist film photosensitive to electron beams is applied thereto. The film is developed by exposing it to electron beams having predetermined pattern data, whereby resist patterns 6c are formed (FIG. 36). With the resist patterns 6c as an etching mask, the light blocking film 5 is etched to form light blocking patterns 5a, 5b made of a metal. By removal of the resist patterns 6c, a metal mask is manufactured (FIG. 37). Here, light blocking patterns 5a for transferring an integrated circuit pattern are formed on the mask substrate 3. The states of the metal masks MR8, MR9 after this step are shown in FIGS. 38 and 39, respectively. After application of a resist film 7 (FIG. 40) to the main surface of the mask substrate 3 (FIG. 37) having the light blocking patterns 5a, 5b formed thereon, mask pattern writing and development are carried out, whereby light blocking patterns 7a made of a resist film are formed as illustrated in FIG. 31 and thus, a mask MR7 is manufactured.

For correction or change of the mask patterns of the mask MR7, the light blocking patterns 7a are removed, for example, by using the above-described organic solvent, oxygen plasma ashing or peeling as described above (FIG. 41). Here, light blocking patterns 5a for transferring an integrated circuit patterns are left. Then, the mask substrate 3 is subjected to washing treatment as described above to remove foreign matters 50 from the surface of the mask substrate 3 whereby the metal mask becomes as illustrated in FIG. 37. Then, as described in the manufacturing step of a resist mask, a resist film 7 is applied onto the mask substrate 3 (FIG. 42), followed by mask pattern writing and development to form light blocking patterns 7a made of a resist film, whereby the mask MR7 is manufactured (FIG. 43). Here, illustrated is formation of the light blocking patterns 7a different in shape and arrangement from the light blocking patterns 7a as illustrated in FIG. 31. Of course, patterns similar to the light blocking patterns 7a of FIG. 31 may be formed.

Even in the case of such a resist mask, a metal light blocker formed in the peripheral region of the mask or an exposed portion of the mask substrate 3 makes it possible to avoid problems such as generation of foreign matters and pattern failure. In a conventional mask, the all the patterns must be changed even if only a part of the patterns on the mask must be corrected or changed, while only partial correction or change is necessary in the case of the above-described resist mask. Regeneration of its light blocker can be started in a stage after formation of a light blocker of a metal. This makes it possible to correct or change the patterns easily in a short time while maintaining the reliability of the mask substrate. In addition, the step cost, material cost and fuel cost can be reduced, which makes it possible to considerably reduce the total cost of the mask. This type of a resist mask is therefore suited for use in a development period or pre-production period of a semiconductor integrated circuit device, or in a step for multikind small-quantity production of a semiconductor integrated circuit device wherein a change or correction of the mask pattern tends to occur or sharing frequency of a mask is low.

(Embodiment 2)

In this embodiment 2, a technical concept of the invention is applied to a test stage for the fabrication of a semiconductor integrated circuit device.

Most of the masks used for this test are not used continuously but in a short period of time. Use of the above-described resist mask as a mask is therefore suited for this purpose from the viewpoints of cost, TAT (Turn Around Time) and ease of re-test. Only the persons in charge of this test are necessary, making it possible to improve the efficiency and to reduce the cost. Compared with the case where not a resist mask but only a conventional mask is used upon test in order to reduce the number of steps and cost, a large number of tests (including the same test and different kinds of tests) can be conducted within a relatively short term. This makes it possible to carry out a meticulous test and to attain detailed and relatively many test results, leading to an improvement in the pattern accuracy (size accuracy or alignment accuracy) and in the accuracy of electrical properties of a semiconductor integrated circuit device.

An example of proper use of a conventional mask, electron beam (EB) direct writing treatment (direct writing treatment using energy beams) and a resist mask upon trial manufacture or test is illustrated in FIG. 44 and their respective flows are illustrated in FIGS. 45 to 47. Instead of electron beams in electron beam direct writing treatment, focused ion beam (FIB) or X rays (energy beam) may be used.

First, whether an estimated using amount of a mask is greater than its threshold value or not is investigated. This threshold value may be determined as described in Embodiment 1 or may be determined by a person in charge of the test (Step 200). When the estimated using amount of a mask is not greater than the threshold value, using possibility of a resist mask is studied (Step 201a). If a resist mask is judged usable, it is used. If a resist mask is judged unusable, using possibility of electron beam direct writing treatment is studied (Step 202a). When electron beam direct writing treatment is judged usable, it is used, while it is judged unusable, a conventional mask is employed.

In the step 200, when the estimated using amount of a mask is greater than the threshold value, using possibility of a conventional mask is studied (Step 201b). When a conventional mask is judged usable, it is used. When a conventional mask is judged unusable, on the other hand, using possibility of a resist mask is studied (Step 202b). If a resist mask is judged usable, it is used. When it is judged unusable, electron beam direct writing treatment is used.

FIG. 45 illustrates a test flow of a conventional mask. After formation of test patterns (Step 300), a conventional mask is manufactured using them (Step 301). With the conventional mask, predetermined patterns are transferred onto a wafer, followed by a test (Step 302). At this stage, various conditions are reviewed and with the first conventional mask, patterns are transferred onto a wafer. A test on the pattern-transferred wafer is repeated (Step 303). Based on the results, a conventional mask to be practically used for the fabrication of a semiconductor integrated circuit device is manufactured (Step 304).

FIG. 46 illustrates a test flow of electron beam direct writing treatment. After formation of test patterns (Step 400), electron beams are directly irradiated to a resist film by using them to transfer these patterns onto a wafer, followed by a test (Step 401). After review of the test patterns (Step 402), a resist mask on another wafer is exposed to electron beams, whereby the patterns are transferred onto the another wafer, followed by a test (Step 401). A resist mask on a further wafer is directly exposed to electron beams to transfer patterns onto the further wafer, followed by test (Step 403). Various conditions are then reviewed (Step 404). A resist mask on a still further wafer is directly exposed to electron beams to transfer patterns onto the still further wafer, followed by test (Step 403), whereby a conventional mask or resist mask to be used in practice for the fabrication of a semiconductor integrated circuit device is manufactured (Step 405). With the resultant conventional mask or resist mask, predetermined patterns are transferred onto a wafer, followed by a test (Step 406). Various conditions are then reviewed (Step 407), whereby a conventional mask or resist mask to be used in practice for the fabrication of a semiconductor integrated circuit device is manufactured.

FIG. 47 illustrates a test flow using a resist mask. After formation of test patterns (Step 500), a resist mask is manufactured using them. This resist mask is manufactured using a blank prepared in advance (Step 501). With the resist mask, patterns are transferred onto a wafer and a test is conducted (Step 502). After review of the test patterns (Step 503), patterns are transferred again onto another wafer and a test is conducted (Step 501). With the resist mask, patterns are transferred onto a further wafer, followed by a test (Step 504). After review of various conditions (Step 505), patterns are transferred onto a still further wafer by using the resist mask, and a test is conducted (Step 504). In this manner, a conventional mask or resist mask to be used in practice for the fabrication of a semiconductor integrated circuit device is manufactured (Step 506). From the used resist mask, patterns made of a resist film are removed and the resulting mask is stored as a mask blank, which will be regenerated as a mask for a test use.

In the test of a conventional mask, the mask is not reshaped except the case where it is utterly unusable and instead, conditions are regulated from the viewpoints of its preparation TAT and cost. In the case of electron beam writing treatment, correction or change of patterns can be conducted easily so that conditions are regulated using the optimum patterns. Upon actual fabrication of a semiconductor integrated circuit device (product), not electron beam direct writing but exposure treatment with a mask is usually performed, which needs review of conditions again because the conditions are different. When a resist mask is employed, correction or change of patterns is not so easy as that of electron beam direct writing but is markedly easy compared with a conventional mask. After formation of the optimum patterns, a test can be made under the same conditions as those for actual fabrication of a semiconductor integrated circuit device. Storage of the above-described blank for the formation of a mask only for test use remarkably facilitates simplification of detection/regeneration and operation of an amount. Use of a resist mask is therefore suited for a test which does not need many masks.

In this Embodiment, a mask for test use can be prepared in a short time and in addition, its cost can be reduced, which enables an increase in testing frequency. Since the test thus made is meticulous, reliability or performance of a semiconductor integrated circuit device can be improved. By using the above-described three methods properly, the optimum cost performance can be attained.

(Embodiment 3)

In this embodiment, described is application of the technical concept of the present invention to the case where a commercially available step diagnosis support or process measurement is conducted.

The evaluation technique investigated by the present inventors is, for example, as follows. First, an evaluation vendor provides test patterns to a user. The user manufactures a mask based on the test patterns and user data merge and by using the mask, transfers predetermined patterns onto a wafer and then observes or measures these patterns (for example, detect whether foreign matters exist or not, and measure the line width). The user submits the data thus obtained to the evaluation vendor and asks evaluation. If there are some mistakes at this stage, the user must carry out these procedures again. The mask is manufactured at the cost of the user.

In this Embodiment, the above-described resist mask is employed upon evaluation. As illustrated in FIG. 48, a user provides a user pattern to an evaluation vendor (Step 600). The evaluation vendor fabricates a mask based on the test pattern and user data merge. Here, a resist mask is used (Steps 601, 602). The evaluation vendor submits the mask to the user (Step 603). The user carries out exposure treatment with the mask, thereby transferring patterns onto a wafer (Sep 604), and then, submits the wafer to the evaluation vendor (Step 605). The evaluation vendor observes or measures the patterns on the wafer thus submitted, for example, detects existence of foreign matters and measures line width (Step 606); makes evaluation (Step 607); and provide the results to the user (Step 608). Alternatively, the user may observe or measure foreign matters, line width and the like, submit the results to the evaluation vendor, and ask the vendor to make evaluation.

Since the evaluation vendor takes charge of the fabrication of a resist mask, a reduction of a contract cost and fabrication of a mask by a person of skill, as well as a reduction in mask cost, can be attained, making it possible to carry out primary evaluation, which is otherwise expensive, at a low cost. Moreover, the work of the user can be reduced. In other words, the user just has to prepare a wafer, while the evaluation vendor takes charge of data preparation, measurement and evaluation. This enables desired division of labor in a specialized field. Thus, shortening of TAT and quality improvement can be attained.

As a modification example of it, a mask maker can be interposed between a user and an evaluation vendor. In such a case, the user provides a user pattern to the mask maker. The mask maker prepares a resist mask as described above based on the test patterns and user data merge. The mask maker submits the resulting mask to the user. The user carries out exposure treatment using the mask, thereby transferring the patterns onto a wafer and then submits the wafer to the evaluation vendor. The evaluation vendor observes or measures foreign matters, line width and the like of the patterns on the wafer thus submitted and provides the user with the evaluation results. Alternatively, the user may observe or measure foreign matters, line width and the like and ask the evaluation vendor to evaluate the results of the observation or measurement. This enables desired division of labor in a specialized field. Thus, shortening of TAT and quality improvement can be attained from the total point of view.

(Embodiment 4)

In a pre-production step during production of a semiconductor integrated circuit device, a plurality of devices are evaluated for electrical properties, pattern size and the like. The device judged most suited from these points is mass produced as a product. When trial manufacture is conducted using only a conventional mask, it takes time to manufacture a plurality of the conventional masks, which increases a manufacturing cost of the mask even in the pre-production stage and therefore preventing evaluation of many devices.

In this Embodiment, a resist mask is employed in a pre-production step of a semiconductor integrated circuit device, while a conventional mask is employed in a mass production step thereafter. Such a using manner will be described below based on FIG. 50, with reference to the flow of FIG. 49.

After formation of design data of a mask (Step 700), a mask for trial manufacture is fabricated based on them. For this mask, a resist mask is employed (Step 701). In FIG. 50(a), a mask MR12 having a resist mask of this stage as a light blocking pattern is illustrated. The detailed structure of the mask MR12 is similar to the above-described various resist masks so that a description on it is omitted. Here, on the mask MR12, for example, four integrated circuit pattern regions are disposed (multi-chip mask or multi-chip reticle). Each of the integrated circuit pattern regions corresponds to one semiconductor chip (hereinafter be called “chip”, simply). In the integrated circuit pattern regions, mask patterns which are similar in kind (same product) but different in data, more specifically, Data D0 to D4, are disposed, respectively. In the integrated circuit pattern regions on the mask MR12, mask patterns different in trimming of the electrical properties such as resistance or capacity are disposed. This diagram indicates that a plurality of integrated circuit pattern regions are disposed on the mask MR12, but the number of the integrated circuit pattern regions is not limited to 4.

As illustrated in FIG. 49, exposure treatment is conducted using the mask MR12, whereby a trial product is obtained (Step 702). The trial product is then evaluated (Step 403). Based on the evaluation results, the product is corrected, followed by repetition of trial manufacture and evaluation (Step 704).

In this Embodiment, patterns of a plurality of chips can be transferred onto a wafer by one exposure treatment, meaning that a plurality of trial cases can be evaluated simultaneously. For example, in a semiconductor integrated circuit device having an analogue circuit, it is sometimes inevitable to start fabrication without sufficiently considering electrical properties such as resistance and capacity. Application of the above-described method to such a case enables evaluation of a plurality of trial cases in a short time, making it possible to improve electrical properties of such a semiconductor integrated circuit device having an analogue circuit. In addition, when sizing in a critical path is changed or the optimizing level of a logic is changed, shortening of a trial manufacture time and improvement in the performance of a semiconductor integrated circuit device can be attained simultaneously by forming a plurality of trial cases on one mask. Particularly when trial manufacture is carried out more than once, use of a resist mask can bring about a considerable reduction in the trial manufacturing time and cost of a mask compared with the use of a conventional mask. These effects are marked in the products of small-quantity multikind production such as ASIC (Application Specific IC). Accordingly, it is markedly effective to apply the technical concept of this embodiment to a small-quantity multikind production process.

When the data of the mask which is judged good or optimum in the evaluation step 703 are obtained, a mask for mass production is manufactured (Step 705) based on them and by using this mask upon exposure treatment, a semiconductor integrated circuit device is fabricated (Step 706). Upon this mass production, the above-described conventional mask having rich durability and high reliability and being therefore usable for a great deal of exposure treatment is used. FIG. 50(b) illustrates the conventional mask MN6 in this stage. Detailed structure of the mask MN6 is similar to that of various conventional masks so that a description on it is omitted. Also in this mask, four integrated circuit pattern regions are disposed on the mask MN6 (multi-chip mask or multi-chip reticle). Each integrated circuit pattern region corresponds to one chip. In respective integrated circuit pattern regions, mask patterns of the same kind (same product) and having the same data (here, Data 2 is shown) as those of the mask judged good or optimum in the evaluation step 703 are disposed. The number of the plurality of integrated circuit pattern regions on the mask MN6 is not limited to 4.

As described above, drastic reductions of the cost and time of a mask for trial manufacture can be attained in this embodiment, enabling the most effective trial manufacture without taking mass production in consideration. It is therefore possible to improve the performance, reliability and yield of a semiconductor integrated circuit device to be mass produced after such trial manufacture.

(Embodiment 5)

In the above-described Embodiment 4, a description was made on the formation of a multi-chip using the same kind of chips (same products). In this embodiment, on the other hand, formation of a multi-chip by disposing different kinds of chips on a mask will be described.

FIG. 51 illustrates a technique investigated by the present inventors for the present invention. On the chips C1 to C7, semiconductor integrated circuit devices different in kind are formed, respectively. In FIG. 51(a), an arrow means the designing term of a semiconductor integrated circuit device. FIG. 51(b) is a plan view of a mask M50, while FIG. 51(c) is a plan view of a mask M51. The data DC1 to DC7 of each of FIGS. 51(b) and (c) indicate mask pattern data of chips C1 to C7, respectively.

In this technique, a group of chips to be disposed on one mask have already been determined at the designing stage of a semiconductor integrated circuit device. For example, chips C1 to C4 are disposed on the mask MR50 and chips C5 to C7 are disposed on the mask MR51. In this case, the manufacturing period of the mask M50 is controlled by the designing term of the chip C2 which is the longest of all the chips, while that of the mask 51 is controlled by the designing term of the chip C5 which is the longest of all. This happens to generate a loss time in the manufacture of a semiconductor integrated circuit device.

In this embodiment, the chips are therefore disposed on the mask in the order of completion of the designing term of a semiconductor integrated circuit device. FIG. 52 illustrates this concept. FIG. 52(a) illustrates the designing terms of chips C1 to C7 and a manner of grouping and disposing them on a mask. The arrow in the diagram shows the designing term of the semiconductor integrated circuit device. FIGS. 52(b) and (c) illustrate the plan views of the mask M1 and M2, respectively. The chips C1 to C7 are products of different kinds.

Here, the chips whose designing terms of a semiconductor integrated circuit device are completed almost at the same time are disposed on one (same) mask, for example, the chips C1, C3, C4 and C6 are disposed on the mask M1, while chips C2, C3 and C7 are disposed on the mask M2. Either one of the conventional mask or resist mask is usable as the mask M1 or M2, but in this case, the latter one is preferred because it makes it possible to flexibly change the pattern constitution until trial manufacture is started and to drastically shorten the fabrication time of a mask. It is desired to standardize the size of the chips C1 to C7 (1/1, 1/2, 1/3, 2/3, 1/4, 1/6, 1/9, 2/9 and 4/9 of the mask size), thereby disposing them on a mask efficiently.

According to this embodiment, a loss time upon fabrication of the mask M1 can be reduced by time T compared with the technique of FIG. 51. In addition, a cost for trial manufacture per kind can be reduced. A cost merit is presumed to be brought by adopting a mask and lot exclusively used for a pre-production step and actualizing a pre-production step of the lowest cost without considering mass production, for example, by manufacturing a mask as a periodical pre-production lot on the side of a vendor of a semiconductor integrated circuit device, suppressing a pre-production cost of a device of which a foundry has received the order or carrying out trial manufacture as a foundry specialized in trial manufacture.

(Embodiment 6)

In this embodiment, a pre-production step of a semiconductor integrated circuit device by using the above-described multi-chip mask will be described. It is to be noted that the term “cut” as used herein means a unit from design to trial manufacture of a semiconductor integrated circuit device.

When a multi-chip type conventional mask is made using a conventional mask, a chip which does not require re-manufacture is manufactured again upon changing of the chip during the cut. For example, when in a first cut, one chip region of a multi-chip mask is evaluated bad and the other chip regions are judged good, only the former chip must be manufactured again in a second cut. In practice, however, since only some layers tend to be corrected, chip disposal cannot be changed, which requires re-manufacture of even chip regions which are judged good in order to prevent extension of the mask manufacturing time. It is wasteful and becomes one of the factors inhibiting a cost reduction of a mask and a reduction of cost for trial manufacture.

In this Embodiment, a resist mask is used for trial manufacture of a semiconductor integrated circuit device. FIG. 53(a) illustrates the cut state of chips C1 to C7. FIG. 53(b) is a plan view of a mask MR13 upon first cut, while FIG. 53(c) is a plan view of a mask MR14 upon second cut. The above-described resist mask is used as the mask MR13 and MR14. The resist mask has a similar structure to that described above, so a description on it is omitted. The symbols DC1 to DC7 in these diagrams indicate mask pattern data of chips C1 to C7, respectively.

FIG. 53 illustrates that in the first cut, the chips C2, C3, C6 are evaluated good, while the other chips are evaluated bad. In this case, only chip regions for forming the chips C1, C4, C5, C7 which are judged bad in the first cut are disposed on the mask MR14 and trial manufacture is carried out using this upon exposure treatment. In this embodiment, the whole layer of the mask must be prepared, but cost and TAT can be reduced sufficiently and only utterly necessary chips can be pre-produced in this embodiment. It is therefore possible to shorten the pre-production period of plural semiconductor integrated circuit devices and, in turn, to shorten the fabrication time of plural semiconductor integrated circuit devices.

(Embodiment 7)

Some semiconductor integrated circuit devices have been mass produced since at least 10 years ago. Such semiconductors are not ordered regularly and the production amount cannot be expected so that masks used for their production cannot be discarded. Masks therefore sometimes remain as a doubtful asset or they are prepared regularly in anticipation of the future demand.

In this Embodiment, upon fabrication of such a semiconductor integrated circuit device, the above-described conventional mask is employed in the first mass-production term and after completion of the mass-production term, the conventional mask is discarded. When the same semiconductor integrated circuit device is required after that, it is fabricated again using the above-described resist mask. In other words, when a mask becomes necessary in such a semiconductor integrated circuit device, only the necessary amount of the mask is manufactured from a resist mask and the semiconductor integrated circuit device is fabricated again by using it upon exposure treatment. In this case, the resist mask may be used when mass production of the semiconductor integrated circuit device is started after that. Alternatively, a conventional mask may be used if the mass production amount exceeds the threshold value. When a resist mask is used, correction or change of mask patterns can be completed in a short time so that a multi-chip can be formed by collecting semiconductor integrated circuit devices of a less mass production amount. In either case, since a mask must be prepared not regularly but by necessity, it is possible to avoid waste. Fabrication of a resist mask may be started from the state of a blank so that it is possible to prepare a necessary mask in a short time. After use, the mask may be stored as its blank state so as to apply it to any product (general-purpose product) as needed. This makes it possible to drastically reduce the cost of such a semiconductor integrated circuit device. In addition, this makes it possible to supply such a semiconductor integrated circuit device speedily at any time according to the demand.

(Embodiment 8)

In this Embodiment, a multi-chip mask is employed in order to increase variations of a predetermined portion in a chip and to change patterns corresponding to the predetermined portion of the multi-chip mask whenever the predetermined number of devices are treated.

FIGS. 55(a) and (b) are plan views of masks MR20a and MR20b, respectively. As the masks MR20a and MR20b, the resist mask is employed. Particularly, use of the resist mask as described in FIGS. 31 to 35 is preferred.

On the mask MR20a, for example, four integrated circuit pattern regions are disposed. These integrated circuit pattern regions correspond to chips having different data DC1 to DC4 patterns. Patterns P1 to P4 schematically illustrate that the patterns in the pattern region corresponding to the predetermined portion are different respectively among these integrated circuit pattern regions. By using this mask MR20a upon exposure treatment, patterns are transferred onto a wafer, whereby a semiconductor integrated circuit device is fabricated. After completion of exposure treatment of a predetermined number of devices, the patterns P1 to P4 are removed from the mask MR20a, whereby the mask MR20b is formed as illustrated in FIG. 55(b). In other words, patterns of a region corresponding to the predetermined portion on the mask MR20a are changed. This pattern changing manner is similar to the correcting or changing manner of light blocking patterns made of a resist film as described in Embodiment 1.

On the mark MR20b, for example four integrated circuit pattern regions are disposed. The integrated circuit pattern regions correspond to chips and they have data DC5 to DC8 patterns which are different each other. The patterns P5 to P8 of the mask MR20b schematically illustrate that they are different from the patterns P1 to P4 of the mask MR20a; and the patterns in the integrated circuit pattern regions of mask MR20b corresponding to the predetermined portion are different each other. By using this mark MR20b upon exposure treatment, patterns are transferred onto a wafer, whereby a semiconductor integrated circuit device is fabricated. After completion of exposure treatment of a predetermined number of devices, patterns in a region corresponding to the predetermined region on the mask MR20b may be changed.

As a specific example of such a pattern change, a change of the pattern size of a critical path into the optimum one can be mentioned. In the critical path, pattern size requires high accuracy. The optimum pattern size varies by a process. Pattern transfer at such a position by using only a conventional mask inevitably retards development time, pre-production time and fabrication time of a semiconductor integrated circuit device, making it difficult to set a more suited size based on many data collected. When a resist mask is used, on the other hand, many data are available and more suited size can be set based on them without markedly retarding development, trial manufacture and fabrication time, making it possible to fabricate a semiconductor integrated circuit device having high performance and reliability in a high yield.

As another specific example of such a pattern change, encoding of data of ROM (Read Only Memory) can be mentioned. In an encoding chip, patterns of ROM are encoded, but a decoding method usually remains unchanged. Usable as an encoding method at present is that comprising encoding of ROM data: f(x), address shuffle: g(x) and shuffle of a decoding circuit: h(x). Supposing that an encoding function is k(x), an equation: k(x)=h(g(f(x))) is established. Any device at each stage fails to form a difference in the encoding level if the whole is regarded as a composite function or to exceed a range permitting treatment by a decoding circuit. In addition, breaking of even one code leads to decoding of all the data.

In this Embodiment, a plurality of the above-described decoding circuits are formed on a logic circuit other than ROM by making use of a multi-chip mask or a plurality of masks (each, a resist mask) as described above. In this case, a plurality of decoding circuits can be formed, the following equation can be established: k(x)=h1(g1(f1(x)))=h2(g2(f2(x)))=h3(g3(f3(x))) . . . If a card leader is imparted with a decoding function, another encoding can be actualized such as k1(x)=h1(g1(f1(x))), k2(x)=h2(g2(f2(x))), k3(x)=h3(g3(f3(x))) . . . , making it impossible to drastically increase the difficulty in decoding, thereby making it impossible to decode the data in practice.

(Embodiment 9)

In this Embodiment, application of the technical concept of the present invention to a manufacturing process of ASIC such as gate array, standard cell or embedded array will be described.

FIG. 56 illustrates one example of the production flow of the semiconductor integrated circuit device according to this Embodiment. A semiconductor integrated circuit device (custom LSI (Large Scale Integrated Circuit)) such as gate array has a gate array diffusion layer (master layer) made of a predetermined patterns which are common to customers, while it has, as a wiring layer over the diffusion layer, a custom layer which is corrected or changed by the request of a customer.

In this Embodiment, patterns of the master layer are formed using the conventional mask in the development and pre-production steps prior to mass production and also in the mass production step. Patterns of the custom layer are, on the other hand, manufactured using the resist mask until the completion of the debugging according to the customer's specification. Upon obtaining the approval of a customer for starting of mass production, the mask is switched over to the conventional mask and mass production of a custom LSI is started. FIG. 56 illustrates one example of the production flow of the custom LSI. The conventional mask is employed in an active region forming step 800, well forming step 801, gate electrode forming step 802 and semiconductor region forming step 803 for source and drain in FIG. 56. In a contact hole forming step 804, first-level interconnect forming step 805, first through-hole forming step 806, second-level interconnect forming step 807, second through-hole forming step 808 and third-level interconnect forming step 809 in FIG. 56, a resist mask is employed first, followed by the use of the conventional mask upon mass production. This flow suggests that a bonding pad forming step 810 is included in the custom layer. This step may be formed either with a mask or without a mask. At this time, it is preferred that a maker prepares a menu for custom LSI such as use of a flash memory (EEPROM: Electric Erasable Programmable Read Only Memory) for an FPGA (Field Programmable Gate Array), use of a resist mask for a gate array, use of a conventional mask for a gate array and so on, while a customer selects one from the menu according to the production amount.

According to this Embodiment, it is possible to considerably shorten the development time of a custom LSI, to provide the custom LSI which can satisfy the request of a customer, and to drastically decrease the development cost of the custom LSI. A maker can therefore carry out small-quantity multikind production of the custom LSI. In other words, the maker can receive a contract to carry out small-quantity multikind production of a custom LSI which is otherwise refused because the production amount is too small, thereby increasing the total sales. The customer, on the other hand, can acquire, at a low cost, the custom LSI of high reliability meeting its specifications.

The structure of the custom LSI and its manufacturing process will next be exemplified.

FIG. 57 is a plan view illustrating a part of a logic element of the custom LSI. This logic element is made of a unit cell 10 surrounded by a dashed line in FIG. 57. This unit cell 10 is formed of, for example, two nMISQns and two pMISQps. The nMISQn is disposed over an n type semiconductor region (diffusion layer) 11n on the surface of a p type well region PW, while the pMISQp is disposed over a p type semiconductor region (diffusion layer) lip on the surface of an n type well region NW, each formed over a semiconductor substrate. A gate electrode 12A is common to nMISQn and pMISQp. The gate electrode 12A is formed to have, for example, a polycide structure wherein a silicide layer is disposed over a single film of low-resistance polycrystalline silicon or a low-resistance polycrystalline silicon film; a polymetal structure obtained by depositing, over a low resistance polycrystalline silicon film, a metal film, for example, tungsten via a barrier film such as tungsten nitride; or a damascene gate electrode structure obtained by depositing a barrier film such as titanium nitride in a groove made in an insulating film and then embedding the groove with a metal film such as copper. A portion of the semiconductor substrate below the gate electrode 12A serves as a channel region.

An interconnect 13A is, for example, for a power source on the high potential side (for example, 3.3V or 1.8V) and is electrically connected with the p type semiconductor region lip of the two pMISQps via a contact hole CNT. An interconnect 13B is, for example, for a power source on the low potential side (for example, 0 V) and is electrically connected with the n type semiconductor region 11n of the one nMISQn via a contact hole CNT. An interconnect 13C is an input interconnect for a two-input NAND gate circuit and is brought into contact with the gate electrode 12A at its broad portion and electrically connected therewith. An interconnect 13D is electrically connected with both the n type semiconductor region 11n and p type semiconductor region 11p via a contact hole CNT. An interconnect 14A is electrically connected with the interconnect 13D via a through-hole TH.

A plan view of the unit cell 10 before formation of the interconnects 13A to 13D and 14A is illustrated in FIG. 58. This unit cell 10 corresponds to the above-described master layer and, for example, a basic constituent common for constituting a logic element such as NAND gate circuit or NOR gate circuit. The logic circuit can be formed efficiently by properly selecting interconnects after the formation step of this unit cell 10. This invention can also be applied even to a constitution for connecting a large number of CMIS (Complementary MIS) circuits.

Until the formation of such a unit cell 10 corresponding to a master layer, the above-described conventional mask is employed. The integrated circuit pattern regions of the conventional mask used at this time are illustrated in FIG. 59. FIG. 59(a) illustrates a mask MN7 used upon formation of an element isolating portion and an active region in the unit cell 10 on a wafer (semiconductor substrate). On the main surface of the mask substrate 3, two light blocking patterns 5e, for example, in a two-dimensional rectangular shape are disposed apart in parallel. These light blocking patterns 5e are made of the same metal as that of the light blocking pattern 5a and are formed to block a light in the active region on the wafer. FIG. 59(b) illustrates a mask MN8 used upon formation of an n type well region NW in the unit cell 10. On the main surface of the mask substrate 3, a light blocking film Sf is deposited and in one part of the film, a light transmitting pattern 4g, for example, in a two-dimensional rectangular shape is opened. The light blocking film 5f is made of the same metal as that of the light blocking pattern 5a and it is formed to block irradiation of a light to a region other than the n type well region on the wafer. FIG. 59(c) illustrates a mask MN9 used upon formation of a p type well region PW in the unit cell 10. On the main surface of the mask substrate 3, a light blocking film 5f is deposited and in one part of the film, a light transmitting pattern 4h, for example, in a two-dimensional rectangular shape is opened. The light blocking film 5f is formed to block irradiation of a light to a region other than the p type well region on the wafer. FIG. 59(d) illustrates a mask MN10 used upon formation of a gate electrode 12A in the unit cell 10. On the main surface of the mask substrate 3, two light blocking patterns 5g, for example, in the strip shape having a broader portion at both ends are formed in parallel each other. The light blocking patterns 5g are made of the same metal as that of the light blocking pattern 5a and are formed to block irradiation of a light to the gate electrode forming region on the wafer.

With reference to FIGS. 60 to 69, steps up to formation of nMISQn and pMISQp will next be described using a cross-sectional view taken along a broken line of FIG. 58.

As illustrated in FIG. 60, after formation, by the oxidation method, of an insulating film 15 made of a silicon oxide film over the main surface (device surface) of a semiconductor substrate 2S constituting a wafer 2W made of p type silicon single crystals, an insulating film 16 made of a silicon nitride film is deposited over the insulating film 15 by CVD, followed by application of a resist film 17 thereto. As illustrated in FIG. 61, the semiconductor substrate 2S is subjected to exposure treatment with the above-described conventional mask MN7, followed by development, whereby a resist pattern 17a is formed over the main surface of the semiconductor substrate 2S. The resist pattern 17a is formed two dimensionally to cover the active region, while allowing an element isolating region to be exposed from the resist pattern. With the resist pattern 17a as an etching mask, the insulating films 16, 15 exposed therefrom are removed in this order. By removing the main surface portion of the semiconductor substrate 2S exposed by this etching, a groove 18 is formed in this main surface of the semiconductor substrate 2S. Then, the resist pattern 17a is removed.

As illustrated in FIG. 63, an insulating film 19 made of silicon oxide is deposited by CVD (Chemical Vapor Deposition) over the main surface of the semiconductor substrate 2S, followed by planarization by chemical mechanical polishing (CMP) of the semiconductor substrate 2S, whereby a groove type element isolating portion SG is finally formed (Step 800 of FIG. 56). In this Embodiment, the element isolating portion SG is formed to have a groove type isolating structure (trench isolation), but it is not limited thereto but may be formed from a field insulating film by LOCOS (Local Oxidization of Silicon).

After application of a resist film onto the main surface of the semiconductor substrate 2S, exposure treatment is given to the semiconductor substrate 2S by using the conventional mask MN8, whereby a resist pattern 17b is formed over the main surface of the semiconductor substrate 2S as illustrated in FIG. 65. The resist pattern 17b is formed two-dimensionally so as to expose therefrom the n type well region NW and to cover therewith the other region. With the resist pattern 17b as an ion implantation mask, phosphorus or arsenic is ion implanted into the semiconductor substrate 2S to form an n type well region NW. Then, the resist pattern 17b is removed.

Onto the main surface of the semiconductor substrate 2S, a resist film is applied similarly, followed by exposure treatment with the conventional mask MN9 to form over the main surface of the semiconductor substrate 2S a resist pattern 17c so as to expose therefrom a p type well PW and to cover therewith the other region as illustrated in FIG. 66. With the resist pattern 17c as an ion implantation mask, boron is ion implanted into the semiconductor substrate 2S to form the p type well PW. Then, the resist pattern 17c is removed (Step 801 of FIG. 56).

As illustrated in FIG. 67, a gate insulating film 20 made of a silicon oxide film is formed over the main surface of the semiconductor substrate 2S to give a thickness (thickness in terms of silicon dioxide) of about 3 nm by the thermal oxidation method, followed by deposition of a conductor film 12 made of polycrystalline silicon by CVD. After application of a resist film onto the conductor film 12, exposure treatment with the conventional mask MN10 is given as illustrated as in FIG. 68, whereby a resist pattern 17d is formed so as to cover therewith a gate electrode forming region while to expose therefrom the other region. With the resist pattern 17d as an etching mask, the conductor film 12 is then etched to form a gate electrode 12A (Step 802 of FIG. 56). By ion implantation or diffusion method, the high-impurity-concentration n type semiconductor region 11n for nMISQn and a high-impurity-concentration p type semiconductor region 11p for pMISQp which regions also serve as a source or drain region or wiring layer are formed in self alignment with the gate electrode 12A (Step 803 of FIG. 56). As the resist patterns 17a to 17d, posi patterns are employed.

By properly selecting an interconnect in the subsequent step, various logic circuits such as NAND gate circuit and NOR gate circuit can be formed. In this Embodiment, a NAND gate circuit ND as illustrated in FIG. 70 is formed. FIG. 70(a) illustrates the symbols of the NAND gate circuit ND, FIG. 70(b) is its circuit diagram and FIG. 70(c) is its plain layout view. Here, illustrated is an NAND gate circuit ND having two inputs I1,I2 and one output F.

In FIGS. 71(a) and (b), fragmentary plan views of patterns of a mask for transferring contact hole and interconnect patterns of the NAND gate circuit ND are illustrated. In FIG. 71, the X-Y axes are indicated for better understanding of the positional relationship of the masks of (a) and (b).

FIG. 71(a) illustrates patterns of a mask MR21 for transferring the contact hole CNT of FIG. 70(c) onto a wafer. The light blocking film 7h is made of the same resist film as that of the light blocking pattern 7a. The light blocking film 7h is partially removed and instead, it has a plurality of openings of fine light transmitting patterns 4i in the two-dimensional square shape. The light transmitting patterns 4i serve as patterns for forming contact holes CNT. FIG. 71(b) illustrates patterns of a mask MR22 for transferring interconnects 13A to 13D of FIG. 70(c) onto the wafer. The light blocking patterns 7i are made of a resist film having a similar constitution to that of the light blocking pattern 7a as described in the above-described embodiment. The light blocking patterns 7i serve as patterns for forming the interconnects 13A to 13D. The manufacturing method of these masks MR21, MR22 is similar to the above-described one so that a description is omitted.

A fabrication process of a semiconductor integrated circuit device by using these masks MR21, MR22 will next be described based on FIGS. 72 to 76. FIGS. 72 to 76 are each a cross-sectional view taken along a broken line of FIG. 70(c).

As illustrated in FIG. 72, after formation of nMISQn and pMISQp on the main surface of a semiconductor substrate 2S as described above, an interlevel insulating film 21a made of a silicon oxide film and doped with phosphorus is deposited by CVD. Onto the interlevel insulating film 21a, a resist film is then applied. By exposure treatment using the mask MR21, a resist pattern 17e is formed so as to expose therefrom a contact hole forming region in the two-dimensional substantially circular shape while to cover the other portion. With this resist pattern 17e as an etching mask, a contact hole CNT is formed in the interlevel insulating film 21a as illustrated in FIG. 73 (Step 804 of FIG. 56).

After removal of the resist pattern 17e, a conductor film 13 made of aluminum, aluminum alloy or copper is deposited by sputtering over the main surface of the semiconductor substrate 2S as illustrated in FIG. 74. A resist film is then applied to the conductor film 13 and then, exposure treatment is given to it by using the mask MR22 to form a resist pattern 17f so as to cover therewith the interconnect forming region while to expose the other region as illustrated in FIG. 75. With this resist pattern 17f as an etching mask, the conductor film 13 is etched to form interconnects 13A to 13D (Step 805 of FIG. 56). The resist patterns 17e, 17f used here are posi type. As illustrated in FIG. 76, an interlevel insulating film 21b is deposited over the main surface of the semiconductor substrate 2S by CVD and with another mask, a through-hole TH and overlying interconnect 14A are formed (Steps 806, 807 of FIG. 56). Line connection between parts is effected by repeating pattern formation by necessary times, whereby a semiconductor integrated circuit device is fabricated.

Described above is a formation example of a two-input NAND gate circuit, but a NOR gate circuit can also be formed easily by changing the pattern shape of a mask. FIG. 77 illustrates a two-input NOR circuit NR formed using the above-described unit cell 10. FIG. 77(a) illustrates the symbols of the NOR circuit NR, FIG. 77(b) is its circuit diagram and FIG. 77(c) illustrates its plain layout.

As illustrated in FIG. 77(c), an interconnect 13A is electrically connected, via a contact hole CNT, with a p type semiconductor region lip of one of the pMISQps, while an interconnect 13E is electrically connected, via a contact hole CNT, with the p type semiconductor region 11n of the other one of the pMISQps. The interconnect 13E is also electrically connected, via a contact hole CNT, with an n type semiconductor region 11n common to both nMISQns. The interconnect 13B is electrically connected, via a contact hole CNT, with the n type semiconductor region 11n of the both nMISQn.

One example of a fragmentary plan view of the patterns of a mask for transferring contact hole and interconnect patterns of such an NOR gate circuit NR is illustrated in FIGS. 78(a) and (b). For better understanding of the positional relationship between these masks in FIGS. 78(a), (b), X-Y axes are indicated.

FIG. 78(a) illustrates patterns of integrated circuit pattern region of the mask MR23 for transferring the contact holes CNT of FIG. 77(c) onto a wafer. The light blocking film 7h is made of a resist film having the same constitution as that of the blocking pattern 7a. The light transmitting patterns 4i are patterns for forming contact holes CNT. FIG. 78(b) illustrates the patterns of the mark MR24 for transferring the interconnects 13A to 13C and 13E of FIG. 77(c) onto the wafer. The light blocking film 7i is formed of a resist material similar to that of the light blocking pattern 7a. The light blocking patterns 7i are patterns for forming interconnects 13A to 13C and 13E. On the wafer, a posi resist film is used for the mask MR23 or MR24. The manufacturing method of these masks MR23, MR24 are similar to the above-described method so that a description on it is omitted. In FIG. 78, X-Y axes are indicated for better understanding of the positional relationship of both the masks.

By selecting either one group of the masks MR21, MR22 or the masks MR23, MR24 as described above, an NAND gate circuit or NOR gate circuit can be formed. The masks MR21, MR22 or masks MR23, MR24 may be left as are and used properly or, after removal of the patterns from these masks MR21, MR22, the masks MR23, MR24 may be formed from the thus obtained blanks. A pattern change of such a resist mask can be carried out easily in a short time. Use of such a mask therefore drastically reduces development, pre-production and manufacturing times of a semiconductor integrated circuit device. In addition, correction or change can be performed using an existing manufacturing apparatus, and a material cost, step cost and fuel cost can be reduced so that the total cost of a semiconductor integrated circuit device can be reduced considerably. Cost reduction can therefore be attained even if a semiconductor integrated circuit device is produced in small quantity. In this Embodiment, a conventional mask is used for the fabrication of the unit cell of FIG. 58 because it is produced in a large amount as a common pattern, while a resist mask is used for forming a hole pattern or interconnect pattern to be laid over the unit cell because the shape of it is changed depending on a desired logic circuit. This makes it possible to promptly provide masks suited for each stage in series of manufacturing steps of the semiconductor integrated circuit device, thereby improving productivity of it.

(Embodiment 10)

In this Embodiment, application of the technical concept of the present invention to the fabrication of a semiconductor integrated circuit device having a mask ROM will be described.

The mask ROM features that since it has a memory cell formed of one MIS, the memory cell can be imparted with large capacity and in addition, the whole circuit constitution can be made simple because of unnecessity of write operation. It is however accompanied with the problems that TAT becomes longer compared with the other ROM (for example, EEPROM (Electric Erasable Programmable Read Only Memory) because the details of the memory change according to the request of a customer; and the cost of a product in the case of small quantity production becomes high because masks are manufactured according to a variety of ROM codes different by customers.

In this Embodiment, patterns of base data formed of a basic constitution common to various mask ROMS are transferred using the above-described conventional mask. For writing of the memory data, the resist mask is used first until completion of the debug of customer's specification or data setting, and it is switched over to the conventional mask at the customer's approval for starting of the mass production. A semiconductor integrated circuit device having a mask ROM is then mass produced.

FIG. 79 illustrates one example of a production flow of a semiconductor integrated circuit device having a mask ROM such as micro-computer. A conventional mask is employed in an active region forming step 900, well forming step 901, gate electrode forming step 902, semiconductor region forming step 903 for source and drain, contact hole forming step 905, first-level interconnect forming step 906, first through-hole forming step 907, second-level interconnect forming step 908, second through-hole forming step 909 and third-level interconnect forming step 910 in FIG. 79. In an ROM forming step 904 of FIG. 79, a resist mask is employed first but a conventional mask is used upon mass production. In this diagram, a bonding pad forming step 911 is conducted using a conventional mask, but it can be conducted without a mask. At this time, it is preferred that the maker prepares a menu for use of a flash memory (EEPROM: Electric Erasable Programmable Read Only Memory) for FPGA (Field Programmable Gate Array), use of a resist mask for a mask ROM, use of a conventional mask for a gate array and so on, while the customer selects one from the menu according to the production amount.

According to this Embodiment, it is possible to markedly shorten the development time of a semiconductor integrated circuit device having a mask ROM, to provide a semiconductor integrated circuit device having an ROM code which can satisfy the request of a customer, and to drastically decrease the development cost of a semiconductor integrated circuit device having a mask ROM. A maker can therefore provide a semiconductor integrated circuit device having a mask ROM at a low cost even if it is a product of small quantity production.

FIG. 80 illustrates base data of a mask ROM, wherein (a) is a plan layout of a memory cell region, (b) is its circuit diagram and (c) is a cross-sectional view taken along a line A-A of (a). Here, a mask ROM of ion implantation program system is exemplified. Application of the present invention is not limited to the mask ROM of an ion implantation program system, but it can be applied to various mask ROMS such as a mask ROM of a contact hole program system and a NAND type mask ROM which is also an ion implantation program system.

Data line DL is electrically connected with an n type semiconductor region 11n via a contact hole CNT. A gate electrode 12B is formed of a portion of a word WL. By one of the nMOSQns in the vicinity of the intersects between the data line 12B and word line WL, one memory cell is formed. In the case of this ion implantation program system ROM, nMISQn having a high threshold voltage (high enough not to permit conduction even if the word line WL is on a high level) and that having a low threshold voltage (permitting conduction when the word line WL is on a high level) are manufactured respectively, depending on whether impurity is introduced into a channel region of nMISQn constituting a memory cell or not, which is caused to correspond to the information “0” or “1”. The conventional mask is employed for the transfer of patterns of these base data.

With these base data as common data, necessary amounts of the below-described three kinds of mask ROMS are prepared, which will be described using FIGS. 81 to 83. In each of FIGS. 81 to 83, (a) is a fragmentary plan view of the used mask in an integrated circuit pattern region, (b) is a layout plan view of the memory cell region of a mask ROM showing data writing patterns and (c) is a cross-sectional view taken along a line A-A of FIG. 80(a) upon a data writing step.

In FIG. 81, illustrated is the case where data writing is carried out by forming an opening pattern 22A as illustrated in (b) on a data base with a mask MR25 shown in (a) and implanting ion impurity to a semiconductor substrate 2S exposed from an opening pattern 22A as illustrated in (c). The above-described resist mask is employed as this mask MR25 and its light blocking film 7j is formed of a resist film having the same composition as that of the light blocking pattern 7a. A portion of the light blocking film 7j is removed and instead, a light transmitting pattern 4j is opened in the two-dimensional square shape. This light transmitting pattern 4j serves as a pattern for forming the opening pattern 22A of the resist pattern 17g on the wafer 2W. Here, with this resist pattern 17g as an impurity implantation mask, an impurity for data writing is introduced into the channel region of one nMISQn. The impurity implantation step for data writing is conducted prior to formation of a gate electrode 12B (that is, word line WL). When an increase in a threshold value of nMISQn is desired, boron may be introduced as an impurity, while when a decrease in a threshold value of nMISQn is desired, phosphorus or arsenic may be introduced.

In FIG. 82, illustrated is the case where data writing is carried out by forming opening patterns 22B, 22C illustrated in (b) on a data base with a mask MR26 shown in (a) and implanting ion impurity to a semiconductor substrate 2S exposed from the opening patterns 22B, 22C as illustrated in (c). A resist mask is employed for this mask MR26. A portion of a light blocking film 7j is removed and two light transmitting patterns 4k, 4m are opened in a two-dimensional square shape. These light transmitting patterns 4k, 4m serve as patterns for forming two opening patterns 22B, 22C of the resist pattern 17h on the wafer 2W. With this resist pattern 17h as an impurity implantation mask, an impurity for data writing is introduced into the channel region of two nMISQns.

In FIG. 83, illustrated is the case where data writing is carried out by forming an opening pattern 22D illustrated in (b) on a data base with a mask MR27 shown in (a) and implanting ion impurity to a semiconductor substrate 2S exposed from the opening pattern 22D as illustrated in (c). The above-described resist mask is employed as this mask MR27. A portion of a light blocking film 7j is removed and a light transmitting pattern 4n is opened. This light transmitting pattern 4n serves as a pattern for forming the opening pattern 22D in the resist pattern 17i on a wafer 2W. Here, with this resist pattern 17i as an impurity implantation mask, an impurity for data writing is introduced into the channel region of three nMISQns. As the resist patterns 17g to 17i, posi type is employed. Steps from data reloading to packaging are carried out as in the fabrication steps of a conventional semiconductor integrated circuit device.

According to such an embodiment of this invention, a semiconductor integrated circuit device having multikind mask ROMs can be fabricated efficiently by using a conventional mask for patterning for the preparation of base data while using a resist mask as a mask for forming a reloading layer. TAT of various mask ROMs can be reduced drastically. In addition, data reloading can be carried out using an existing manufacturing apparatus and a material cost, step cost and fuel cost can be reduced, making it possible to drastically reduce the cost of a semiconductor integrated circuit device having a mask ROM even if it is a product of small-quantity production.

(Embodiment 11)

In this embodiment, use of a resist mask upon debugging of a semiconductor integrated circuit device will be described.

For analysis of the failure of a semiconductor integrated circuit device and countermeasures against it, FIB (Focused Ion Beam) is employed. FIB permits easy processing, but since a workman corrects devices one by one while setting a position to be corrected, it takes time and labor for treating a plurality of samples to correct a plurality of chips, leading to difficulty in correction. It is possible to analyze a failure and take a measure against it by simulation, but the value obtained by simulation differs a little from the actual value and this leads to a problem such as a hindrance to an improvement in performance.

In this Embodiment, correction or detection (measurement, analysis) is conducted by forming an actual pattern, particularly, a wiring pattern of the final interconnect layer from a resist mask. This makes it possible to prepare a plurality of sample chips in a short time compared with the case where FIB or conventional mask is employed for the same purpose. Detection is carried out using a chip having patterns practically formed thereon so that reliability of the measured value or analytical results can be improved.

FIG. 84 illustrates a specific example of correction of wiring. FIG. 84(a) illustrates an interconnection pattern on a wafer before correction, while FIG. 84(b) illustrates an interconnection pattern on a wafer after correction. The broken lines indicate underlying interconnects 23A, 23B which do not undergo a change by correction. The interconnects 24A, 24B1, 24B2, 24C1 and 24C2 are the uppermost interconnects and they undergo a change by correction. In FIG. 84, X-Y axes are indicated for better understanding of a positional relationship between the interconnects in (a) and (b).

A mask used for the formation of such a wiring pattern is illustrated in FIG. 85. A mask MR28 in FIG. 85(a) is used for the formation of a wiring pattern of FIG. 84(a). Here a resist mask is exemplified. The wiring pattern before correction is sometimes formed by using a conventional mask. In FIG. 85(b), the mask MR29 is used for the formation of a wiring pattern of FIG. 84(b). In this case, a resist mask is employed.

(Embodiment 12)

In this Embodiment, described is a case where trimming or debugging is conducted for each lot. Described specifically, characteristics of a semiconductor integrated circuit device are adjusted by feeding back data on average fluctuations of the characteristics of many lots of semiconductor integrated circuit devices which are mass produced, to a wiring layer forming step of a semiconductor integrated circuit device of the subsequent lot and then, correcting the wiring based on these data. This correction of wiring is carried out using a resist mask.

FIG. 86 illustrates its flow (completion of trial manufacture, evaluation, analysis and data correction). Here, the above-described multi-chip mask is employed. Instead of trial manufacture of four kinds each in one lot, four lots of a four-chip mask are manufactured with a time lag of several days. The results of debugging of the leading lot is fed back to the subsequent lot. Based on the data thus fed back, the pattern size or shape on a multi-chip mask for the metallization is changed. Using the resultant multi-chip mask, a wiring layer of semiconductor integrated circuit devices of the next lot is formed. In this manner, trimming of semiconductor integrated circuit devices is carried out lot by lot.

This makes it possible to provide semiconductor integrated circuit devices uniform in electrical characteristics and having high reliability in a short time. Upon pattern change of a mask for trimming or debugging, a wasteful material or step can be omitted and in addition, an existing manufacturing apparatus is employed as is so that semiconductor integrated circuit devices having high reliability can be provided at a low cost.

The present invention made by present inventors was described specifically based on embodiments. It should however be borne in mind that the present invention is not limited to or by the above-described embodiments. It is needless to say that it can be changed within an extent not departing from the scope of the invention.

For example, in the above-described embodiments, a conventional wiring structure is adopted for interconnection. The wiring structure is not limited to it but may be formed by so-called damascene method or dual damascene method wherein an interconnect or plug is formed by embedding a conductor film in a groove having an insulating film formed therein.

In the above-described embodiments, a semiconductor substrate composed singly of a semiconductor was described as a semiconductor integrated circuit substrate but the semiconductor integrated circuit substrate is not limited to it. Alternatively, an SOI (Silicon On Insulator) substrate having a thin semiconductor layer disposed on an insulating layer or an epitaxial substrate having an epitaxial layer disposed on a semiconductor substrate may be used.

Upon exposure treatment with various masks, the above-described modified illumination may be usable as an exposure light.

In the above descriptions, the invention made by the present inventors was applied to a semiconductor integrated circuit device, which had been the background of the invention. The invention is not limited to the fabrication process of a semiconductor integrated circuit device but is applicable to a fabrication process of another device such as liquid-crystal display or micro-machine.

The advantages available by the typical inventions, among the inventions disclosed by the present application, will next be described briefly.

(1) According to the present invention, by properly using a mask having a blocker made of a metal film and a mask having a blocker made of an organic material containing an organic photosensitive resin film upon exposure treatment in the fabrication step of a semiconductor integrated circuit device, it is possible to improve the productivity of the semiconductor integrated circuit device.

(2) According to the present invention, by properly using a mask having a blocker made of a metal film and a mask having a blocker made of an organic material containing an organic photosensitive resin film upon exposure treatment in the fabrication step of a semiconductor integrated circuit device, it is possible to shorten the fabrication time of the semiconductor integrated circuit device.

(3) According to the present invention, by properly using a mask having a blocker made of a metal film and a mask having a blocker made of an organic material containing an organic photosensitive resin film upon exposure treatment in the fabrication step of a semiconductor integrated circuit device, it is possible to reduce the fabrication cost of the semiconductor integrated circuit device.

What is claimed is:

1. A fabrication method of a semiconductor integrated circuit device, comprising the step of using a first photomask which has, as a blocker against an exposure light, an organic material containing an organic photosensitive resin and a second photomask which has, as a blocker against an exposure light, a metal film, depending on the production amount or fabrication step of the semiconductor integrated circuit device.

2. A fabrication method of a semiconductor integrated circuit device according to claim 1, comprising:
(a) a step wherein a maker prepares a menu for customer including a production type using the first photomask and a production type using the second photomask, and
(b) a step wherein a production client selects a production type most suited for the semiconductor integrated circuit device or a predetermined fabrication step of the semiconductor integrated circuit device from the menu for customer.

3. A fabrication method of a semiconductor integrated circuit device, comprising the steps of:
(a) judging whether the production amount of the semiconductor integration circuit device exceeds a predetermined threshold production amount or not; and
(b) when the production amount of the semiconductor integrated circuit device does not exceed the threshold value, using a photomask which has, as a blocker against an exposure light, an organic material containing an organic photosensitive resin film upon exposure treatment.

4. A fabrication method of a semiconductor integrated circuit device according to claim 3, further comprising the step of using a photomask which has, as a blocker against an exposure light, a metal film upon exposure treatment when the production amount of the semiconductor integrated circuit device is expanded to exceed the threshold value.

5. A fabrication method of a semiconductor integrated circuit device, comprising the steps of:
(a) judging whether the production amount of the semiconductor integration circuit device exceeds a predetermined threshold production amount or not;
(b) when the production amount of the semiconductor integrated circuit device exceeds the threshold value, judging whether the function of the semiconductor integrated circuit device has been determined or not;
(c) when the function has not been determined, using a photomask which has, as a blocker against an exposure light, an organic material containing an organic photosensitive resin film upon exposure treatment.

6. A fabrication method of a semiconductor integrated circuit device according to claim 5, further comprising the step of using a photomask which has, as a blocker against an exposure light, a metal film upon exposure treatment in a stage when the function of the semiconductor integrated circuit device is determined.

7. A fabrication method of a semiconductor integrated circuit device according to claim 5, further comprising the step of using a photomask which has, as a blocker against an exposure light, a metal film upon exposure treatment when the function of the semiconductor integrated circuit device has been determined.

8. A fabrication method of a semiconductor integrated circuit device, comprising the step of using a photomask, as a blocker against an exposure light, an organic material containing an organic photosensitive resin upon exposure treatment prior to a mass production step.

9. A fabrication method of a semiconductor integrated circuit device, comprising the step of using a first photomask which has, as a blocker against an exposure light, an organic material containing an organic photosensitive resin upon exposure treatment prior to a mass production step, and in the mass production step, using a second photomask which has, as a blocker against an exposure light, a metal film upon exposure treatment.

10. A fabrication method of a semiconductor integrated circuit device, comprising the step of using a first photomask which has, as a blocker against an exposure light, an organic material containing an organic photosensitive resin upon exposure treatment in a step of forming patterns relating to the constitution of a logic circuit, while using a second photomask which has, as a blocker against an exposure light, a metal film upon exposure treatment in a step of forming patterns relating to a unit cell.

11. A fabrication method of a semiconductor integrated circuit device, comprising the steps of:
(a) using a first photomask having, as a blocker against an exposure light, an organic material containing an organic photosensitive resin upon exposure treatment for forming patterns relating to the constitution of a logic circuit prior to a mass production step of the semiconductor integrated circuit device,
(b) using a second photomask having a metal as a blocker against an exposure light upon exposure treatment for forming patterns relating the constitution of the logic circuit in the mass production step of the semiconductor integrated circuit device, and
(c) using the second photomask having a metal as a blocker against an exposure light upon exposure treatment for forming patterns relating to a unit cell prior to the mass production step and in the mass production step.

12. A fabrication method of a semiconductor integrated circuit device having an ROM, comprising the steps of using a first photomask having, as a blocker against an exposure light, an organic material containing an organic photosensitive resin upon exposure treatment for forming patterns relating to data writing of the ROM; and using a second photomask having a metal as a blocker against an exposure light upon exposure treatment for forming patterns other than those relating to the data writing.

13. A fabrication method of a semiconductor integrated circuit device having an ROM, comprising the steps of:
(a) using a first photomask having, as a blocker against an exposure light, an organic material containing an organic photosensitive resin upon exposure treatment for forming patterns relating to data writing of the ROM prior to a mass production step of the semiconductor integrated circuit device,
(b) using a second photomask having a metal as a blocker against an exposure light upon exposure treatment for forming patterns relating to data writing of the ROM in the mass production step of the semiconductor integrated circuit device; and
(c) using the second photomask having a metal as a blocker against an exposure light upon exposure treatment for forming patterns other than those relating to data writing of the ROM prior to the mass production step and in the mass production step.

14. A fabrication method of a semiconductor integrated circuit device, comprising the steps of:
(a) a step wherein a producer of the semiconductor integrated circuit device prepares a menu for customer including a production type using a first photomask which has, as a blocker against an exposure light, an organic photosensitive resin, and a production type using a second photomask which has a metal film as a blocker against an exposure light, each upon exposure treatment, and
(b) a step wherein a production client selects, from the menu for customer, the optimum production type for the semiconductor integrated circuit device or a predetermined fabrication step of the semiconductor integrated circuit device.

15. A fabrication method of a semiconductor integrated circuit device, comprising, upon forming patterns of the semiconductor integrated circuit device, properly using
(a) exposure treatment using a first photomask having, as a blocker against an exposure light, an organic material containing an organic photosensitive resin;
(b) another exposure treatment using a second photomask having a metal film as a blocker against an exposure light; and
(c) direct writing treatment using an energy beam.

16. A fabrication method of a semiconductor integrated circuit device according to claim 15, comprising the steps of:
judging whether the using amount of the photomask exceeds a predetermined threshold using amount or not;
judging whether the first photomask is usable or not when the using amount of the photomask is less than the threshold value, and
carrying out exposure treatment with the first photomask when the first photomask is usable while carrying out direct writing treatment using the energy beam when the first photomask is unusable.

17. A fabrication method of a semiconductor integrated circuit device according to claim 15, comprising the steps of:
judging whether the using amount of the photomask exceeds a predetermined threshold using amount or not;
judging whether the second photomask is usable or not when the using amount of the photomask exceeds the threshold value,
carrying out exposure treatment with the second photomask when the second photomask is usable,
judging whether the first photomask is usable or not when the second photomask is unusable,
carrying out exposure treatment with the first photomask when the first photomask is usable, and
carrying out direct writing treatment with the energy beam when the first photomask is unusable.

18. A fabrication method of a semiconductor integrated circuit device, comprising the steps of:
(a) forming a first photomask having, as a blocker against an exposure light, an organic material containing an organic photosensitive resin on a semiconductor-integrated-circuit-device evaluator's side;
(b) transferring a predetermined pattern onto a semiconductor wafer by exposure treatment with the first photomask, on a semiconductor-integrated-circuit-device maker's side; and
(c) evaluating the semiconductor wafer to which the predetermined pattern has been transferred, on the semiconductor-integrated-circuit-device evaluator's side.

19. A fabrication method of a semiconductor integrated circuit device, comprising the steps of:
(a) using a photomask having a metal film as a blocker against an exposure light upon exposure treatment in a mass production step of the semiconductor integrated circuit device;
(b) discarding the photomask having a metal film as a blocker against an exposure light after completion of the mass production step of the semiconductor integrated circuit device; and
(c) using another photomask having, as a blocker against an exposure light, an organic material containing an organic photosensitive resin upon exposure treatment in reproduction of the semiconductor integrated circuit device.

20. A fabrication method of a semiconductor integrated circuit device according to claim 19, wherein upon reproduction of the semiconductor integrated circuit device, in the stage when the production amount exceeds a predetermined threshold production amount, a photomask having a metal film as a blocker against an exposure light is used instead of the another photomask having, as a blocker against an exposure light, an organic material containing an organic photosensitive resin upon exposure treatment.

21. A fabrication method of a semiconductor integrated circuit device, comprising the steps of:
(a) using a first photomask having, as a blocker against an exposure light, an organic material containing an organic photosensitive resin upon exposure treatment prior to a mass production step of the semiconductor integrated circuit device; and
(b) using a second photomask having a metal film as a blocker against an exposure light upon exposure treatment in the mass production step of the semiconductor integrated circuit device,
wherein said first photomask has a plurality of semiconductor chip transfer regions disposed thereon, and
patterns having data of the semiconductor integrated circuit device which are different each other are disposed in the transfer regions, respectively.

22. A fabrication method of a semiconductor integrated circuit device according to claim 21, wherein said second photomask has a plurality of semiconductor chip transfer regions disposed thereon and patterns having the same data of the semiconductor integrated circuit device selected in an evaluation step are disposed in the transfer regions.

23. A fabrication method of a semiconductor integrated circuit device, comprising the steps of:
(a) disposing a semiconductor chip transfer region of a plurality of semiconductor integrated circuit devices on one photomask in the order of completion of a design period of the semiconductor integrated circuit devices; and
(b) carrying out exposure treatment with the one photomask.

24. A fabrication method of a semiconductor integrated circuit device according to claim 23, wherein the one photomask has, as a blocker against an exposure light, an organic material containing an organic photosensitive resin.

25. A fabrication method of a semiconductor integrated circuit device, comprising the steps of:
(a) in a first pre-production step, carrying out exposure treatment using a photomask having, disposed thereon, a semiconductor chip transfer region of a plurality of semiconductor integrated circuit devices and judging the quality of the patterns thus transferred; and
(b) in a second pre-production step, carrying out another exposure treatment using a photomask having, disposed thereon, a semiconductor chip transfer region of the plurality of semiconductor integrated circuit devices which are judged bad in said first pre-production step and judging quality of the patterns thus transferred,
wherein the photomasks used in the first and second pre-production steps each has, as a blocker against an exposure light, an organic material containing an organic photosensitive resin.
